(19) United States
(12) Patent Application Publication
(10) Pub. No.: US 2025/0227841 A1
(43) Pub. Date: Jul. 10, 2025

(54) GLASS SUBSTRATE, MULTILAYER WIRING SUBSTRATE, AND METHOD FOR PRODUCING GLASS SUBSTRATE

(71) Applicant: TOPPAN Holdings Inc., Tokyo (JP)

(72) Inventor: Masashi SAWADAISHI, Tokyo (JP)

(73) Assignee: TOPPAN Holdings Inc., Tokyo (JP)

(21) Appl. No.: 19/093,330

(22) Filed: Mar. 28, 2025

Related U.S. Application Data
(63) Continuation of application No. PCT/JP2023/029922, filed on Aug. 21, 2023.

(30) Foreign Application Priority Data
Sep. 30, 2022 (JP) 2022-157968
Sep. 30, 2022 (JP) 2022-157982
Sep. 30, 2022 (JP) 2022-158002

(51) Int. Cl. H05K 1/11; H05K 1/03; H05K 3/00; H05K 3/40

(52) U.S. Cl. CPC H05K 1/115; H05K 1/0306; H05K 3/002; H05K 3/0029; H05K 3/4038; H05K 2201/09536; H05K 2203/0789; H05K 2203/107

(57) ABSTRACT

A glass substrate having a first surface and a second surface, the glass substrate including at least one through hole penetrating from the first surface to the second surface, where a cut surface of the through hole in a thickness direction of the glass substrate has a shape of a side surface, the shape having a dispersion roughness of 1,000 nm or less and an unevenness width of 1,500 nm or less.

### CROSS-REFERENCE TO RELATED APPLICATIONS

This application is a bypass continuation of PCT International Application No. PCT/JP2023/029922 filed on Aug. 21, 2023, which claims priority to Japanese Patent Application Nos. 2022-157968, 2022-157982 and 2022-158002 filed on Sep. 30, 2022, the entire contents of each are incorporated herein by reference.

### TECHNICAL FIELD

The present invention relates to a glass substrate, a multilayer wiring substrate, and a method for producing a glass substrate.

### BACKGROUND ART

Recently, three-dimensional mounting technique has been used in which circuit boards are laminated. In such a mounting technique, through electrodes are formed in the circuit board. The through electrodes are formed by forming through holes in a substrate made of an insulator and disposing conductors in the through holes. Higher integration of circuit boards also requires finer through holes.

For example, Patent Literature 1 discloses a technique for providing a glass substrate having a plurality of through holes by irradiating a plate-like glass with an excimer laser light. Patent Literature 2 discloses a method for manufacturing a high-density array of holes in glass, the method including a step of irradiating a front surface of a glass product with a UV laser beam. Patent Literature 3 discloses a through electrode substrate including: a substrate including a through hole; and a conductor disposed along an inner side surface of the through hole, wherein the substrate has a first surface and a second surface, and the through hole has a through hole shape that satisfies a condition in which a sum of inclination angles of the inner side surface with respect to a central axis of the through hole is 8.0° or more, where: an inclination angle expanding toward the first surface side is defined as a positive inclination angle; and the inclination angles are inclination angles at distances from the first surface, the distances being 6.25%, 18.75%, 31.25%, 43.75%, 56.25%, 68.75%, 81.25%, and 93.75% of a length of a section from the first surface to the second surface.

### CITATION LIST

### Patent Literature

Patent Literature 1: International Publication No. 2010/087483
Patent Literature 2: Japanese Translation of PCT International Application Publication No. 2014-501686
Patent Literature 3: Japanese Patent Publication No. 6809511

### SUMMARY OF INVENTION

### Technical Problem

However, the contents described in Patent Literatures 1 to 3 do not discuss the effect of the side surface roughness of the through hole on the transmission characteristics of the through electrode. For this reason, the side surface of the through hole described in Patent Literatures 1 to 3 has a dispersion roughness of 1,000 nm or more and a PV (Peak to Valley) of 1,500 nm or more. This makes it difficult to maintain the sufficiently excellent transmission characteristics of the through electrode, especially in high frequency bands such as the sub-6 GHz band among the frequency bands used for 5G, due to the roughness of the side surface of the through hole.

An object of the present invention is to provide a glass substrate capable of forming a through electrode with excellent transmission characteristics, and a multilayer wiring substrate including such a glass substrate.

### Solution to Problem

To solve the above-mentioned problem, one typical glass substrate of the present invention has a first surface and a second surface and includes at least one through hole penetrating from the first surface to the second surface, and the side surface of the through hole has a dispersion roughness of 1,000 nm or less and an unevenness width of 1,500 nm or less.

### Advantageous Effects of Invention

According to the present invention, it is possible to provide a glass substrate capable of forming a through electrode with excellent transmission characteristics, and a multilayer wiring substrate including such a glass substrate.

Problems, configurations, and effects other than those described above will be made clear by the following explanation of embodiments of the invention.

### BRIEF DESCRIPTION OF DRAWINGS

FIG. 1 is a diagram showing a cross section of a truncated cone-shaped through hole and a method for measuring inclination angles.

FIG. 2 is a diagram showing a cross section of an X-shaped through hole and a method for measuring inclination angles.

FIG. 3 is a diagram showing a method for measuring a side surface roughness of a through hole.

FIG. 4 is a diagram showing a cross section of a truncated cone-shaped through hole and a method for measuring inclination angles.

FIG. 5 is a diagram showing measurement results of inclination angles of a through hole of Example 1 in a first embodiment.

FIG. 6 is a diagram showing measurement results of inclination angles of a through hole of Example 2 in the first embodiment.

FIG. 7 is a diagram showing measurement results of inclination angles of a through hole of Example 3 in the first embodiment.

FIG. 8 is a diagram showing a cross-sectional shape of a through hole of Comparative Example 1 in the first embodiment.

FIG. 9 is a diagram showing measurement results of inclination angles of the through hole of Comparative Example 1 in the first embodiment.

FIG. 10 is a diagram showing a cross-sectional shape of a through hole of Comparative Example 2 in the first embodiment.

FIG. 11 is a diagram showing measurement results of inclination angles of the through hole of Comparative Example 2 in the first embodiment.

FIG. 12 is a diagram showing a shape of a through hole of Comparative Example 3 in the first embodiment.

FIG. 13 is a diagram showing measurement results of inclination angles of the through hole of Comparative Example 3 in the first embodiment.

FIG. 14 is a diagram showing transmission characteristics of a through electrode of Example 1 and transmission characteristics of a through electrode of Comparative Example 1 in the first embodiment.

FIG. 15A is SEM images of cross sections of the through holes of each Example and each Comparative Example in the first embodiment.

FIG. 15B is a diagram describing ridgelines of the through holes in each Example of the first embodiment.

FIG. 16 is a diagram showing an example of a structure of a multilayer wiring substrate according to the first embodiment.

FIG. 17 is a diagram showing another example of a configuration of a multilayer wiring substrate according to the first embodiment.

FIG. 18 is a diagram showing a step of bonding a glass substrate to a first support.

FIG. 19 is a diagram showing a step of forming laser modified portions.

FIG. 20 is a diagram showing a step of forming a first wiring layer.

FIG. 21 is a diagram showing a step of bonding a second support.

FIG. 22 is a diagram showing a step of peeling the first support.

FIG. 23 is a diagram showing a step of forming through holes.

FIG. 24 is a diagram showing a step of forming through electrodes.

FIG. 25 is a diagram showing a step of forming an insulating resin layer.

FIG. 26 is a diagram showing a step of peeling the second support and a second bonding layer.

FIG. 27 is a diagram showing a step of forming a first wiring layer and a second wiring layer.

FIG. 28 is a diagram showing an example of a configuration of a multilayer wiring substrate in a second embodiment.

FIG. 29 is a diagram showing another example of a configuration of a multilayer wiring substrate in the second embodiment.

FIG. 30 is a diagram showing a step of preparing a glass substrate.

FIG. 31 is a diagram showing a step of forming laser modified portions.

FIG. 32 is a diagram showing a step of forming through holes.

FIG. 33 is a diagram showing a step of forming through electrodes in each through hole.

FIG. 34 is a diagram showing a step of forming a first wiring layer and a second wiring layer.

FIG. 35 is a diagram showing measurement results of inclination angles of a through hole of Example 1 in the second embodiment.

FIG. 36 is a diagram showing a measurement results of inclination angles of a through hole of Example 2 in the second embodiment.

FIG. 37 is a diagram showing measurement results of inclination angles of a through hole of Example 3 in the second embodiment.

FIG. 38 is a diagram showing a cross-sectional shape of a through hole of Comparative Example 1 in the second embodiment.

FIG. 39 is a diagram showing measurement results of inclination angles of the through hole of Comparative Example 1 in the second embodiment.

FIG. 40 is a diagram showing a cross-sectional shape of a through hole of Comparative Example 2 in the second embodiment.

FIG. 41 is a diagram showing measurement result of inclination angles of the through hole of Comparative Example 2 in the second embodiment.

FIG. 42 is a diagram showing a cross-sectional shape of a through hole of Comparative Example 3 in the second embodiment.

FIG. 43 is a diagram showing measurement results of inclination angles of the through hole of Comparative Example 3 in the second embodiment.

FIG. 44 is a diagram showing transmission characteristics of a through electrode of Example 1 and transmission characteristics of a through electrode of Comparative Example 1 in the second embodiment.

FIG. 45 is a diagram showing a case in which the multilayer wiring substrate is used as an interposer substrate for a semiconductor power device and a BGA substrate.

FIG. 46 is a diagram showing a cross section in the case of FIG. 45.

FIG. 47 is a diagram showing a case in which the multilayer wiring substrate and the semiconductor power device are used in an electronic device for communication.

FIG. 48 is a diagram showing a cross section in the case of FIG. 47.

FIG. 49 is a diagram showing a cross section of a truncated cone-shaped through hole and a method for measuring inclination angles.

FIG. 50 is a diagram showing a method for measuring a side surface roughness of a through hole.

FIG. 51 is a diagram showing measurement results of inclination angles of a through hole of Example 1 in a first embodiment (Supplement 1).

FIG. 52 is a diagram showing measurement results of inclination angles of a through hole in Example 2 in the first embodiment (Supplement 1).

FIG. 53 is a diagram showing measurement results of inclination angles of a through hole in Example 3 in the first embodiment (Supplement 1).

FIG. 54 is a diagram showing a cross-sectional shape of a through hole of Comparative Example 1 in the first embodiment (Supplement 1).

FIG. 55 is a diagram showing measurement results of inclination angles of the through hole of Comparative Example 1 in the first embodiment (Supplement 1).

FIG. 56 is a diagram showing a cross-sectional shape of a through hole of Comparative Example 2 in the first embodiment (Supplement 1).

FIG. 57 is a diagram showing measurement results of inclination angles of the through hole of Comparative Example 2 in the first embodiment (Supplement 1).

FIG. 58 is a diagram showing a cross-sectional shape of a through hole of Comparative Example 3 in the first embodiment (Supplement 1).

FIG. 59 is a diagram showing measurement results of inclination angles of the through hole of Comparative Example 3 in the first embodiment (Supplement 1).

FIG. 60A is a diagram showing Table 4 in a form of a graph.

FIG. 60B is a diagram schematically showing a case in which a through electrode is formed.

FIG. 61A is a diagram showing SEM images of cross sections of the through holes of each Example and each Comparative Example in the first embodiment (Supplement 1).

FIG. 61B is a diagram describing ridgelines of the through hole in each Example of the first embodiment (Supplement 1).

FIG. 61C is a diagram showing a case in which a through electrode is formed in the through hole of the first embodiment (Supplement 1).

FIG. 62 is a diagram showing transmission characteristics of a through electrode of Example 1 and transmission characteristics of a through electrode of Comparative Example 1 in the embodiment.

FIG. 63 is a diagram showing an example of a configuration of a multilayer wiring substrate 1 according to the first embodiment (Supplement 1).

FIG. 64 is a diagram showing another example of a configuration of the multilayer wiring substrate 1 according to the first embodiment (Supplement 1).

FIG. 65 is a diagram showing a step of bonding a glass substrate to a first support.

FIG. 66 is a diagram showing a step of forming laser modified portions.

FIG. 67 is a diagram showing a step of forming a first wiring layer.

FIG. 68 is a diagram showing a step of bonding a second support.

FIG. 69 is a diagram showing a step of peeling the first support.

FIG. 70 is a diagram showing a step of forming through holes.

FIG. 71 is a diagram showing a step of forming through electrodes.

FIG. 72 is a diagram showing a step of forming an insulating resin layer.

FIG. 73 is a diagram showing a step of peeling the second support and a second bonding layer.

FIG. 74 is a diagram showing a step of forming a first wiring layer and a second wiring layer.

FIG. 75 is a diagram showing a case in which the multilayer wiring substrate is used as an interposer substrate for a semiconductor power device and a BGA substrate.

FIG. 76 is a diagram showing a cross section in the case of FIG. 75.

FIG. 77 is a diagram showing a case in which the multilayer wiring substrate and the semiconductor device are used in an electronic device for communication.

FIG. 78 is a diagram showing a cross section in the case of FIG. 77.

FIG. 79 is a diagram describing features of a through hole and a through electrode formed in the present disclosure.

FIG. 80 is a diagram showing a cross section of a truncated cone-shaped through hole and a method for measuring inclination angles.

FIG. 81 is a diagram showing a method for measuring a side surface roughness of a through hole.

FIG. 82 is a diagram showing measurement results of inclination angles of a through hole of Example 1 in a first embodiment (Supplement 2).

FIG. 83 is a diagram showing measurement results of inclination angles of a through hole of Example 2 in the first embodiment (Supplement 2).

FIG. 84 is a diagram showing measurement results of inclination angles of a through hole of Example 3 in the first embodiment (Supplement 2).

FIG. 85 is a diagram showing a cross-sectional shape of a through hole of Comparative Example 1 in the first embodiment (Supplement 2).

FIG. 86 is a diagram showing measurement results of inclination angles of the through hole of Comparative Example 1 in the first embodiment (Supplement 2).

FIG. 87 is a diagram showing a cross-sectional shape of a through hole of Comparative Example 2 in the first embodiment (Supplement 2).

FIG. 88 is a diagram showing measurement results of inclination angles of the through hole of Comparative Example 2 in the first embodiment (Supplement 2).

FIG. 89 is a diagram showing a cross-sectional shape of a through hole of Comparative Example 3 in the first embodiment (Supplement 2).

FIG. 90 is a diagram showing measurement results of inclination angles of the through hole of Comparative Example 3 in the first embodiment (Supplement 2).

FIG. 91 is a diagram showing measurement results of inclination angles of a through hole of Application Example 1.

FIG. 92 is a diagram showing measurement results of inclination angles of a through hole of Application Example 2.

FIG. 93 is a diagram showing measurement results of inclination angles of a through hole of Application Example 3.

FIG. 94A is a diagram showing Table 19 in a form of a graph.

FIG. 94B is a diagram schematically showing a case in which a through electrode is formed.

FIG. 94C is a diagram describing features of a through hole and a through electrode formed in the present disclosure.

FIG. 95A is a diagram showing a SEM image of a typical cross-sectional shape of the through hole for each Example and each Comparative Example in the first embodiment (Supplement 2).

FIG. 95B is a diagram showing SEM images of a cross sections of the through holes of each Example and each Comparative Example in the first embodiment (Supplement 2).

FIG. 95C is a diagram describing ridgelines of the through hole of each Example in the first embodiment (Supplement 2).

FIG. 95D is a diagram showing a case in which a through electrode is formed in a through hole in the first embodiment (Supplement 2).

FIG. 96 is a diagram showing transmission characteristics of the through electrode of Example 1 in the first embodiment (Supplement 2) and transmission characteristics of the through electrode of Comparative Example 1.

FIG. 97 is a diagram showing an example of a configuration of a multilayer wiring substrate according to the first embodiment (Supplement 2).

FIG. 98 is a diagram showing another example of a configuration of a multilayer wiring substrate in the first embodiment (Supplement 2).

FIG. 99 is a diagram showing a step of bonding a glass substrate to a first support.

FIG. 100 is a diagram showing a step of forming laser modified portions.

FIG. 101 is a diagram showing a step of forming a first wiring layer.

FIG. 102 is a diagram showing a step of bonding a second support.

FIG. 103 is a diagram showing a step of peeling the first support.

FIG. 104 is a diagram showing a step of forming through holes.

FIG. 105 is a diagram showing a step of forming through electrodes.

FIG. 106 is a diagram showing a step of forming an insulating resin layer.

FIG. 107 is a diagram showing a step of peeling the second support and a second bonding layer.

FIG. 108 is a diagram showing a step of forming a first wiring layer and a second wiring layer.

FIG. 109 is a diagram showing a case in which the multilayer wiring substrate is used as an interposer substrate for a semiconductor power device and a BGA substrate.

FIG. 110 is a diagram showing a cross section in the case of FIG. 109.

FIG. 111 is a diagram showing a case in which the multilayer wiring substrate and the semiconductor power device are used in an electronic device for communication.

FIG. 112 is a diagram showing a cross section in the case of FIG. 111.

### DESCRIPTION OF EMBODIMENTS

Embodiments of the present invention will be described below with reference to the drawings. The following embodiments and Examples are merely examples of the embodiments of the present invention, and the present invention is not intended to be construed as being limited to these embodiments and examples. In the drawings referred to in the embodiments of the present invention, the same or similar reference numerals and characters (reference signs each consisting of only A, B, or the like, added after the number) are used for the same portions, and repeated explanation may be omitted. In addition, the description of the dimensions and ratios in the drawings may differ from the actual ratios for the convenience of explanation and notation, or may be omitted from some of the configurations.

The position, size, shape, range, or the like of each component shown in the drawings may not represent the actual position, size, shape, range, and the like, in order to make the invention easier to understand. For this reason, the present invention is not necessarily limited to the position, size, shape, range, and the like disclosed in the drawings.

In the present disclosure, the term “surface” may refer not only to the surface of a plate-like member, but also to the interface of a layer contained in a plate-like member that is substantially parallel to the surface of the plate-like member. Additionally, “upper surface” or “lower surface” means the surface shown on the upper side or lower side on a drawing when a plate-like member or a layer contained in a plate-like member is illustrated. The “upper surface” and the “lower surface” are sometimes referred to as a “first surface” and a “second surface”.

A term “side surface” means a thickness portion of a surface or a layer in a plate-like member or a layer contained in a plate-like member. Part of a surface and a side surface may be collectively referred to as an “end portion”.

A “side surface of a through hole” means the interface on an object that forms the through hole, in the through hole provided in the object.

An “upper side” means a vertically upward direction when a plate-like member or a layer is placed horizontally. An “upper side” and a “lower side” opposite to this are sometimes referred to as a “positive Z-axis direction” and a “negative Z-axis direction”, and a horizontal direction is sometimes referred to as an “X-axis direction” and a “Y-axis direction”.

A distance in the Z-axis direction is referred to as a “height,” and a distance on an XY plane defined by the X-axis and Y-axis directions is referred to as a “width.” In referring to a layered object, the height is also referred to as a “thickness.”

A “through electrode provided in a glass substrate” means a conductive path provided for electrical continuity between the first surface and the second surface of the glass substrate when the glass substrate is used as part of a multilayer wiring substrate, and does not necessarily need to completely penetrate the glass substrate with a single conductive material. As long as the conductive path from the first surface and the conductive path from the second surface are connected, they are included in the through electrodes. The form of the through electrode may be a filled type in which a through hole is filled with a conductive material, or a conformal type in which only the side wall portion of the through hole is covered with a conductive material (the through hole includes both bottomed and completely through holes).

A “planar shape” and a “planar view” mean the shape when a surface or layer is seen from above. A “cross-sectional shape” and a “cross-sectional view” mean the shape when a plate-like member or a layer is cut in a specific direction and seen from the horizontal direction.

A “central portion” means the center portion, not a peripheral portion of the surface or the layer. A “center direction” means a direction from the peripheral portion of the surface or the layer toward the center in the planar shape of the surface or the layer.

### <Measuring Method>

To describe the shape of a through hole provided in a glass substrate according to first and second embodiments of the present invention, the following first shows a method for measuring inclination angles of a through hole 12 and a method for measuring a side surface roughness.

Here shows points to note in measuring inclination angles depending on the positions of the side wall of the glass substrate through hole and describing the values thereof.

When a specific position in the through hole is specified as a position in a depth direction from one side of the glass substrate, an angle of the side surface at that position depends greatly on the scale at which the shape of the side surface at that position is observed.

In other words, results may be significantly different between the following two cases of: observing the inclination angle of the side wall at a certain position on a scale of overlooking the entire through hole of the glass substrate; and enlarging the sidewall near the measurement point, making the fine unevenness clear on the side wall at that position, precisely determining a position where that point, at which the angle is specified, corresponds to on the unevenness, and determining the inclination angle of the tangent at that position to be the desired angle.

The inclination angle of the glass substrate through hole in the present disclosure corresponds to the former case, and means an inclination angle that reflects the tendency in overlooking the entire through hole without being excessively affected by the unevenness of the side surface.

An example of a measurement method is setting the tangent at the measurement point so as to reflect the tendency of the inclination at the measurement point and in its vicinity as much as possible, in a cross-sectional photograph at a scale and resolution in which the entire through hole can be overlooked and fine unevenness on the side surface cannot be seen with the naked eye.

### (Method for Measuring Inclination Angles of Through Hole (Truncated Cone Shape))

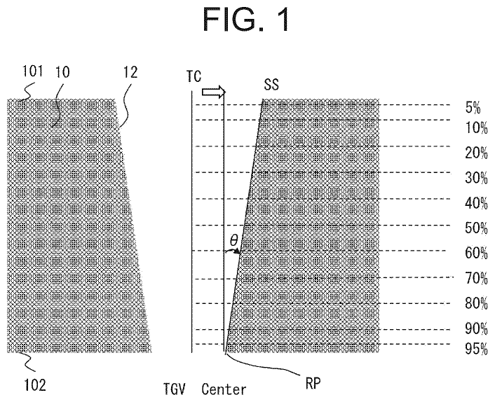

First, FIG. 1 illustrates the shape of the through hole 12 obtained in the first embodiment of the present invention. FIG. 1 is a diagram showing a cross section of the truncated cone-shaped through hole 12 and a method for measuring inclination angles. The cross section of the through hole 12 shown in FIG. 1 is obtained by: dividing (cutting) the through hole 12 from a first surface 101 side in the thickness direction of the glass substrate with a scriber to expose a cross section (cut surface); and analyzing the SEM image, observed with a SEM (Scanning Electron Microscope), using image analysis software. In FIG. 1, the area shown with a pattern design indicates the glass substrate 10. The through hole 12 shown in FIG. 1 has a truncated cone shape, and the through hole 12 has a minimum value on a second surface 102 side at which the diameter of the through hole is minimum. The scales of 5%, 10%, . . . 95% shown in FIG. 1 each indicate a percentage with respect to the length from the first surface 101 of the glass substrate 10 to the second surface 102 thereof.

A center line TC is drawn at a central portion of an opening on the second surface 102 side of the glass substrate 10 so as to be perpendicular to the second surface 102. Next, as shown by an arrow, the center line TC is translated toward either side of the through hole 12, the translated center line TC is brought into contact with the point where the diameter of the through hole 12 is at its minimum value, and the point of contact is set as a reference point RP. Then, tangents ss are drawn from the reference point RP to the cross-sectional positions at heights of each of the scale positions of 5% to 95%, and the inclination angles of each tangent ss are measured and defined as the inclination angles at each of the cross-sectional positions of 5% to 95%. The inclination angle is positive in a direction in which the diameter of the through hole 12 expands upward.

As described above, in the first embodiment, the method for measuring the inclination angles includes the following protocols of (1) to (3): (1) creating a center line of the through hole 12; (2) moving the center line horizontally to the position where the opening is at its minimum value to create a reference point; and (3) drawing tangents from the reference point to the specific positions of the through hole, and measuring their angles. In particular, using the protocol of (2) creating a reference point enables a highly reliable measurement on a scale that overlooks the entire through hole and that is not affected by fine unevenness on the side wall.

In addition, in a specific inclination angle measurement, a scriber and a precision breaker are used from the first surface 101 side of the through hole 12 to divide (cut) the through hole 12 at the central portion, to expose the cross section of the through hole 12. As a method for dividing, for example, three-point bending can be applied. Then, the exposed cross section is observed by SEM and the SEM image of the cross section is subjected to image analysis, and thereby the angle of the through hole 12 is measured.

### (Method for Measuring Inclination Angles of Through Hole (X-Shape))

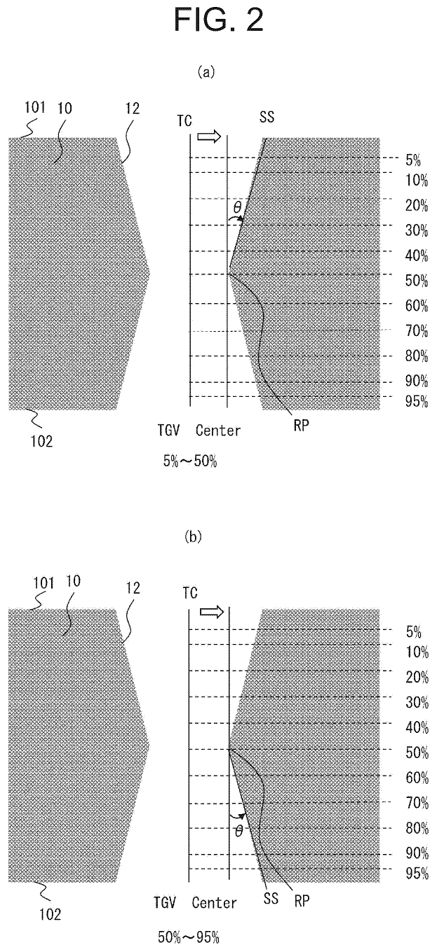

The following describes a method for measuring the inclination angle in the shape of a through hole 12 obtained in the second embodiment of the present invention with reference to FIG. 2.

FIG. 2 is a diagram showing a cross section of the through hole 12 that has an hourglass shape (hereinafter also referred to as an “X-shape”) with a narrowed central portion in the height direction, and a method for measuring inclination angles. The cross section of the through hole 12 shown in FIG. 2 is obtained by dividing the through hole 12 from the first surface 101 side with a scriber to expose the cross section, and then performing image analysis on the SEM image observed with a SEM (Scanning Electron Microscope). In FIG. 2(a) and FIG. 2(b), the cross section is shown that is taken along a plane passing through the center of the through hole 12, and as in FIG. 1, the area shown with the pattern design indicates the glass substrate 10. The scales of 5%, 10%, . . . 95% shown in FIGS. 2(a) and (b) each indicate a percentage with respect to the length from the first surface 101 of the glass substrate 10 to the second surface 102 thereof.

The shape of the through hole 12 shown in FIG. 2 has a structure that is almost symmetrical up and down at the position of scale 50%. In the method for measuring the inclination angles of the side surface of the through hole 12, a center line TC is drawn at the central portion of an opening on the first surface 101 side of the glass substrate 10 so as to be perpendicular to the first surface 101, in the section of 5% to 50% in distance from the first surface 101, as shown in FIG. 2(a). Next, the center line TC is translated toward either sides of the through hole 12 as shown by an arrow and is brought into contact with the point where the diameter of the through hole 12 is at its minimum value, and the point of contact is set as a reference point RP. Then, tangents ss are drawn that are straight lines connecting the reference point RP to cross-sectional positions at heights of each of scale positions of 5% to 50%, and the inclination angles of each tangent ss are measured and defined as the inclination angles at each of the cross-sectional positions of 5% to 50%. The inclination angle is positive in the direction in which the diameter of the through hole 12 expands either upward or downward.

Similarly, in the section of 50% to 95% in distance from the first surface 101, as shown in FIG. 2(b), a center line TC is drawn at the central portion of an opening on the second surface 102 side of the glass substrate 10 so as to be perpendicular to the second surface 102. Next, as shown by an arrow, the center line TC is translated toward either side of the through hole 12 and is brought into contact with the point where the diameter of the through hole 12 is at its minimum value, and the point of contact is set as the reference point RP. Then, tangents ss are drawn from the reference point RP to the cross-sectional positions at the heights of each of the scale positions of 50% to 95%, and the inclination angles of the tangents ss are measured. In the 5% to 50% section in FIG. 2(a), the direction from the translated center line TC toward the tangent ss is defined as positive when this direction is clockwise as viewed on the paper. Contrarily, in the region of 50% to 95% in FIG. 2(b), the direction from the translated center line TC toward the tangent ss is counterclockwise as viewed on the paper, and the inclination angle is therefore expressed as a negative value.

### (Method for Measuring Side Surface Roughness)

Next, a method for measuring a side surface roughness of the through hole 12 will be described. To measure the side surface roughness of the through hole 12, the cross section of the through hole 12 is observed by SEM, as in the measurement of the side surface angle, and the observed SEM image is analyzed using image analysis software. To measure the side surface roughness of the through hole, the measurement range is normally the range from the first surface 101 to the second surface 102 of the through hole. However, if there are projections and recesses in the through hole, two or more ranges excluding the parts of the projections and recesses are set as measurement ranges, and the results of these measurement ranges are averaged to determine the side surface roughness. In calculating the side surface roughness, the same measurements are made on five through holes (sample number n=5) created under the same conditions, and the average value is defined as the side surface roughness of the through hole created under the conditions.

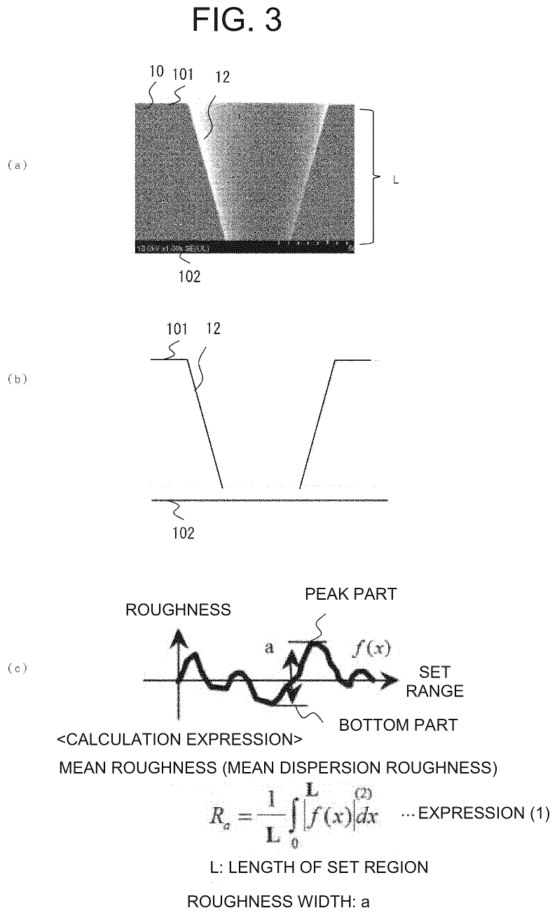

FIG. 3 is a diagram showing a method for measuring the side surface roughness of a through hole. FIG. 3(a) shows a SEM image of the cross section of the through hole 12. FIG. 3(b) shows a diagram in which the contour of the side surface of the through hole 12 is extracted from the SEM image obtained by observation of the cross section of the through hole 12. The mean dispersion roughness and unevenness width are measured from the extracted contour data. FIG. 3(c) is a diagram schematically showing the calculation expression for the mean dispersion roughness and the unevenness width. For the contour data extracted in FIG. 3(b), a roughness curve f(x) showing the roughness of the contour is measured in a set region L set based on the first surface 101. As shown in Expression (1), the mean dispersion roughness (hereinafter simply referred to as “dispersion roughness”) Ra is obtained by integrating the squared absolute value of a roughness curve f(x) over the set region L and then dividing it by the length of the set region L. The roughness width (hereinafter also referred to as the “unevenness width”) a is the difference between the peak part showing the maximum roughness value and the bottom part showing the minimum roughness value of the roughness curve f(x).

When a plurality of roughness curves f(x) are set for one through hole, the average roughness of the through hole is calculated by averaging the roughness values calculated from them.

### (Method for Measuring Transmission Characteristics)

To measure the transmission characteristics, an S parameter (S21) is used that shows the frequency dependency of the degree of propagation wave with respect to the input wave. S21 is expressed as a logarithm of the power ratio (transmitted wave power/input wave power), and a smaller absolute value indicates a smaller transmission loss.

A network analyzer was used to measure the S parameter (S21). For a measurement sample, a sample was manufactured in which the periphery of the through electrode 11 formed on the glass substrate was surrounded by a conductor and the conductor was grounded. With this sample, S21s were measured between the first surface 101 side and the second surface 102 side of the through electrode 11.

### Examples and Comparative Examples According to First Embodiment

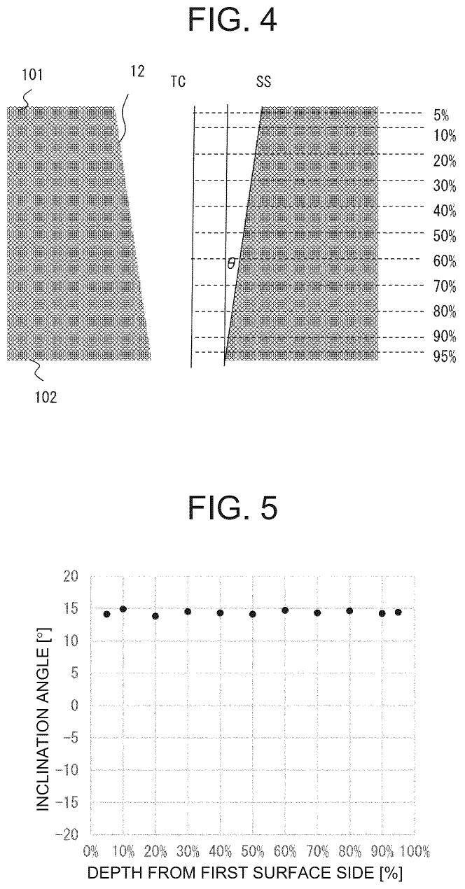

Next, the shape of the through hole 12 in the first embodiment will be described with reference to FIG. 4. FIG. 4 is a diagram showing a cross section of the truncated cone-shaped through hole 12 and a method for measuring inclination angles. In the first embodiment, as shown in FIG. 23 described later, the glass substrate 10 in which laser modified portions 65 are formed is etched from the first surface 101 side of the glass substrate 10. As a result, the formed through hole 12 has a truncated cone shape with a diameter that narrows from the first surface 101 toward the second surface 102. The inclination angles of the side surface of the through hole 12 vary depending on the laser processing conditions and etching conditions for the glass substrate 10.

In each Example of the present invention, the glass substrate is subjected to laser processing under the irradiation conditions of pulse width and number of shots shown in Table 1, and the through hole 12 is then formed by etching. In Example 1 of the first embodiment, the pulse width is 5 ps and the number of shots is 1, in Example 2 the pulse width is 15 ps and the number of shots is 1, and in Example 3 the pulse width is 25 ps and the number of shots is 1.

In addition, the Comparative Examples are through holes created by changing the producing method and laser processing method shown in the first embodiment. In other words, in Comparative Example 1 the pulse width is 30 ps and the number of shots is 1, in Comparative Example 2 the pulse width is 30 ns and the number of shots is 50, and in Comparative Example 3 the pulse width is 50 us and the number of shots is 5.

All of the Examples and Comparative Examples each had an average opening diameter of 80 μm on the second surface 102 side of the glass substrate 10, and had a 3σ of 4.5 μm or less in this case, the 3σ being the average of the measured values plus three times the standard deviation. In addition, the formed laser modified portions 65 each had an opening diameter on the second surface 102, the opening diameter having a difference of 10 μm or less between its maximum opening diameter φ_{Max} and its minimum opening diameter φ_{Min}.

TABLE 1

| | Example | Example | Example | Comparative | Comparative | Comparative |
|---|---|---|---|---|---|---|
| | 1 | 2 | 3 | Example 1 | Example 2 | Example 3 |
| Pulse | 5 ps | 15 ps | 25 ps | 30 ps | 30 ns | 50 μs |
| width | | | | | | |
| Number | 1 | 1 | 1 | 1 | 50 | 5 |
| of shots | | | | | | |

### (Inclination Angle of Through Hole)

The following describes the shapes and characteristic shapes of the through holes of the Examples and Comparative Examples in the first embodiment with reference to FIGS. 5 to 13.

FIG. 5 is a diagram showing measurement results of inclination angles of a through hole of Example 1 in the first embodiment.

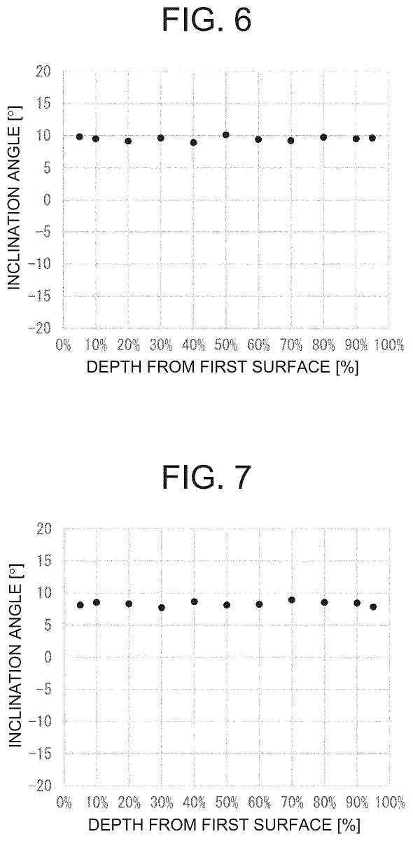

FIG. 6 is a diagram showing measurement results of inclination angles of a through hole of Example 2 in the first embodiment.

FIG. 7 is a diagram showing measurement results of inclination angles of a through hole of Example 3 in the first embodiment.

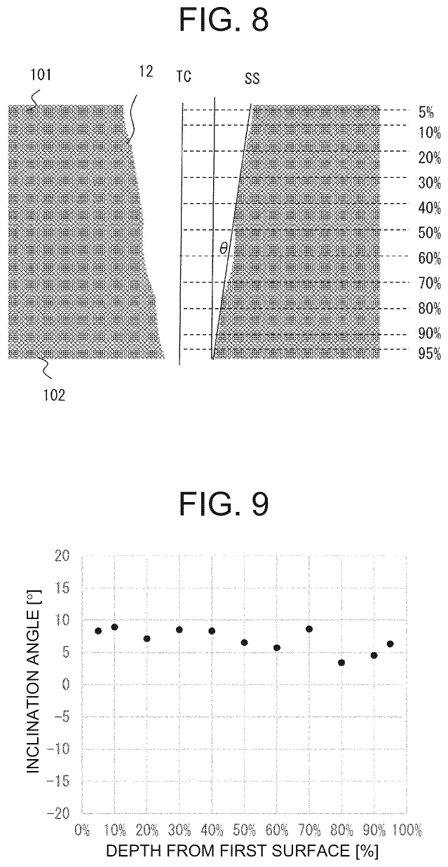

FIG. 8 is a diagram showing a cross-sectional shape of a through hole of Comparative Example 1 in the first embodiment.

FIG. 9 is a diagram showing measurement results of inclination angles of the through hole of Comparative Example 1 in the first embodiment.

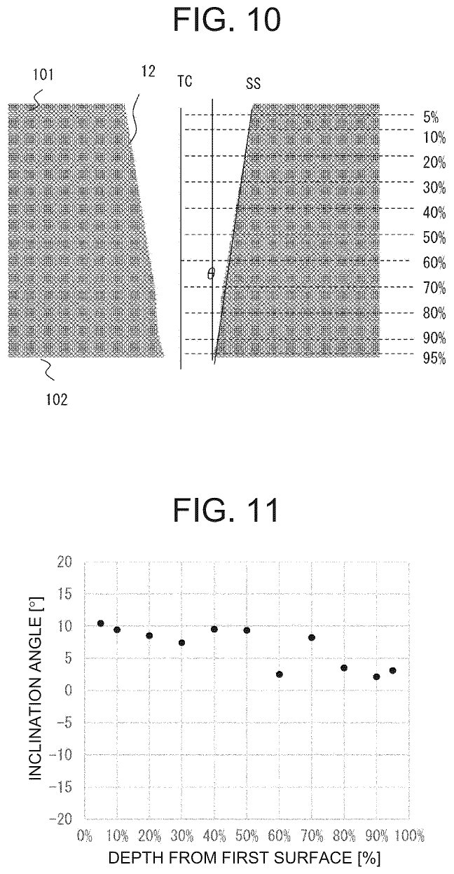

FIG. 10 is a diagram showing a cross-sectional shape of a through hole of Comparative Example 2 in the first embodiment.

FIG. 11 is a diagram showing measurement results of inclination angles of the through hole of Comparative Example 2 in the first embodiment.

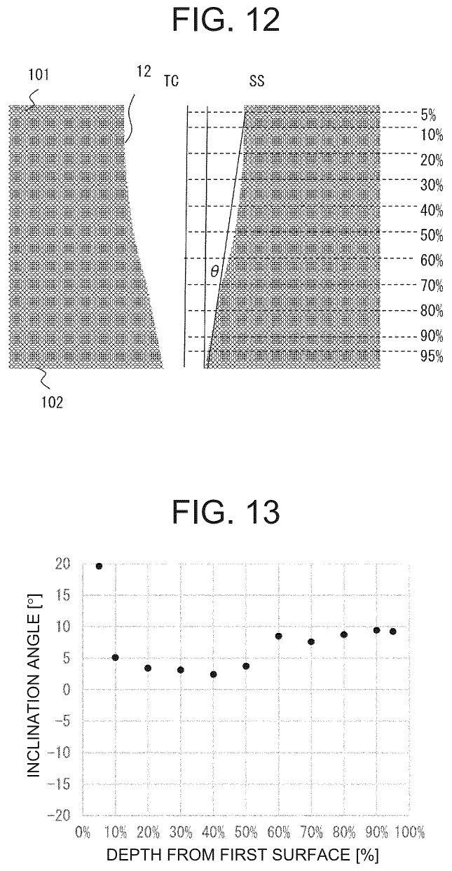

FIG. 12 is a diagram showing a shape of a through hole of Comparative Example 3 in the first embodiment.

FIG. 13 is a diagram showing measurement results of inclination angles of the through hole of Comparative Example 3 in the first embodiment.

### (Inclination Angle)

Table 2 summarizes, in a tabular form, measurement results of the inclination angles of the side surfaces of the through holes 12 in each Example and each Comparative Example in the first embodiment. In each Example in the first embodiment, the inclination angles are almost constant at each of the cross-sectional positions of 5% to 95% of the through hole 12. Each Comparative Example in the first embodiment demonstrates that the inclination angles of the side surface vary at each position of 5% to 95%.

TABLE 2

| | Example | Example | Example | Comparative | Comparative | Comparative |
|---|---|---|---|---|---|---|
| | 1 | 2 | 3 | Example 1 | Example 2 | Example 3 |
| 5% | 14.1 | 9.8 | 8.1 | 8.3 | 10.4 | 19.6 |
| 10% | 14.9 | 9.5 | 8.5 | 8.9 | 9.4 | 5.1 |
| 20% | 13.8 | 9.1 | 8.3 | 7.1 | 8.5 | 3.4 |
| 30% | 14.5 | 9.6 | 7.7 | 8.5 | 7.4 | 3.1 |
| 40% | 14.3 | 8.9 | 8.6 | 8.3 | 9.5 | 2.4 |
| 50% | 14.1 | 10.1 | 8.1 | 6.5 | 9.3 | 3.7 |
| 60% | 14.7 | 9.4 | 8.2 | 5.7 | 2.5 | 8.5 |
| 70% | 14.3 | 9.2 | 8.9 | 8.6 | 8.2 | 7.6 |
| 80% | 14.6 | 9.7 | 8.5 | 3.4 | 3.5 | 8.7 |
| 90% | 14.2 | 9.5 | 8.4 | 4.5 | 2.1 | 9.4 |
| 95% | 14.4 | 9.6 | 7.8 | 6.3 | 3.1 | 9.2 |

Unit: °

### (Mean Dispersion Roughness and Unevenness Width)

Next, the mean dispersion roughnesses and unevenness widths of the side surfaces of the through holes 12 will be described with reference to Table 3 for each Example and each Comparative Example in the first embodiment. As shown in Table 3, each Example of the first embodiment has a dispersion roughness of 1,000 nm or less and an unevenness width of 1,500 nm or less, in the side surface shape of the cut surface of the through hole 12 in the thickness direction of the glass substrate. Each Comparative Example has a dispersion roughness of 1,500 nm or more and an unevenness width of 1,500 nm or more. These demonstrate that there is a difference in the roughnesses of the through hole side surfaces.

TABLE 3

| | Example | Example | Example | Comparative | Comparative | Comparative |
|---|---|---|---|---|---|---|
| | 1 | 2 | 3 | Example 1 | Example 2 | Example 3 |
| Dispersion | 31.6 nm | 563.6 nm | 994.5 nm | 1587.6 nm | 1685.3 nm | 1789.5 nm |
| roughness | | | | | | |
| Unevenness | 354.6 nm | 1083.1 nm | 1294.5 nm | 1659.1 nm | 1689.1 nm | 1985.4 nm |
| width | | | | | | |

### (Transmission Characteristics)

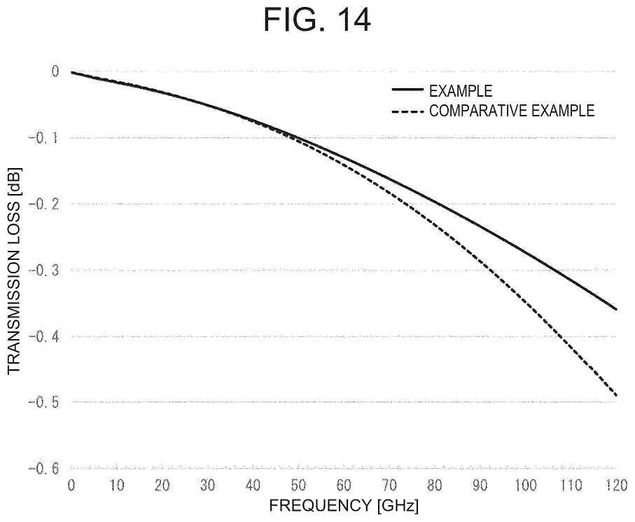

The following describes the transmission characteristics of the through electrode of each Example and each Comparative Example in the first embodiment with reference to FIG. 14. FIG. 14 is a diagram showing transmission characteristics of the through electrode of Example 1 and transmission characteristics of the through electrode of Comparative Example 1 in the first embodiment. In FIG. 14, the transmission characteristics are shown as the results of measuring a transmission loss S21. The transmission characteristics of Examples 1 to 3 showed the same tendency, and Example 1 is shown as a representative. The transmission characteristics of Comparative Examples 1 to 3 also showed almost the same tendency, and Comparative Example 1 is shown as a representative.

Note that the formation conditions for the formation of the seed layer and plating processing for forming the electrodes in the through holes were the same in both the Examples and Comparative Examples. As shown in FIG. 14, the transmission loss of the Example is smaller than that of the Comparative Example in all frequency regions. This shows that as the side surface of the through hole has smaller values of dispersion roughness and unevenness width, the loss is smaller and the transmission characteristics are more excellent, in the through electrode formed in the through hole.

(Transmission Characteristics when Thickness of Glass Substrate is Changed)

Transmission characteristics S21 were also measured when the thickness of the glass substrate 10 was changed for each Example and each Comparative Example. The results are shown in Table 4. As shown in Table 4, the thicknesses of the glass substrates 10 were set to 100 μm, 150 μm, and 200 μm, the through holes and the through electrodes were created under conditions based on each Example and each Comparative Example, and the transmission characteristics were measured. Table 4 shows that all the Examples in the first embodiment have more excellent transmission characteristics S21 than any of Comparative Examples therein.

Note that: the transmission characteristics shown in Table 4 are the transmission characteristics of a single through electrode; and in a multilayer wiring substrate that requires a plurality of through electrodes, improving the transmission characteristics of a single through electrode leads to a significant performance improvement. Using each Example according to the first embodiment makes it possible to obtain a multilayer wiring substrate that achieves excellent transmission characteristics of the through electrode in a high frequency band compared to existing techniques.

TABLE 4

| | | Example 1 | | Example 2 | | Example 3 | |
|---|---|---|---|---|---|---|---|
| | Glass | Measured | | Measured | | Measured | |
| Frequency | thickness | value | Determination | value | Determination | value | Determination |
| 5 GHZ | 100 μm | 0.0079 | Good | 0.0082 | Good | 0.0087 | Good |
| | 150 μm | −0.0083 | Good | −0.0087 | Good | −0.0094 | Good |
| | 200 μm | −0.0091 | Good | −0.0101 | Good | −0.0106 | Good |
| 10 GHz | 100 μm | −0.0140 | Good | −0.0148 | Good | −0.0154 | Good |
| | 150 μm | 0.0145 | Good | 0.0156 | Good | 0.0165 | Good |
| | 200 μm | −0.0161 | Good | −0.0189 | Good | −0.0189 | Good |
| 20 GHz | 100 μm | 0.0293 | Good | 0.0302 | Good | 0.0309 | Good |
| | 150 μm | −0.0288 | Good | −0.0298 | Good | −0.0315 | Good |
| | 200 μm | −0.0312 | Good | −0.0379 | Good | −0.0352 | Good |
| 28 GHz | 100 μm | −0.0442 | Good | −0.0456 | Good | −0.0463 | Good |
| | 150 μm | 0.0441 | Good | 0.0450 | Good | 0.0468 | Good |
| | 200 μm | −0.0486 | Good | −0.0595 | Good | −0.0537 | Good |
| 56 GHz | 100 μm | 0.0851 | Good | 0.0914 | Good | 0.1040 | Good |
| | 150 μm | −0.0976 | Good | −0.1013 | Good | −0.1160 | Good |
| | 200 μm | 0.1094 | Good | 0.1213 | Good | 0.1340 | Good |
| 84 GHz | 100 μm | −0.1891 | Good | −0.2014 | Good | −0.2114 | Good |
| | 150 μm | 0.2004 | Good | 0.2212 | Good | 0.2114 | Good |
| | 200 μm | −0.2114 | Good | −0.2421 | Good | −0.2114 | Good |
| | | Comparative Example 1 | | Comparative Example 2 | | Comparative Example 3 | |
| | Glass | Measured | | Measured | | Measured | |
| Frequency | thickness | value | Determination | value | Determination | value | Determination |
| 5 GHZ | 100 μm | 0.0090 | | 0.0090 | | 0.0090 | |
| | 150 μm | −0.0098 | — | −0.0099 | — | −0.0099 | — |
| | 200 μm | −0.0111 | — | −0.0112 | — | −0.0112 | — |
| 10 GHz | 100 μm | −0.0157 | — | −0.0157 | — | −0.0157 | — |
| | 150 μm | 0.0169 | | 0.0170 | | 0.0170 | |
| | 200 μm | −0.0193 | — | −0.0194 | — | −0.0194 | — |
| 20 GHz | 100 μm | 0.0314 | | 0.0314 | | 0.0314 | |
| | 150 μm | −0.0321 | — | −0.0321 | — | −0.0321 | — |
| | 200 μm | −0.0357 | — | −0.0358 | — | −0.0358 | — |
| 28 GHz | 100 μm | −0.0469 | — | −0.0469 | — | −0.0469 | — |
| | 150 μm | 0.0471 | | 0.0471 | | 0.0471 | |
| | 200 μm | −0.0542 | — | −0.0544 | — | −0.0544 | — |
| 56 GHz | 100 μm | 0.1337 | | 0.1457 | | 0.1517 | |
| | 150 μm | −0.1537 | — | −0.1875 | — | −0.1915 | — |
| | 200 μm | 0.1854 | | 0.1984 | | 0.2184 | |
| 84 GHz | 100 μm | −0.2527 | — | −0.2727 | — | −0.2827 | — |
| | 150 μm | 0.2827 | | 0.3127 | | 0.3193 | |
| | 200 μm | −0.3027 | — | −0.3374 | — | −0.3474 | — |

### (Cross-Sectional Shape)

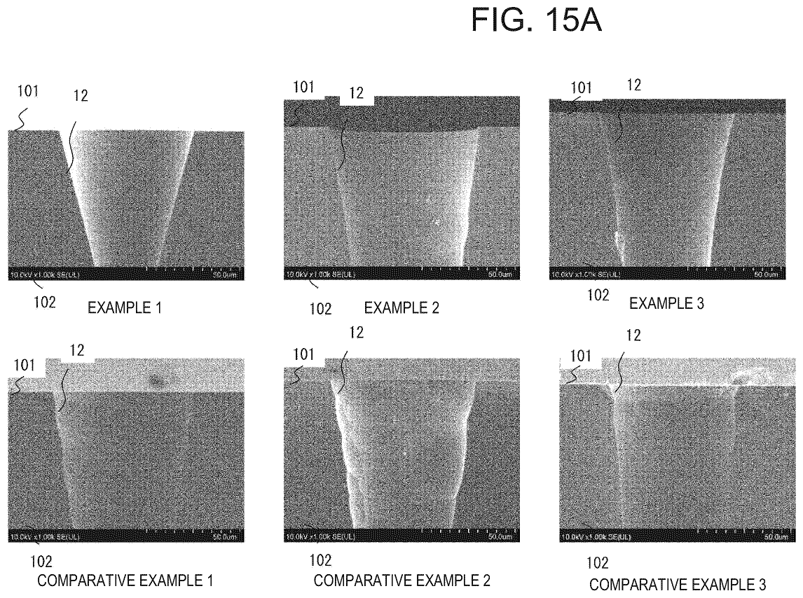

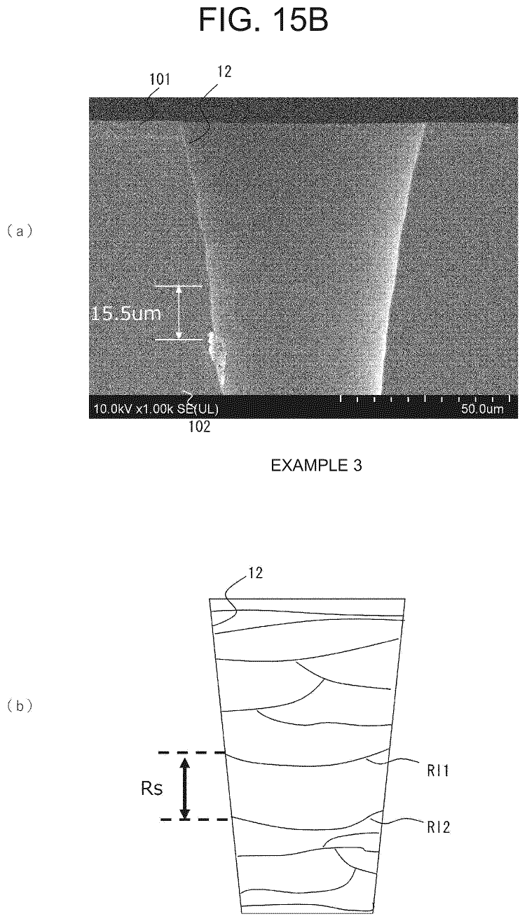

Next, the side surface shape of the through hole 12 will be described. FIG. 15A is a diagram describing the side surfaces of the through holes for each Example and Comparative Example of the first embodiment. FIG. 15A is a diagram showing SEM images of cross sections of the through holes of each Example and each Comparative Example in the first embodiment.

Each SEM image is obtained by photographing the cut surface of a through hole in the thickness direction of the glass substrate. The SEM images shown in FIG. 15A are at a magnification of 1000 times (one division of the scale is 5 μm).

In the SEM image, the areas that have high contrast and appear white are each a region where the angle of the inclined surface of the sample surface changes to form a ridgeline on the inclined surface. For this reason, the areas that appear as white lines each indicate either a peak or a bottom of the roughness on the sample surface, and the state of presence and degree of placement of the ridgelines formed on the side surface of these through holes makes it possible to understand the roughness of the side surface of the through hole, which affects the transmission characteristics of the through electrode.

In each Example of the first embodiment shown in FIG. 15A, a plurality of white ridgelines appear and can be seen that extend in a direction parallel or substantially parallel to the first surface 101 of the glass substrate 10, forming a band-like striped pattern.

Now, with reference to FIG. 15B, the ridgelines of the cross section of the through hole will be described. FIG. 15B is a diagram describing the ridgelines of the through hole in each Example of the first embodiment. FIG. 15B (a) is an enlarged view of Example 3 in FIG. 15A. FIG. 15B (b) is a diagram indicating the ridgelines of the side surface and cross section by solid lines in the observed through hole in the SEM image.

In the example shown in FIG. 15B (b), the widest space between ridgelines among the substantially parallel ridgelines is between a ridgeline Rl1 and a ridgeline Rl2. In the example shown in FIG. 15B (b), the space between the ridgelines on the side surface is less than or equal to Rs in a direction perpendicular to the first surface 101. As shown in FIG. 15B (a), in Example 3, the space between the ridgelines is 15.5 μm or less.

When the state of the ridgelines is observed in the same manner, in Example 1, the space between the ridgelines in the direction perpendicular to the first surface 101 is in a range of 2 μm to 3 μm inclusive. In Example 2, the space between the ridgelines in the direction perpendicular to the first surface 101 of the glass substrate 10 is in a range of 5 μm to 6 μm inclusive.

As is clear from FIG. 15A, as the first embodiment changes from Example 3 toward Example 1, that is, as the dispersion roughness, which is the smoothness of the side surface of the through hole, decreases, the side surface of the through hole 12 is denser with the white lines, which can be seen as ridgelines extending in a direction parallel to the first surface 101 of the glass substrate 10, and has a narrower space between the ridgelines. Conversely, as the dispersion roughness increases (i.e., as the sample changes from Example 1 to Example 3, and further from Comparative Example 1 to Comparative Example 3), the space between the ridgelines increases and the number of ridgelines extending in a direction that is not parallel to the first surface 101 also increases. Furthermore, it can be seen that the occurrence frequency of the following ridgelines increases: ridgelines extending in a direction perpendicular to the first surface 101; and ridgelines extending in a direction between the direction parallel to the first surface 101 and the direction perpendicular to the first surface 101 (hereinafter also referred to as a “diagonal direction”). This indicates that the ratio of ridgelines extending in a vertical direction and ridgelines extending in the diagonal direction decreases as the dispersion roughness decreases. For example, in Example 2, when the mean dispersion roughness is 500 nm and the unevenness width is 980 nm, white lines can be seen that extend in a direction between a direction parallel to the first surface 101 and a direction perpendicular to the first surface 101 (i.e., the diagonal direction).

On the other hand, when the side surface of the through hole is rougher (when the mean dispersion roughness is greater than 1,000 nm and the unevenness width is greater than 1,500 nm) as in Comparative Examples 1 to 3 in the first embodiment, the ratio of white lines increases that extend in a direction perpendicular to the first surface 101 of the glass substrate 10 or in a direction between a direction perpendicular to the first surface 101 and a direction parallel to the first surface 101. In other words, a plurality of ridgelines can be seen in the diagonal direction. It can be seen that the smoothness (roughness) of the side surface of the through hole 12 appears in the SEM image, and affects the transmission characteristics of the through electrode.

In terms of transmission characteristics, the through electrodes shown in Examples 1 to 3 provide more excellent results than the through electrodes shown in Comparative Examples 1 to 3. Comparison of the Examples demonstrates that Example 1 is the most preferable, followed by Example 2 and Example 3 in this order.

### <Configuration of Multilayer Wiring Substrate According to First Embodiment>

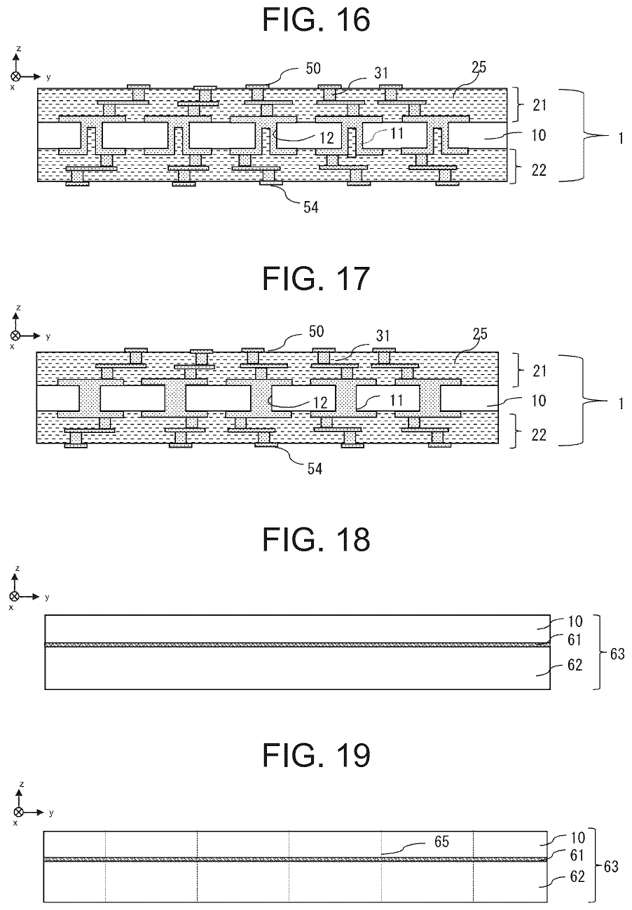

FIG. 16 is a diagram showing an example of a configuration of a multilayer wiring substrate according to the first embodiment. FIG. 17 is a diagram showing another example of a configuration of the multilayer wiring substrate according to the first embodiment. A multilayer wiring substrate 1 includes a glass substrate 10, a first wiring layer 21, and a second wiring layer 22. The first wiring layer 21 is disposed on the first surface 101 side of the glass substrate 10, and the second wiring layer 22 is disposed on the second surface 102 side of the glass substrate 10. The glass substrate 10 includes the through holes 12 penetrating from the first surface 101 side to the second surface 102 side. Each through electrode 11 is formed of a conductor formed along the side surface of the through hole 12. The through electrode 11 electrically connects part of the first wiring layer 21 and part of the second wiring layer 22. The first wiring layer 21 and the second wiring layer 22 each include an insulating resin layer 25.

The first wiring layer 21 and the second wiring layer 22 may also be configured with a plurality of layers laminated, and the number of layers may be set as necessary. The through electrode 11 is an electrode for establishing an electrical connection between the first wiring layer 21 and the second wiring layer 22. The conductive electrodes 31 are each an electrode for ensuring electrical continuity in the thickness direction of the multilayer wiring substrate 1. Semiconductor power device joining pads 50 are members for connecting semiconductor circuits to be mounted on the multilayer wiring substrate 1. Substrate joining pads 54 are members for joining the multilayer wiring substrate 1 to another substrate or another semiconductor power device.

As long as the through electrode can electrically connect the first surface 101 side to the second surface 102 side of the glass substrate 10, a conductor may be disposed only on the side surface of the through hole 12 as shown in FIG. 16, or a conductor may be embedded in the through hole 12 as shown in FIG. 17.

Note that the shapes of the through holes 12 are shown with details omitted in FIGS. 16 and 17. Similarly, the detailed shapes thereof are omitted in FIGS. 18 to 27.

The thickness of the multilayer wiring substrate 1 is, for example, in a range of 100 μm to 400 μm inclusive.

### <Method for Producing Multilayer Wiring Substrate in First Embodiment>

The method for producing the multilayer wiring substrate 1 in the first embodiment will be described with reference to FIGS. 18 to 27. First, a step of forming the through holes 12 in the glass substrate 10 will be described.

### [Bonding Step of First Support]

FIG. 18 is a diagram showing a step of bonding the glass substrate 10 to a first support 62. The thickness of the glass substrate 10 can be set appropriately depending on the application, taking into account the thickness after etching.

Here, the thickness of the glass substrate 10 can be set appropriately depending on the application, taking into account the thickness of the glass substrate 10 after an etching step for forming the through holes.

The glass substrate 10 can use, for example, alkali-free glass with a SiO₂ ratio in a range of 55 mass % to 81 mass % inclusive. If the SiO₂ ratio of the glass substrate 10 is greater than 81 mass %, the processing rate of etching decreases, the flatness of the angle of the side surface of the through hole 12 decreases, and poor adhesion may occur in forming the through electrode 11, which will be described later. If the SiO₂ ratio is less than 55 mass %, alkali metals are highly likely to be contained in the glass, which will affect the reliability of the multilayer wiring substrate after the electronic device is mounted.

As shown in FIG. 18, the glass substrate 10 and the first support 62 are bonded together at a first bonding layer 61, and a laminated structure 63 is formed that includes the glass substrate 10, the first bonding layer 61, and the first support 62.

Note that the glass substrate 10 and the first support 62 are temporarily fixed by the first bonding layer 61.

To bond the first support to the glass substrate 10, for example, a laminator, a vacuum pressure press, a reduced pressure bonding machine, or the like can be used.

The first support 62 is desirably made of the same material as the glass substrate 10, for example. When the glass substrate 10 is made of alkali-free glass with a SiO₂ ratio in the range of 55 mass % to 81 mass % inclusive, it is desirable that the first support 62 be also made of alkali-free glass. The thickness of the first support 62 can be set appropriately depending on the thickness of the glass substrate 10. However, the thickness of the first support 62 is desirably such that the first support 62 can be transported during the step of producing, and the thickness of the first support 62 is, for example, in a range of 300 μm to 1,500 μm inclusive.

### [Laser Modification Step]

Next, FIG. 19 is a diagram showing a step of forming a laser modified portions. Laser modified portions 65 are formed in the glass substrate 10 by irradiating the portions of the glass substrate 10 where through holes are to be formed with a laser. Each laser modified portion 65 is formed in the glass substrate 10 with a shape of Φ3 μm or less, and is formed continuously in the thickness direction of the glass substrate 10. At this time, it is desirable that there occur no fine cracks (hereinafter also referred to as “microcracks”) of 5 μm or more around the laser modified portion 65 (hereinafter also referred to as a “peripheral portion of the laser irradiation”). When microcracks of 5 μm or more occur around the laser modified portion 65, the dispersion roughness of the side surface of the through hole 12 after etching will be 1000 nm or more, and the unevenness width thereof will be 1500 nm or more. This makes it difficult to obtain the through hole 12 with a smooth side surface.

When microcracks of 5 μm or more occur, the SEM image of the side surface of the through hole 12 after etching visibly shows not only the ridgelines extending in a direction parallel to the first surface 101 of the glass substrate 10, but also ridgelines extending in a direction perpendicular to the first surface 101 and ridgelines extending in a direction between the direction parallel to the first surface 101 and the direction perpendicular to the first surface 101, as is described later.

For processing the laser modified portion 65, it is preferable to use, for example, a femtosecond laser or a picosecond laser, and to use a laser emission wavelength of any one of 1064 nm, 532 nm, and 355 nm. If the laser pulse width is 25 picoseconds or more, microcracks of 5 μm or more are likely to occur around the laser modified portion 65. For this reason, the laser pulse width is desirably 25 picoseconds or less. In addition, since microcracks are likely to occur if processing is performed by a plurality of times of pulse irradiation, the laser modified portion 65 is desirably formed by one pulse. Under the condition that does not generate microcracks of 5 μm or more around the laser modified portion 65, the laser emission wavelength and laser output may be appropriately set depending on the thickness of the glass substrate 10. In other words, in the laser modification step (first step), the glass substrate is irradiated with a laser at the portion where the through hole is to be formed, and the microcracks that occur in a peripheral portion of the laser irradiation have a maximum length of 5 μm.

### [Formation of the First Wiring Layer]

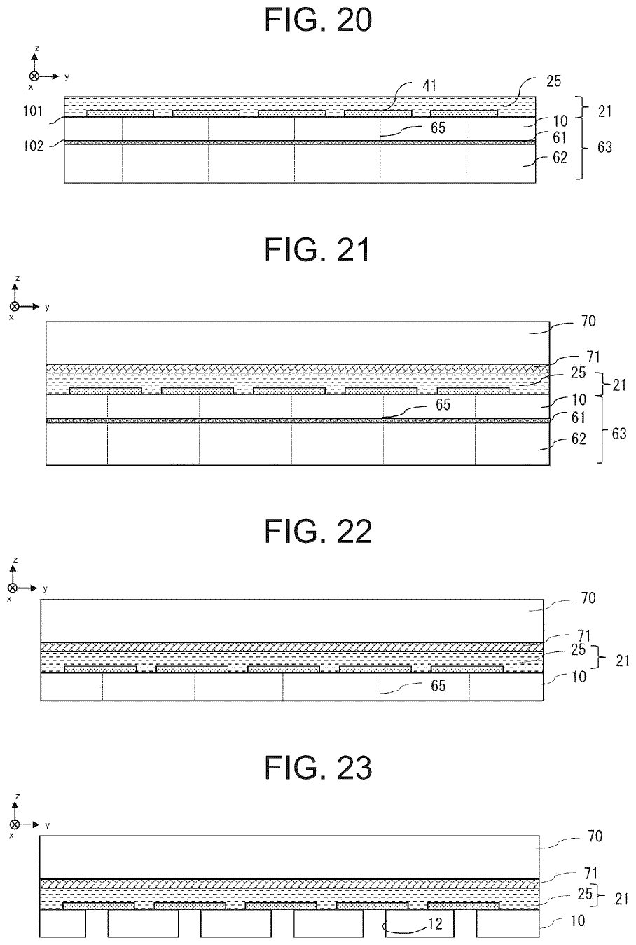

Next, FIG. 20 is a diagram showing a step of forming the first wiring layer 21. As shown in FIG. 20, the first wiring layer 21 consisting of a conductive layer and an insulating resin layer is formed on the first surface 101 of the glass substrate 10 of the laminated structure 63. Here, a seed layer including a hydrofluoric acid resistant metal layer is formed on the glass substrate 10, and then through electrode connection portions 41 (or wiring between the through electrodes) are formed on the first surface 101 through a semi-additive process (SAP). The unnecessary seed layer is removed, and then the insulating resin layer 25 is formed.

In the formation of the seed layer, the hydrofluoric acid resistant metal layer on the glass substrate 10 is an alloy layer containing chromium, nickel, or both, and can be formed in a range of 10 nm to 1,000 nm inclusive by sputtering processing. After that, a conductive metal film is formed to the desired thickness on the hydrofluoric acid resistant metal. The conductive metal film can be appropriately set from, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, and Cu₃N₄.

In the semi-additive process, a photoresist is used to form a desired pattern to form a wiring pattern by plating. Generally, a dry film resist is used, but a liquid resist can also be used. The desired pattern is formed through exposure and development, a plating film is then formed through electrolytic plating, the unnecessary resist is peeled, and the seed layer is etched, thereby making it possible to form wiring.

### [Insulating Resin Layer]

Next, in the formation of the insulating resin layer 25, the insulating resin layer 25 is made of thermosetting resin, and the material thereof is a material that contains at least one of epoxy resin, polyimide resin, and polyamide resin, and that contains silica SiO₂ filler. The material of the insulating resin layer 25 can be appropriately selected as necessary. However, when a photosensitive insulating resin material is used, filling the silica SiO₂ filler is difficult for ensuring photolithography properties. For this reason, a photosensitive insulating resin material can also be used, but it is more preferable to use thermosetting resin.

### [Bonding Step of Second Support]

Next, FIG. 21 is a diagram showing a step of bonding a second support. As shown in FIG. 21, a second bonding layer 71 is formed on the first wiring layer 21 of the laminated structure 63, and a second support 70 is placed and bonded on the second bonding layer 71.

The second support 70 can use, for example, glass, and is desirably made of the same material as the glass substrate 10. When the glass substrate 10 is alkali-free glass, the second support 70 is also desirably made of alkali-free glass. The thickness of the second support 70 can be set appropriately depending on the thickness of the glass substrate 10. However, the thickness is desirably such that the second support 70 can be transported, and the thickness is in a range of 300 μm to 1,500 μm inclusive.

### [Peeling Step]

Next, FIG. 22 shows a step of peeling the first support. As shown in FIG. 22, the first support 62 is peeled off the glass substrate 10 at the first bonding layer 61.

### [Formation of Through Holes]

Next, FIG. 23 shows a step of forming the through holes 12.

### [Etching Step]

The glass substrate 10 in which the laser modified portions 65 are formed is subjected to etching processing with a predetermined etching solution to form the through holes 12. At the same time, the second surface of the glass substrate 10 is also etched, and the thickness of the glass substrate 10 decreases. The etching is performed from the second surface 102 side of the glass substrate 10. Therefore, each through hole 12 in the first embodiment has a truncated cone shape whose diameter narrows from the second surface 102 side toward the first surface 101 side.

### [Etching Solution]

The etching solution to be used contains hydrofluoric acid in a range of 0.2 mass % to 20.0 mass % inclusive, nitric acid in a range of 4.0 mass % to 25.0 mass % inclusive, and inorganic acid other than hydrofluoric acid and nitric acid in a range of 0.5 mass % to 11.0 mass % inclusive. Examples of inorganic acids other than hydrofluoric acid and nitric acid include hydrochloric acid, sulfuric acid, phosphoric acid, and sulfamic acid. At least one inorganic acid is contained depending on the type of components other than silicon contained in the glass substrate 10. Desirably, the etching solution contains hydrochloric acid and sulfuric acid. The etching rate for the glass substrate 10 is appropriately adjusted to be in a range of 0.1 μm/min to 10 μm/min inclusive. The etching rate for the glass substrate 10 is desirably in a range of 0.25 μm/min to 4 μm/min inclusive, and more desirably in a range of 0.25 μm/min to 0.5 μm/min inclusive. The etching temperature is not particularly limited and can be adjusted appropriately, and is, for example, in a range of 10° C. to 30° C. inclusive.

In the step of forming the through holes 12 by etching, the concentration of hydrofluoric acid may be lowered and etching may be performed a plurality of times. An example is such that: the etching rate for the glass substrate 10 in the first etching processing is in a range of 4 μm/min to 10 μm/min inclusive; the etching rate for the glass substrate 10 in the second etching processing is in a range of 0.5 μm/min to 4 μm/min inclusive; and then the etching rate for the glass substrate 10 in the third etching processing is in a range of 0.25 μm/min to 0.5 μm/min inclusive. The number of etching processing times may be set appropriately so that the roughness of the side surface of the through holes falls within the desired range.

### [Formation of Through Electrode]

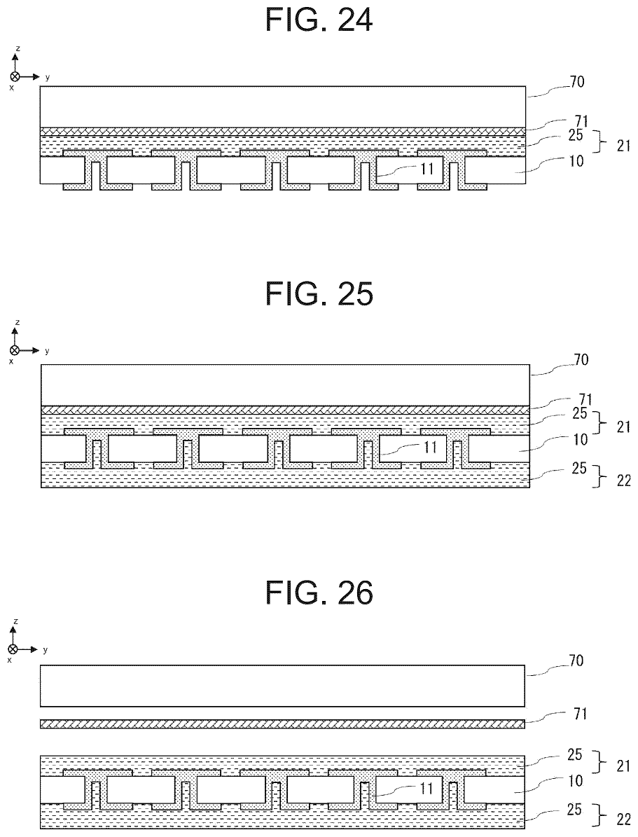

Next, a step of forming the through electrodes 11 will be described with reference to FIG. 24. FIG. 24 is a diagram showing a step of forming the through electrodes 11.

A metal layer for electrolytic plating processing is formed on the second surface 102 of the glass substrate 10 in which the through holes 12 are formed. The metal layer just needs to be made of any metal that functions as a seed layer for electrolytic plating processing, such as metals including Cu, Ti, Cr, W, Ni, or the like. The metal layer uses at least one of the above-mentioned metals. The metal layer desirably has a Cu layer formed on its outermost surface. Ti, Cr, W, and Ni are desirably used as an adhesion layer with the glass substrate 10 under the Cu layer. The thickness of the metal layer is appropriately set to a range that can cover the side surface of each through hole 12. The formation method to be employed can be, for example, a formation method through deposition using sputtering.

Subsequently, the through electrodes 11 are formed by electrolytic plating processing that uses the above-mentioned metal layer as the seed layer. To selectively grow the through holes 12, a mask is formed with an insulator such as a resist on the first surface 101 and the second surface 102 of the glass substrate 10 except for the through holes 12, and then electrolytic plating processing is performed. For a material to be used for electrolytic plating processing, for example, Cu can be used, and other metals including Au, Ag, Pt, Ni, Sn, or the like can also be used. Depending on the application of the multilayer wiring substrate, electrolytic plating processing may be performed so that the through holes 12 are filled with the above-mentioned metal conductors.

### [Formation of Insulating Resin Layer]

A step of forming the insulating resin layer 25 will be described with reference to FIG. 25. FIG. 25 is a diagram showing a step of forming the insulating resin layer. After electrolytic plating processing for forming the through electrodes, the insulator such as a resist is removed, and the metal film is removed that is formed as the seed layer on the second surface 102 of the glass substrate 10. The plurality of through electrodes 11 formed on the glass substrate 10 are electrically isolated from each other, and then the insulating resin layer 25 is formed on the second surface side as shown in FIG. 25.

### [Peeling of Second Support]

The following describes a step of peeling the second support 70 and the second bonding layer 71 with reference to FIG. 26. FIG. 26 is a diagram showing a step of peeling the second support 70 and the second bonding layer 71. As shown in FIG. 26, the second bonding layer 71 and the second support 70 formed above the first wiring layer 21 are peeled off the interface between the first wiring layer 21 and the second bonding layer 71 on the first surface 101 side. As a result, as shown in FIG. 26, a glass substrate 10 is obtained in which the first wiring layer 21 is formed on the first surface 101 side and the second wiring layer 22 is formed on the second surface 102 side.

When the second support 70 is peeled off the second wiring layer 22, a peeling method can be appropriately selected from UV light irradiation, heat treatment, physical peeling, or the like depending on the material used for the second bonding layer 71. In addition, if there is a residue of the second bonding layer 71 on the joining surface between the first wiring layer 21 and the second bonding layer 71, the following may be performed: plasma cleaning, ultrasonic cleaning, water washing, solvent cleaning using alcohol, or the like.

### [Formation of First Wiring Layer and Second Wiring Layer]

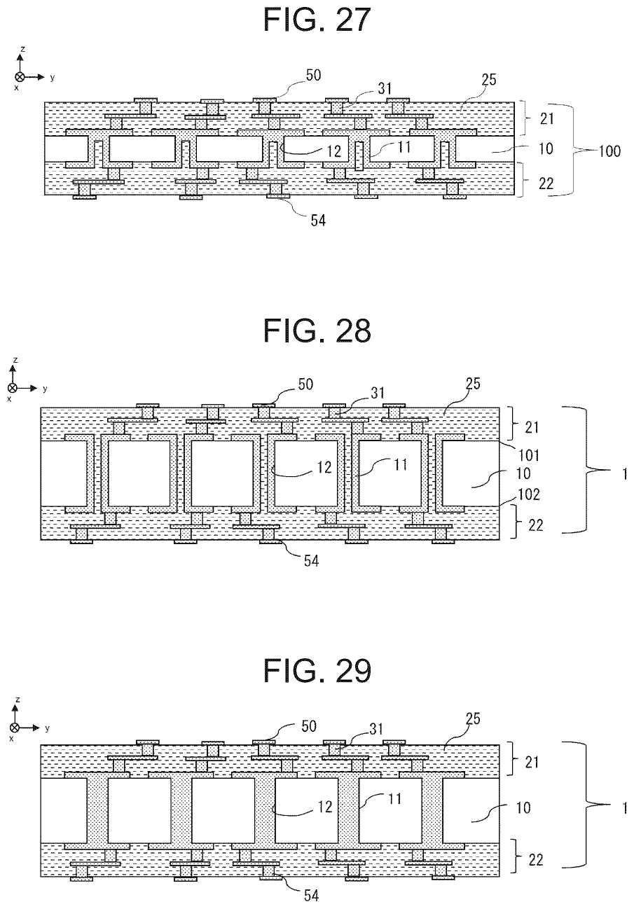

The following describes the formation of the first wiring layer 21 and the second wiring layer 22 formed on the glass substrate 10 with reference to FIG. 27. FIG. 27 is a diagram showing a step of forming the first wiring layer 21 and the second wiring layer 22. For the glass substrate 10 on which the through electrodes 11 are formed, the first wiring layer 21 is formed on the first surface 101, and the second wiring layer 22 is formed on the second surface 102. In the step of forming the first wiring layer 21 and the second wiring layer 22, a mask having a pattern is first formed with a photosensitive resist or a dry film resist, and wiring is then formed by electrolytic plating processing. After that, physical adhesion processing or chemical adhesion processing is performed, and then the insulating resin layer 25 is laminated. For the conductive electrodes 31, holes are formed in the insulating resin layer 25 by laser processing or the like, and then a metal film is formed by electroless plating or deposition processing by sputtering. A mask having a pattern is formed on the above-mentioned metal film using resist, and the holes formed by electrolytic plating are filled with a conductor. The mask and excess metal film are then removed. The above-mentioned step is repeated a plurality of times depending on the number of layers required, to form the first wiring layer 21 and the second wiring layer 22. Note that the first wiring layer 21 and the second wiring layer 22 desirably have the same number of layers in order to prevent warping of the multilayer wiring substrate 1. If the layer thicknesses of the first wiring layer 21 and the second wiring layer 22 are different, the number of layers may be different between the first wiring layer 21 and the second wiring layer 22. The number of layers of the first wiring layer 21 and the number of layers of the second wiring layer 22 may be set appropriately depending on the application of the multilayer wiring substrate.

### <Configuration of Multilayer Wiring Substrate in Second Embodiment>

FIG. 28 is a diagram showing an example of a configuration of a multilayer wiring substrate 1 in a second embodiment. FIG. 29 is a diagram showing another example of a configuration of the multilayer wiring substrate 1 in the second embodiment. The second embodiment differs from the first embodiment in the following points: no conductive electrode 31 is placed on a Z-axis of a through electrode 11 in a first wiring layer 21; and since no support is used in steps of producing the multilayer wiring substrate, etching processing is performed from both a first surface 101 and a second surface 102 of a glass substrate 10, and the through hole shape is formed in an X-shape.

In the second embodiment, the multilayer wiring substrate 1 includes the glass substrate 10, the first wiring layer 21, and a second wiring layer 22. The first wiring layer 21 is disposed on the first surface 101 side of the glass substrate 10, and the second wiring layer 22 is disposed on the second surface 102 side of the glass substrate 10. The glass substrate 10 includes through holes 12 penetrating from the first surface 101 side to the second surface 102 side. Each through electrode 11 is formed of a conductor formed along the side surface of the through hole 12. The through electrode 11 electrically connects part of the first wiring layer 21 and part of the second wiring layer 22. The first wiring layer 21 and the second wiring layer 22 each include an insulating resin layer 25. The first wiring layer 21 and the second wiring layer 22 may also be configured with a plurality of layers laminated, and the number of layers may be set as necessary. The through electrode 11 is an electrode for establishing an electrical connection between the first wiring layer 21 and the second wiring layer 22. The conductive electrodes 31 are each an electrode for ensuring electrical continuity in the thickness direction of the multilayer wiring substrate 1. Semiconductor power device joining pads 50 are members for connecting semiconductor circuits to be mounted on the multilayer wiring substrate 1. Substrate joining pads 54 are members for joining the multilayer wiring substrate 1 to another substrate or another semiconductor power device.

As long as the through electrode can electrically connect the first surface 101 side to the second surface 102 side of the glass substrate 10, a conductor may be disposed only on the side surface of the through hole 12 as shown in FIG. 28, or a conductor may be embedded in the through hole 12 as shown in FIG. 29.

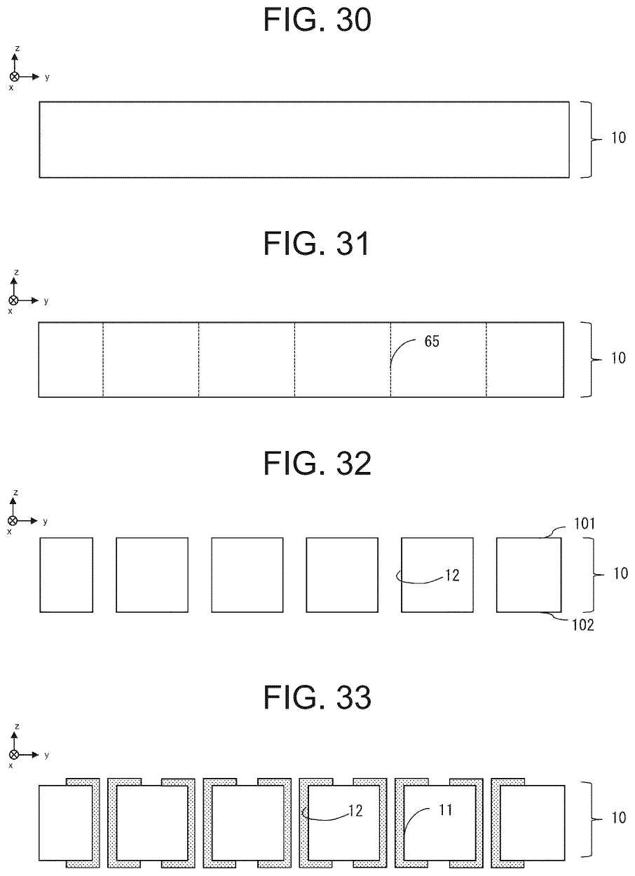

Note that the shapes of the through holes 12 are shown with details omitted in FIGS. 28 and 29. Similarly, the detailed shapes thereof are omitted in FIGS. 30 to 34.

The thickness of the multilayer wiring substrate 1 is, for example, in a range of 100 μm to 400 μm inclusive.

### <Method for Producing Multilayer Wiring Substrate in Second Embodiment>

Next, a method for producing the multilayer wiring substrate 1 will be described with reference to FIGS. 30 to 34. First, a step of forming the through holes 12 in the glass substrate 10 will be described.

### [Glass Substrate]

FIG. 30 shows a step of preparing the glass substrate 10. The thickness of the glass substrate 10 can be appropriately set depending on the application, taking into account the thickness of the glass substrate 10 after the etching step of forming the through holes.

The glass substrate 10 can use, for example, alkali-free glass with a SiO₂ ratio in a range of 55 mass % to 81 mass % inclusive. If the SiO₂ ratio of the glass substrate 10 is greater than 81 mass %, the processing rate of etching decreases, the flatness of the angle of the side surface of the through hole 12 decreases, and poor adhesion may occur in forming the through electrodes 11, which will be described later. If the SiO₂ ratio is less than 55 mass %, alkali metals are highly likely to be contained in the glass, which will affect the reliability of the multilayer wiring substrate after the electronic device is mounted.

### [Laser Modification Step]

Next, FIG. 31 shows a step of forming laser modified portions. Laser modified portions 65 are formed in the glass substrate 10 by irradiating the portions of the glass substrate 10 where through holes are to be formed with a laser. Each laser modified portion 65 is formed in the glass substrate 10 with a shape of Φ3 μm or less, and is formed continuously in the thickness direction of the glass substrate 10. At this time, it is desirable that there occur no fine cracks (hereinafter also referred to as “microcracks”) of 5 μm or more around the laser modified portion 65 (hereinafter also referred to as a “peripheral portion of the laser irradiation”). When microcracks of 5 μm or more occur around the laser modified portion 65, the dispersion roughness of the side surface of the through hole 12 after etching will be 1000 nm or more, and the unevenness width thereof will be 1500 nm or more. This makes it difficult to obtain the through hole 12 with a smooth side surface.

When microcracks of 5 μm or more occur, the SEM image of the side surface of the through hole 12 after etching visibly shows not only the ridgelines extending in a direction parallel to the first surface 101 of the glass substrate 10, but also ridgelines extending in a direction perpendicular to the first surface 101 and ridgelines extending in a direction between the direction parallel to the first surface 101 and the direction perpendicular to the first surface 101, as is described later.

For processing the laser modified portion 65, it is preferable to use, for example, a femtosecond laser or a picosecond laser, and to use a laser emission wavelength of any one of 1064 nm, 532 nm, and 355 nm. If the laser pulse width is 25 picoseconds or more, microcracks of 5 μm or more are likely to occur around the laser modified portion 65. For this reason, the laser pulse width is desirably 25 picoseconds or less. In addition, since microcracks are likely to occur if processing is performed by a plurality of times of pulse irradiation, the laser modified portion 65 is desirably formed by one pulse. Under the condition that does not generate microcracks of 5 μm or more around the laser modified portion 65, the laser emission wavelength and laser output may be appropriately set depending on the thickness of the glass substrate 10. In other words, in the laser modification step (first step), the glass substrate is irradiated with a laser at the portion where the through hole is to be formed, and the microcracks that occur in a peripheral portion of the laser irradiation have a maximum length of 5 μm.

### [Etching Step]

Next, FIG. 32 shows a step of forming the through holes. The etching step (second step) is a step of etching the glass substrate irradiated with a laser to form the through holes. The glass substrate 10 in which the laser modified portions 65 are formed is subjected to etching processing with a predetermined etching solution to form the through holes 12. At the same time, the first surface and the second surface of the glass substrate 10 are also etched, and the thickness of the glass substrate 10 decreases. When etching is performed from both the first surface 101 and the second surface 102 of the glass substrate 10, the through holes 12 of the second embodiment are processed to have a shape almost symmetrical up and down.

### [Etching Solution]

The etching solution to be used contains hydrofluoric acid in a range of 0.2 mass % to 20.0 mass % inclusive, nitric acid in a range of 4.0 mass % to 25.0 mass % inclusive, and inorganic acid other than hydrofluoric acid and nitric acid in a range of 0.5 mass % to 11.0 mass % inclusive. Examples of inorganic acids other than hydrofluoric acid and nitric acid include hydrochloric acid, sulfuric acid, phosphoric acid, and sulfamic acid. At least one inorganic acid is contained depending on the type of components other than silicon contained in the glass substrate 10. Desirably, the etching solution contains hydrochloric acid and sulfuric acid. The etching rate for the glass substrate 10 is appropriately adjusted to be in a range of 0.1 μm/min to 10 μm/min inclusive. The etching rate for the glass substrate 10 is desirably in a range of 0.25 μm/min to 4 μm/min inclusive, and more desirably in a range of 0.25 μm/min to 0.5 μm/min inclusive. The etching temperature is not particularly limited and can be adjusted appropriately, and is, for example, in a range of 10° C. to 30° C. inclusive.

In the step of forming the through holes 12 by etching, the concentration of hydrofluoric acid may be lowered and etching may be performed a plurality of times. An example is such that: the etching rate for the glass substrate 10 in the first etching processing is in a range of 4 μm/min to 10 μm/min inclusive; the etching rate for the glass substrate 10 in the second etching processing is in a range of 0.5 μm/min to 4 μm/min inclusive; and then the etching rate for the glass substrate 10 in the third etching processing is in a range of 0.25 μm/min to 0.5 μm/min inclusive. The number of etching processing times may be set appropriately so that the roughness of the side surface of the through holes falls within the desired range.

### [Formation of Through Electrode]

Next, FIG. 33 is a diagram showing a step of forming the through electrodes 11 in the through holes 12.

Metal layers for electrolytic plating processing is formed on the first surface 101 and the second surface 102 of the glass substrate 10 in which the through holes 12 are formed. The metal layer just needs to be made of any metal that functions as a seed layer for electrolytic plating processing, such as metals including Cu, Ti, Cr, W, Ni, or the like. The metal layer uses at least one of the above-mentioned metals. The metal layer desirably has a Cu layer formed on its outermost surface. Ti, Cr, W, and Ni are desirably used as an adhesion layer with the glass substrate 10 under the Cu layer. The thickness of the metal layer is appropriately set to a range that can cover the side surface of each through hole 12. The formation method to be employed can be, for example, a formation method through deposition using sputtering.

Subsequently, the through electrodes 11 are formed by electrolytic plating processing that uses the above-mentioned metal layer as the seed layer. To selectively grow the through holes 12, a mask is formed with an insulator such as a resist on the first surface 101 and the second surface 102 of the glass substrate 10 except for the through holes 12, and then electrolytic plating processing is performed. For a material to be used for electrolytic plating processing, for example, Cu can be used, and other metals including Au, Ag, Pt, Ni, Sn, or the like can also be used. Depending on the application of the multilayer wiring substrate, electrolytic plating processing may be performed so that the through holes 12 are filled with the above-mentioned metal conductors.

After electrolytic plating processing, the insulator such as a resist is removed, and the metal films formed on the first surface 101 and the second surface 102 of the glass substrate 10 are removed, so that the plurality of through electrodes 11 formed on the glass substrate 10 are electrically isolated from each other.

### [Formation of First Wiring Layer and Second Wiring Layer]

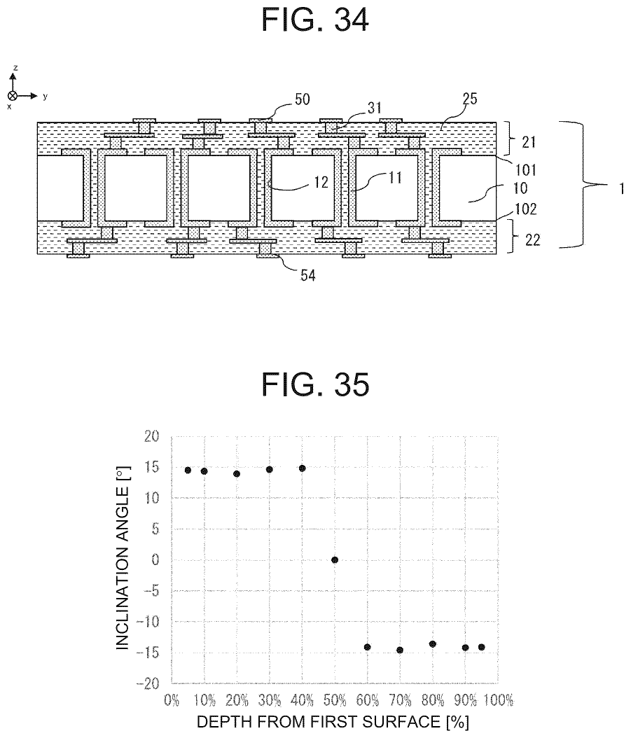

The following describes formation of the first wiring layer 21 and the second wiring layer 22 formed on the glass substrate 10 with reference to FIG. 34. FIG. 34 is a diagram showing a step of forming the first wiring layer 21 and the second wiring layer 22. For the glass substrate 10 on which the through electrodes 11 are formed, the first wiring layer 21 is formed on the first surface 101, and the second wiring layer 22 is formed on the second surface 102. In the step of forming the first wiring layer 21 and the second wiring layer 22, a mask having a pattern is first formed with a photosensitive resist or a dry film resist, and wiring is then formed by electrolytic plating processing. After that, physical adhesion processing or chemical adhesion processing is performed, and then the insulating resin layer 25 is laminated. For the conductive electrodes 31, holes are formed in the insulating resin layer 25 by laser processing or the like, and then a metal film is formed by electroless plating or deposition processing by sputtering. A mask having a pattern is formed on the above-mentioned metal film using resist, and the holes formed by electrolytic plating are filled with a conductor. The mask and excess metal film are then removed. The above-mentioned step is repeated a plurality of times depending on the number of layers required, to form the first wiring layer 21 and the second wiring layer 22. Note that the first wiring layer 21 and the second wiring layer 22 desirably have the same number of layers in order to prevent warping of the multilayer wiring substrate 1. If the layer thicknesses of the first wiring layer 21 and the second wiring layer 22 are different, the number of layers may be different between the first wiring layer 21 and the second wiring layer 22. The number of layers of the first wiring layer 21 and the number of layers of the second wiring layer 22 may be set appropriately depending on the application of the multilayer wiring substrate.

### [Insulating Resin Layer]

The insulating resin layer 25 is made of thermosetting resin. The material is, for example, a material that contains at least one of epoxy resin, polyimide resin, and polyamide resin, and that contains silica SiO₂ filler. The material is a liquid or film-like material. In the case of liquid resin, a spin coating method is used. In the case of film-like resin, a vacuum laminator is used. In any case, heating and pressurization are performed under vacuum to form the insulating resin layer 25. The material of the insulating resin layer 25 can be appropriately selected as necessary.

### Examples and Comparative Examples of Second Embodiment

The shape of the through hole 12 in the second embodiment will be described using FIG. 2. In the second embodiment, as shown in FIG. 32, the glass substrate 10 in which the laser modified portions 65 are formed is etched from the first surface 101 and the second surface 102. As a result, the formed through holes 12 each have a minimum point where the diameter is smallest at a position approximately halfway between the first surface 101 and the second surface 102, and have a vertically symmetrical structure. The inclination angles of the side surface of the through hole 12 vary depending on the laser processing conditions and etching conditions for the glass substrate 10. In each Example of the second embodiment, laser processing is performed under the irradiation conditions of the pulse width and number of shots shown in Table 5, and the through hole 12 is formed by etching. In Example 1, the pulse width is 5 ps and the number of shots is 1, in Example 2 the pulse width is 15 ps and the number of shots is 1, and in Example 3 the pulse width is 25 ps and the number of shots is 1.

The Comparative Examples are through holes created by the same producing method as shown in the second embodiment. In Comparative Example 1 of the second embodiment, the pulse width is 30 ps and the number of shots is 1, in Comparative Example 2 the pulse width is 30 ns and the number of shots is 100, and in Comparative Example 3 the pulse width is 50 μs and the number of shots is 10.

In addition, in each Example and Comparative Example, the opening diameter on the first surface 101 side of the glass substrate 10 had an average of 80 μm, 3σ of which was 4.5 μm or less. In the opening diameter on the first surface 101 side of the formed laser modified portion 65, there was a difference of 5 μm or less between the maximum opening diameter φ_{Max} and the minimum opening diameter φ_{Min}.

TABLE 5

| | Example | Example | Example | Comparative | Comparative | Comparative |
|---|---|---|---|---|---|---|
| | 1 | 2 | 3 | Example 1 | Example 2 | Example 3 |
| Pulse | 5 ps | 15 ps | 25 ps | 30 ps | 30 ns | 50 μs |
| width | | | | | | |
| Number | 1 | 1 | 1 | 1 | 100 | 10 |
| of shots | | | | | | |

### (Inclination Angle of the Through Hole)

The following describes the shapes and characteristic shapes of the through holes of each Example and Comparative Example using FIGS. 35 to 43.

FIG. 35 is a diagram showing measurement results of inclination angles of a through hole of Example 1 in the second embodiment.

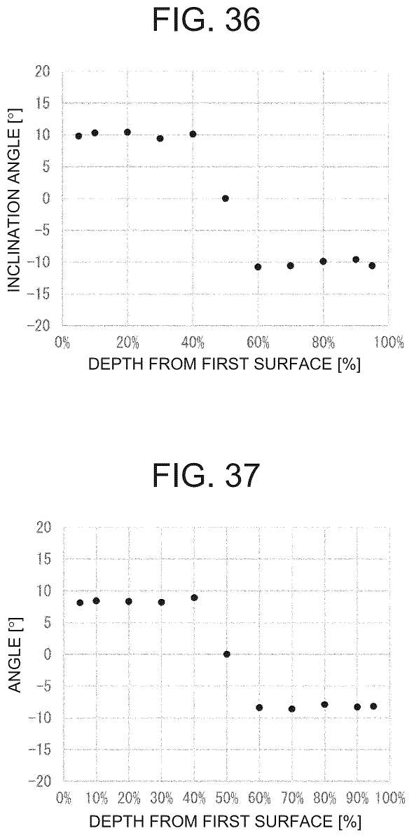

FIG. 36 is a diagram showing measurement results of inclination angles of a through hole of Example 2 in the second embodiment.

FIG. 37 is a diagram showing measurement results of inclination angles of a through hole of Example 3 in the second embodiment.

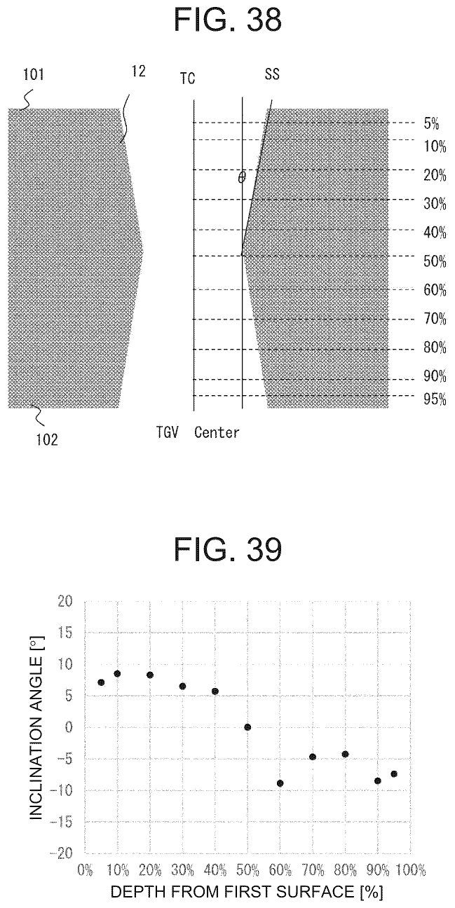

FIG. 38 is a diagram showing the cross-sectional shape of the through hole of Comparative Example 1 in the second embodiment.

FIG. 39 is a diagram showing measurement results of inclination angles of the through hole of Comparative Example 1 in the second embodiment.

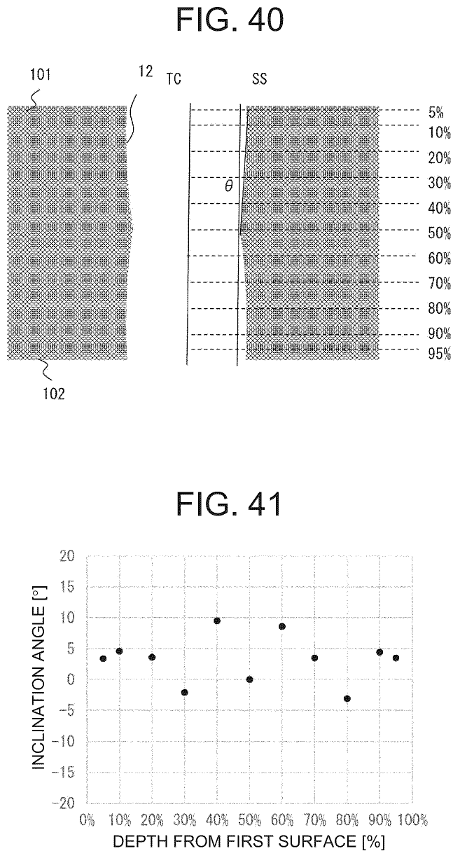

FIG. 40 is a diagram showing the cross-sectional shape of the through hole of Comparative Example 2 in the second embodiment.

FIG. 41 is a diagram showing measurement results of inclination angles of the through hole of Comparative Example 2 in the second embodiment.

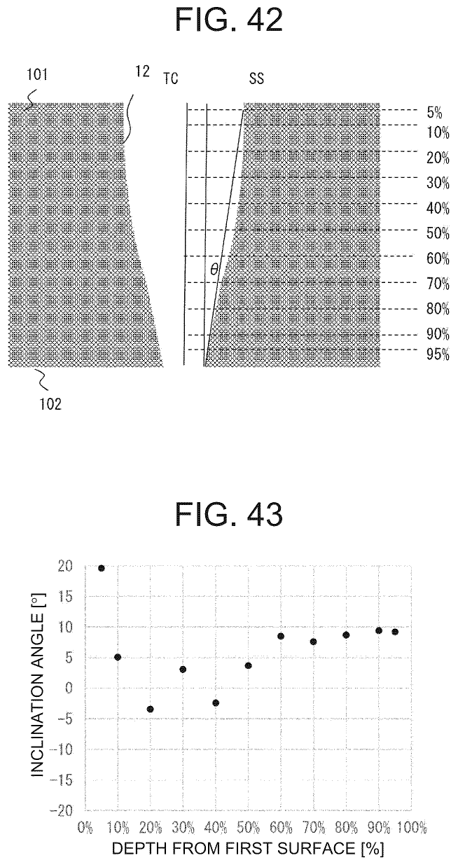

FIG. 42 is a diagram showing the cross-sectional shape of the through hole of Comparative Example 3 in the second embodiment.

FIG. 43 is a diagram showing measurement results of inclination angles of the through hole of Comparative Example 3 in the second embodiment.

Table 6 shows the results of measuring the inclination angles of the side surfaces of the through holes 12 of each Example and each Comparative Example in the second embodiment. In each Example of the second embodiment, the side surface angles of the through hole 12 are symmetrical up and down with respect to the position at the distance of 50% from the first surface 101, and almost constant. Each Comparative Example demonstrates that the inclination angles of the side surface of the through hole 12 vary at each position of 5% to 95%.

TABLE 6

| | Example | Example | Example | Comparative | Comparative | Comparative |
|---|---|---|---|---|---|---|
| | 1 | 2 | 3 | Example 1 | Example 2 | Example 3 |
| 5% | 14.5 | 9.8 | 8.1 | 7.1 | 3.4 | 19.6 |
| 10% | 14.3 | 10.3 | 8.4 | 8.5 | 4.6 | 5.1 |
| 20% | 13.9 | 10.4 | 8.3 | 8.3 | 3.6 | −3.4 |
| 30% | 14.6 | 9.4 | 8.2 | 6.5 | 2.1 | 3.1 |
| 40% | 14.8 | 10.1 | 8.9 | 5.7 | 9.5 | −2.4 |
| 50% | 0 | 0 | 0 | 0 | 0 | 3.7 |
| 60% | −14.1 | −10.8 | −8.4 | −8.9 | 8.6 | 8.5 |
| 70% | 14.6 | 10.6 | 8.6 | 4.7 | 3.5 | 7.6 |
| 80% | −13.6 | −9.9 | −7.9 | −4.3 | −3.1 | 8.7 |
| 90% | −14.2 | −9.6 | −8.3 | −8.5 | 4.4 | 9.4 |
| 95% | −14.1 | −10.6 | −8.2 | −7.4 | 3.5 | 9.2 |

Unit: °

### (Mean Dispersion Roughness and Unevenness Width)

Next, the mean dispersion roughnesses and unevenness widths of the side surfaces of the through holes 12 will be described with reference to Table 7 for each Example and each Comparative Example in the second embodiment.

Table 7 summarizes, in a tabular form, the measurement results of the mean dispersion roughnesses and unevenness widths of the side surfaces of the through holes 12 in each Example and each Comparative Example in the second embodiment.

As shown in Table 7, each Example of the second embodiment has a dispersion roughness of 1,000 nm or less and an unevenness width of 1,500 nm or less. Each Comparative Example has a dispersion roughness of 1,500 nm or more and an unevenness width of 1,500 nm or more. These demonstrate that there is a difference in the roughnesses of the through hole side surfaces.

TABLE 7

| | Example | Example | Example | Comparative | Comparative | Comparative |
|---|---|---|---|---|---|---|
| | 1 | 2 | 3 | Example 1 | Example 2 | Example 3 |
| Dispersion | 30.5 nm | 501.3 nm | 985.1 nm | 1623.5 nm | 1829.4 nm | 1789.5 nm |
| roughness | | | | | | |
| Unevenness | 316.2 nm | 982.1 nm | 1323.5 nm | 1756.4 nm | 199.61 nm | 1985.4 nm |
| width | | | | | | |

### (Transmission Characteristics)

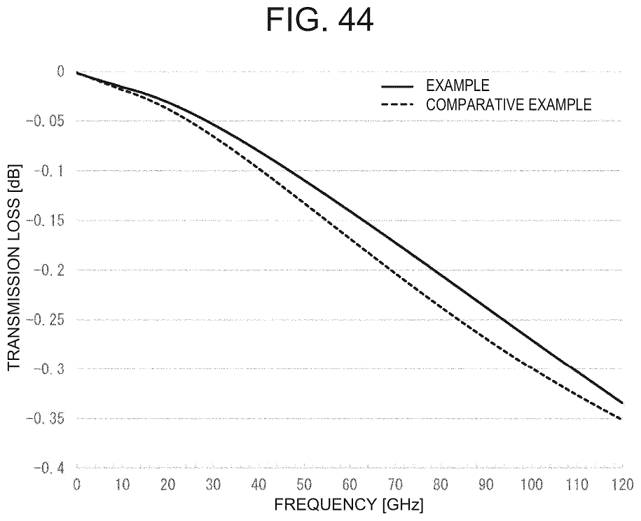

The following describes the transmission characteristics of the through electrodes of an Example and a Comparative Example in the second embodiment, using FIG. 44. FIG. 44 is a diagram showing transmission characteristics of a through electrode of Example 1 and transmission characteristics of a through electrode of Comparative Example 1 in the second embodiment. In FIG. 44, the transmission characteristics are shown as the results of measuring the transmission loss S21. The transmission characteristics of Examples 1 to 3 showed the same tendency, and Example 1 is shown as a representative. The transmission characteristics of Comparative Examples 1 to 3 also showed almost the same tendency, and Comparative Example 1 is shown as a representative. The formation conditions for the formation of the seed layer, plating processing, and the like for forming electrodes were the same in both the Examples and Comparative Examples. As shown in FIG. 44, the transmission loss of the Example is smaller than that of the Comparative Example in the all frequency regions. This shows that as the side surface of the through hole has smaller values of dispersion roughness and unevenness width, the loss is smaller and the transmission characteristics are more excellent, in the through electrode formed in the through hole.

The transmission characteristics S21 were also measured when the thickness of the glass substrate 10 was changed in each Example and each Comparative Example. The results are shown in Table 8. As shown in Table 8, the thicknesses of the glass substrates 10 were set to 250 μm, 300 μm, 350 μm, and 400 μm, and through holes and through electrodes were created under conditions based on each Example and each Comparative Example, and the transmission characteristics were measured. Table 8 shows that all the Examples in the second embodiment have more excellent transmission characteristics S21 than any of Comparative Examples therein.

Note that: the transmission characteristics shown in Table 8 are the transmission characteristics of a single through electrode; and in a multilayer wiring substrate that requires a plurality of through electrodes, improving the transmission characteristics of a single through electrode leads to a significant performance improvement. Using each Example according to the second embodiment makes it possible to obtain a multilayer wiring substrate that achieves excellent transmission characteristics of the through electrode in a high frequency band compared to existing techniques.

In terms of transmission characteristics, the through electrodes shown in Examples 1 to 3 provide more excellent results than the through electrodes shown in Comparative Examples 1 to 3. Comparison of the Examples demonstrates that Example 1 is the most preferable, followed by Example 2 and Example 3 in this order.

TABLE 8

| | | | | | | | | Comparative | | Comparative | | Comparative | |
|---|---|---|---|---|---|---|---|---|---|---|---|---|---|
| | | Example 1 | | Example 2 | | Example 3 | | Example 1 | | Example 2 | | Example 3 | |
| | | | Deter- | | Deter- | | Deter- | | Deter- | | Deter- | | Deter- |
| Fre- | Glass | Measured | mina- | Measured | mina- | Measured | mina- | Measured | mina- | Measured | mina- | Measured | mina- |
| quency | thickness | value | tion | value | tion | value | tion | value | tion | value | tion | value | tion |
| 5 GHz | 250 μm | −0.0071 | Good | −0.0081 | Good | −0.0091 | Good | −0.0121 | — | −0.0161 | — | −0.0169 | — |
| | 300 μm | −0.0073 | Good | −0.0082 | Good | −0.0094 | Good | −0.0141 | — | −0.0181 | — | −0.0199 | — |
| | 350 μm | −0.0076 | Good | −0.0084 | Good | −0.0095 | Good | −0.0161 | — | −0.0191 | — | −0.0217 | — |
| | 400 μm | −0.0079 | Good | −0.0086 | Good | −0.0098 | Good | −0.0181 | — | −0.0211 | — | −0.0239 | — |
| 10 GHz | 250 μm | −0.0121 | Good | −0.0141 | Good | −0.0161 | Good | −0.0288 | — | −0.0295 | — | −0.0300 | — |
| | 300 μm | −0.0131 | Good | −0.0144 | Good | −0.0165 | Good | −0.0298 | — | −0.0320 | — | −0.0328 | — |
| | 350 μm | −0.0136 | Good | −0.0147 | Good | −0.0169 | Good | −0.0318 | — | −0.0368 | — | −0.0378 | — |
| | 400 μm | −0.0139 | Good | −0.0149 | Good | −0.0171 | Good | −0.0328 | — | −0.0388 | — | −0.0398 | — |
| 20 GHz | 250 μm | −0.0261 | Good | −0.0291 | Good | −0.0312 | Good | −0.0449 | — | −0.0490 | — | −0.0492 | — |
| | 300 μm | −0.0282 | Good | −0.0322 | Good | −0.0372 | Good | −0.0485 | — | −0.0549 | — | −0.0559 | — |
| | 350 μm | −0.0323 | Good | −0.0361 | Good | −0.0431 | Good | −0.0525 | — | −0.0585 | — | −0.0595 | — |
| | 400 μm | −0.0364 | Good | −0.0389 | Good | −0.0491 | Good | −0.0562 | — | −0.0612 | — | −0.0615 | — |
| 28 GHz | 250 μm | −0.0416 | Good | −0.0452 | Good | −0.0486 | Good | −0.0595 | — | −0.0632 | — | −0.0642 | — |
| | 300 μm | −0.0439 | Good | −0.0486 | Good | −0.0539 | Good | −0.0645 | — | −0.0685 | — | −0.0695 | — |
| | 350 μm | −0.0489 | Good | −0.0538 | Good | −0.0579 | Good | −0.0685 | — | −0.0728 | — | −0.0745 | — |
| | 400 μm | −0.0536 | Good | −0.0581 | Good | −0.0606 | Good | −0.0725 | — | −0.0745 | — | −0.0777 | — |
| 56 GHz | 250 μm | −0.1013 | Good | −0.1114 | Good | −0.1343 | Good | −0.1711 | — | −0.1883 | — | −0.1983 | — |
| | 300 μm | −0.1216 | Good | −0.1515 | Good | −0.1623 | Good | −0.1888 | — | −0.2188 | — | −0.2228 | — |
| | 350 μm | −0.1430 | Good | −0.1712 | Good | −0.1999 | Good | −0.2311 | — | −0.2651 | — | −0.2715 | — |
| | 400 μm | −0.1782 | Good | −0.1973 | Good | −0.2434 | Good | −0.2509 | — | −0.2909 | — | −0.3109 | — |
| 84 GHz | 250 μm | −0.1998 | Good | −0.2038 | Good | −0.2179 | Good | −0.2502 | — | −0.2735 | — | −0.2833 | — |
| | 300 μm | −0.2112 | Good | −0.2231 | Good | −0.2328 | Good | −0.2815 | — | −0.2985 | — | −0.3299 | — |
| | 350 μm | −0.2451 | Good | −0.2613 | Good | −0.2763 | Good | −0.3325 | — | −0.3653 | — | −0.3723 | — |
| | 400 μm | −0.2799 | Good | −0.2985 | Good | −0.3118 | Good | −0.3763 | — | −0.3945 | — | −0.4095 | — |

### Third Embodiment

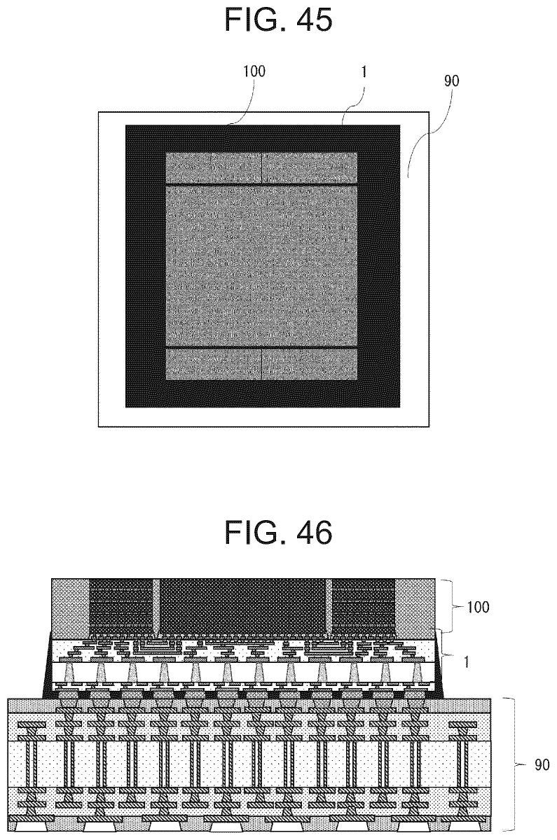

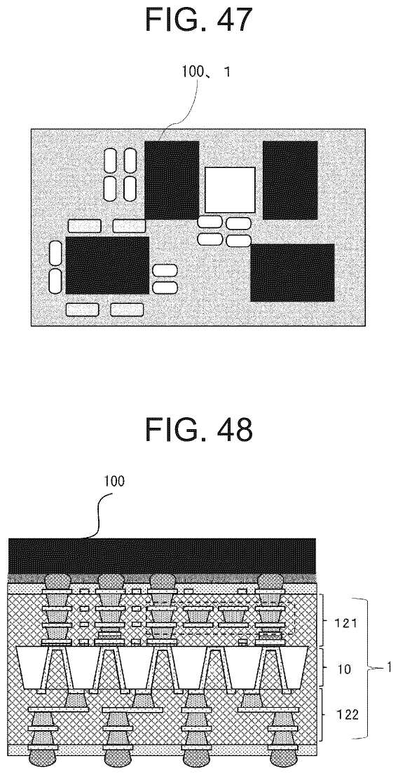

FIG. 45 is a diagram showing a case in which a multilayer wiring substrate 1 is used as an interposer substrate for a semiconductor power device 100 and a BGA (Ball Grid Array) substrate 90. FIG. 46 is a diagram showing a cross section of the case of FIG. 45. FIG. 47 is a diagram showing a case in which the multilayer wiring substrate 1 and the semiconductor power device 100 are used in an electronic device for communication. FIG. 48 is a diagram showing a cross section of the case of FIG. 47. The electronic device to be used has a layer thickness of 800 μm or less. For example, the electronic device is an interposer substrate on which a memory compatible with HBM (High Bandwidth Memory) is mounted.

The above-described electronic device has limited applications to which the device is adapted due to the effect of the transmission characteristics of the through electrodes, and the use of the multilayer wiring substrate of the present invention allows the electronic device to be adapted to a high frequency band region.

### <Actions and Effects>

As described above, in both the first and second embodiments, the Examples have successfully formed with through holes having smaller values of the dispersion roughness and unevenness width than the Comparative Examples. Since the side surface of the through hole can be smoothed in this way, the through electrode, which is formed in the through hole, has high transmission characteristics in a high frequency band. In this way, a through electrode having high transmission characteristics can be formed.

According to the embodiments of the present invention, and the producing method and Examples according to the embodiments of the present invention, forming the side surface of the through hole smoothly allows transmission characteristics to be excellent, and allows the through electrode to have improved transmission characteristics compared to existing techniques. Using the present invention enables providing a multilayer wiring substrate with excellent transmission characteristics in a high frequency band.

The scope of the present invention is not limited to the exemplary embodiments illustrated and described, and includes various modified examples. For example, the above-mentioned embodiments are described in detail to describe the present invention in an easy-to-understand manner, and the scope of the present invention is not necessarily limited to those including all of the configurations described.

In addition, part of the configuration of one embodiment can be replaced with the configuration of another embodiment, and the configuration of another embodiment can be added to the configuration of one embodiment. In addition, part of the configuration of each embodiment can have another configuration added thereto, can be deleted, or can be replaced with another configuration.

Furthermore, all embodiments are also included that bring about an effect equivalent to the object of the present invention.

### Another Embodiment

The present disclosure also includes the following aspects.

### (Aspect 1)

A glass substrate having a first surface and a second surface, the glass substrate comprising at least one through hole penetrating from the first surface to the second surface,
wherein a cut surface of the through hole in a thickness direction of the glass substrate has a shape of a side surface, the shape having a dispersion roughness of 1,000 nm or less and an unevenness width of 1,500 nm or less.

### (Aspect 2)

The glass substrate according to Aspect 1, wherein
the dispersion roughness is an arithmetic mean roughness calculated with Expression 1 in a set section, the set section being set in a roughness curve, the roughness curve being extracted based on contour data of the side surface, and
the unevenness width is a difference between highest and lowest parts in the set section.

$$\begin{matrix}[ Expression 1 ] & \\ Ra = \frac{1}{L} {\int }_{0}^{L} {\vert f ( x ) \vert}^{2} {dx}^{\cdot \cdot } & Expression 1\end{matrix}$$

$$where : Ra is an arithmetic mean roughness .$$

$$f ( x ) is a roughness curve , and$$

$$L is a length of a set section .$$

### (Aspect 3)

A glass substrate having a first surface and a second surface, the glass substrate comprising at least one through hole penetrating from the first surface to the second surface,
wherein a SEM image of a cut surface of the through hole in a thickness direction of the glass substrate allows a plurality of ridgelines to be seen, the SEM image having a magnification of 1000 times, the ridgelines extending in a side wall surface of the through hole, the ridgelines extending in a direction substantially parallel to the first surface, a space between the ridgelines being 15.5 μm or less in a direction perpendicular to the first surface.

### (Aspect 4)

The glass substrate according to any one of Aspects 1 to 3, wherein an SiO₂ ratio of the glass substrate is in a range of 55 mass % to 81 mass % inclusive.

### (Aspect 5)

A multilayer wiring substrate comprising the glass substrate according to any one of Aspects 1 to 4,
wherein an electronic device mounted on the multilayer wiring substrate has a layer thickness of 800 μm or less, and
the multilayer wiring substrate has a thickness of 100 μm or more and 400 μm or less.

### (Aspect 6)

A method for producing the glass substrate according to any one of Aspects 1 to 5, the method comprising:
a first step of irradiating a portion of the glass substrate with a laser, the portion being where the through hole is to be formed; and
a second step of etching the glass substrate irradiated with the laser to form the through hole.

### (Aspect 7)

The method for producing a glass substrate according to Aspect 6, wherein the laser radiated in the first step has any of laser emission wavelengths of 1064 nm, 532 nm, and 355 nm, and has a pulse width of 25 picoseconds or less.

### (Aspect 8)

The method for producing a glass substrate according to Aspect 6 or 7, wherein, in the first step, a maximum length of a microcrack occurring in a peripheral portion of the laser irradiation is 5 μm.

### (Aspect 9)

The method for producing a glass substrate according to any one of Aspects 6 to 8, wherein, in the second step, etching is performed a plurality of times with different etching rates.

### (Aspect 10)

The method for producing a glass substrate according to any one of Aspects 6 to 9, wherein, in the second step, an etching solution is used that contains hydrofluoric acid in a range of 0.2 mass % to 20.0 mass % inclusive, nitric acid in a range of 4.0 mass % to 25.0 mass % inclusive, and an inorganic acid other than hydrofluoric acid and nitric acid in a range of 0.5 mass % to 11.0 mass % inclusive.

### (Supplement 1)

Another aspect of the present disclosure is shown below.

The present invention relates to a glass substrate, a multilayer wiring substrate, and a method for producing a glass substrate.

### Background Art

Recently, three-dimensional mounting technique has been used in which circuit boards are laminated. In such a mounting technique, through electrodes are formed in the circuit board. The through electrodes are formed by forming through holes in a substrate made of an insulator and disposing conductors in the through holes. Higher integration of circuit boards also requires finer through holes.

For example, Patent Literature 1 discloses a technique for providing a glass substrate having a plurality of through holes by irradiating a plate-like glass with an excimer laser light. Patent Literature 2 discloses a method for manufacturing a high-density array of holes in glass, the method including a step of irradiating a front surface of a glass product with a UV laser beam. Patent Literature 3 discloses a through electrode substrate including: a substrate including a through hole; and a conductor disposed along an inner side surface of the through hole, wherein the substrate has a first surface and a second surface, and the through hole has a through hole shape that satisfies a condition in which a sum of inclination angles of the inner side surface with respect to a central axis of the through hole is 8.0° or more, where: an inclination angle expanding toward the first surface side is defined as a positive inclination angle; and the inclination angles are inclination angles at distances from the first surface, the distances being 6.25%, 18.75%, 31.25%, 43.75%, 56.25%, 68.75%, 81.25%, and 93.75% of a length of a section from the first surface to the second surface. Patent Literature 4 discloses a through electrode substrate that includes: a substrate 12 that includes a first surface 13 and a second surface 14 located opposite the first surface and is provided with a through hole 20; and a through electrode 22 located in the through hole of the substrate.

### CITATION LIST

### Patent Literature

<Patent Literature 1> International Publication No. 2010/087483
<Patent Literature 2> Japanese Translation of PCT International Application Publication No. 2014-501686
<Patent Literature 3> Japanese Patent Publication No. 6809511
<Patent Literature 4> Japanese Patent Publication No. 6965589

### SUMMARY OF INVENTION

### Technical Problem

However, the contents described in Patent Literatures 1 to 3 do not discuss the effect of the side surface roughness of the through hole on the transmission characteristics of the through electrode. For this reason, the side surfaces described in Patent Literatures 1 to 3 have insufficient flatness in terms of transmission characteristics, and also have a problem with uniformity of the inclination angle of the through hole side surface.

In addition, as disclosed in Patent Literature 4, in order to form a through electrode, the side surface of the through hole needs to be subjected to: electroless plating after forming a metal layer by sputtering; and formation of a metal layer for electrolytic plating processing. As disclosed in Patent Literature 4, the metals that can be adapted to the electroless plating processing are limited, and Ni is selected, for example. Ni is a magnetic material and a difficult-to-etch metal. This affects the wiring layer portion so that the wiring is roughen and undercut is generated at the lower part of the wiring, in a removal step after formation of the wiring in the through hole. This then causes a problem with the transmission characteristics of the through electrode. In the above-mentioned fact, a glass substrate is desired that has a through hole in which a through electrode can be easily formed.

An object of the present invention is to provide a glass substrate capable of forming a through electrode with excellent transmission characteristics, and a multilayer wiring substrate including such a glass substrate.

### Solution to Problem

To solve the above-mentioned problems, one typical glass substrate of the present invention has a first surface and a second surface and includes at least one through hole penetrating from the first surface to the second surface, in which: a side surface of the through hole has an inclination angle in a range of 7° to 15° inclusive at a position in a section of 5% to 95% inclusive from the first surface; and when the side surface of the through hole is regarded as a left side surface and a right side surface in a cross-sectional view, a difference between an inclination angle of the left side surface and an inclination angle of the right side surface is 1.0° or less.

### Advantageous Effects of Invention

According to the present invention, it is possible to provide a glass substrate capable of forming a through electrode with excellent transmission characteristics, and a multilayer wiring substrate including such a glass substrate.

Problems, configurations, and effects other than those described above will be made clear by the following explanation of embodiments of the invention.

### DESCRIPTION OF EMBODIMENTS

The scope of the present invention is not limited to the exemplary embodiments and Examples illustrated and described, and includes various modified examples. For example, the embodiments and the Examples according to the present disclosure are described in detail to describe the present invention in an easy-to-understand manner, and the scope of the present invention is not necessarily limited to those including all of the configurations described.

It is also possible to replace part of the configuration of a certain embodiment and Example with the configuration of another embodiment and Example, and it is also possible to add the configuration of another embodiment and Example to the configuration of a certain embodiment and Example. In addition, part of the configuration of each embodiment and each Example can have another configuration added thereto, can be deleted, or can be replaced with another configuration.

Furthermore, all embodiments are also included that bring about an effect equivalent to the object of the present invention.

The position, size, shape, range, or the like of each component shown in the drawings may not represent the actual position, size, shape, range, and the like, in order to make the invention easier to understand. For this reason, the present invention is not necessarily limited to the position, size, shape, range, and the like disclosed in the drawings.

In the present disclosure, the term “surface” may refer not only to the surface of a plate-like member, but also to the interface of a layer contained in a plate-like member that is substantially parallel to the surface of the plate-like member. Additionally, “upper surface” or “lower surface” means the surface shown on the upper side or lower side on a drawing when a plate-like member or a layer contained in a plate-like member is illustrated. The “upper surface” and the “lower surface” are sometimes referred to as a “first surface” and a “second surface”.

A term “side surface” means a thickness portion of a surface or a layer in a plate-like member or a layer contained in a plate-like member. Part of a surface and a side surface may be collectively referred to as an “end portion”.

A “side surface of a through hole” means the interface on an object that forms the through hole, in the through hole provided in the object.

An “upper side” means a vertically upward direction when a plate-like member or a layer is placed horizontally. An “upper side” and a “lower side” opposite to this are sometimes referred to as a “positive Z-axis direction” and a “negative Z-axis direction”, and a horizontal direction is sometimes referred to as an “X-axis direction” and a “Y-axis direction”.

A distance in the Z-axis direction is referred to as a “height,” and a distance on an XY plane defined by the X-axis and Y-axis directions is referred to as a “width.” In referring to a layered object, the height is also referred to as a “thickness.”

A “through electrode provided in a glass substrate” means a conductive path provided for electrical continuity between the first surface and the second surface of the glass substrate when the glass substrate is used as part of a multilayer wiring substrate, and does not necessarily need to completely penetrate the glass substrate with a single conductive material. As long as the conductive path from the first surface and the conductive path from the second surface are connected, they are included in the through electrodes. The form of the through electrode may be a filled type in which a through hole is filled with a conductive material, or a conformal type in which only the side wall portion of the through hole is covered with a conductive material (the through hole includes both bottomed and completely through holes).

A “planar shape” and a “planar view” mean the shape when a surface or layer is seen from above. A “cross-sectional shape” and a “cross-sectional view” mean the shape when a plate-like member or a layer is cut in a specific direction and seen from the horizontal direction.

A “central portion” means the center portion, not a peripheral portion of the surface or the layer. A “center direction” means a direction from the peripheral portion of the surface or the layer toward the center in the planar shape of the surface or the layer.

### <Measuring Method>

To describe the shape of the through hole provided in the glass substrate according to the first embodiment (Supplement 1) of the present invention, the following first shows a method for measuring inclination angles of a through hole 12 and a method for measuring a side surface roughness.

Here shows points to note in measuring inclination angles depending on the positions of the side wall of the glass substrate through hole and describing the values thereof.

When a specific position in the through hole is specified as a position in a depth direction from one side of the glass substrate, an angle of the side surface at that position depends greatly on the scale at which the shape of the side surface at that position is observed.

In other words, results may be significantly different between the following two cases of: observing the inclination angle of the side wall at a certain position on a scale of overlooking the entire through hole of the glass substrate; and enlarging the sidewall near the measurement point, making the fine unevenness clear on the side wall at that position, precisely determining a position where that point, at which the angle is specified, corresponds to on the unevenness, and determining the inclination angle of the tangent at that position to be the desired angle.

The inclination angle of the glass substrate through hole in the present disclosure corresponds to the former case, and means an inclination angle that reflects the tendency in overlooking the entire through hole without being excessively affected by the unevenness of the side surface.

An example of a measurement method is setting the tangent at the measurement point so as to reflect the tendency of the inclination at the measurement point and in its vicinity as much as possible, in a cross-sectional photograph at a scale and resolution in which the entire through hole can be overlooked and fine unevenness on the side surface cannot be seen with the naked eye.

### (Method for Measuring Inclination Angle of Through Hole)

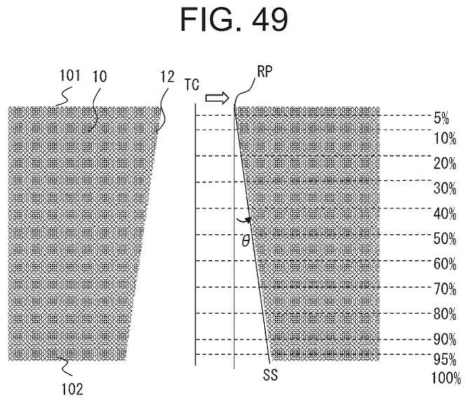

FIG. 49 illustrates the shape of the through hole 12 obtained in the first embodiment (Supplement 1) of the present invention. FIG. 49 is a diagram showing a cross section of the truncated cone-shaped through hole 12 and a method for measuring inclination angles. The cross section of the through hole 12 shown in FIG. 49 is obtained by: dividing (cutting) the through hole 12 from the first surface 101 side in the thickness direction of the glass substrate with a scriber to expose a cross section (cut surface); and analyzing the SEM image, observed with a SEM (Scanning Electron Microscope), using image analysis software. In FIG. 49, the area shown with a pattern design indicates the glass substrate 10. The through hole 12 shown in FIG. 49 has a truncated cone shape, and the through hole 12 has a minimum value on the first surface 101 side at which the diameter of the through hole is minimum. The scales of 5%, 10%, . . . 95% shown in FIG. 49 each indicate a percentage with respect to the length from the first surface 101 of the glass substrate 10 to the second surface 102 thereof.

A center line TC is drawn at a central portion of an opening on the first surface 101 side of the glass substrate 10 so as to be perpendicular to the first surface 101. Next, as shown by an arrow, the center line TC is translated toward either side of the through hole 12, the translated center line TC is brought into contact with the point where the diameter of the through hole 12 is at its minimum value, and the point of contact is set as a reference point RP. Then, tangent lines ss are drawn from the reference point RP to the cross-sectional positions at heights of each of the scale positions of 5% to 100%, and the inclination angles of each tangent ss are measured and defined as the inclination angles at each of the cross-sectional positions of 5% to 95%. The inclination angle is positive in a direction in which the diameter of the through hole 12 expands downward.

As described above, in the first embodiment (Supplement 1), the method for measuring the inclination angles includes the following protocols of (1) to (3): (1) creating a center line of the through hole 12; (2) moving the center line horizontally to the position where the opening is at its minimum value to create a reference point; and (3) drawing tangents from the reference point to the specific positions of the through hole, and measuring their angles. In particular, using the protocol of (2) creating a reference point enables a highly reliable measurement on a scale that overlooks the entire through hole and that is not affected by fine unevenness on the side wall.

In addition, in a specific inclination angle measurement, a scriber and a precision breaker are used to divide (cut) the through hole 12 at the central portion from the first surface 101 side to expose the cross section of the through hole 12. As a method for dividing, for example, three-point bending can be applied. Then, the exposed cross section is observed by SEM and the SEM image of the cross section is subjected to image analysis, and thereby the angle of the through hole 12 is measured.

### (Method for Measuring Side Surface Roughness)

Next, a method for measuring a side surface roughness of the through hole 12 will be described. To measure the side surface roughness of the through hole 12, the cross section of the through hole 12 is observed by SEM, as in the measurement of the side surface angle, and the observed SEM image is analyzed using image analysis software. To measure the side surface roughness of the through hole, the measurement range is normally the range from the first surface 101 to the second surface 102 of the through hole. However, if there are projections and recesses in the through hole, two or more ranges excluding the parts of the projections and recesses are set as measurement ranges, and the results of these measurement ranges are averaged to determine the side surface roughness. In calculating the side surface roughness, the same measurements are made on five through holes (sample number n=5) created under the same conditions, and the average value is defined as the side surface roughness of the through hole created under the conditions.

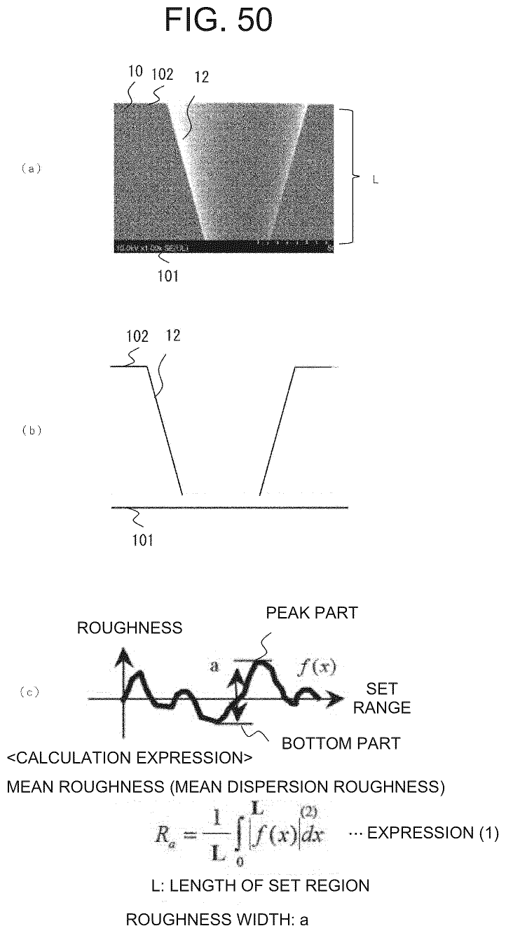

FIG. 50 is a diagram showing a method for measuring the side surface roughness of a through hole. FIG. 50(a) shows a SEM image of the cross section of the through hole 12. FIG. 50(b) shows a diagram in which the contour of the side surface of the through hole 12 is extracted from the SEM image obtained by observation of the cross section of the through hole 12. The mean dispersion roughness and unevenness width are measured from the extracted contour data. FIG. 50(c) is a diagram schematically showing the calculation expression for the mean dispersion roughness and the unevenness width. For the contour data extracted in FIG. 50(b), a roughness curve f(x) showing the roughness of the contour is measured in a set region L set based on the first surface 101. As shown in Expression (1), the mean dispersion roughness (hereinafter simply referred to as “dispersion roughness”) Ra is obtained by integrating the squared absolute value of a roughness curve f(x) over the set region L and then dividing it by the length of the set region L. The roughness width (hereinafter also referred to as the “unevenness width”) a is the difference between the peak part showing the maximum roughness value and the bottom part showing the minimum roughness value of the roughness curve f(x).

When a plurality of roughness curves f(x) are set for one through hole, the average roughness of the through hole is calculated by averaging the roughness values calculated from them.

### (Method for Measuring Transmission Characteristics)

To measure the transmission characteristics, an S parameter (S21) is used that shows the frequency dependency of the degree of propagation wave with respect to the input wave. S21 is expressed as a logarithm of the power ratio (transmitted wave power/input wave power), and a smaller absolute value indicates a smaller transmission loss.

A network analyzer was used to measure the S parameter (S21). For a measurement sample, a sample was manufactured in which the periphery of the through electrode 11 formed on the glass substrate was surrounded by a conductor and the conductor was grounded. With this sample, S21s were measured between the first surface 101 side and the second surface 102 side of the through electrode 11.

### Examples and Comparative Examples According to First Embodiment (Supplement 1)

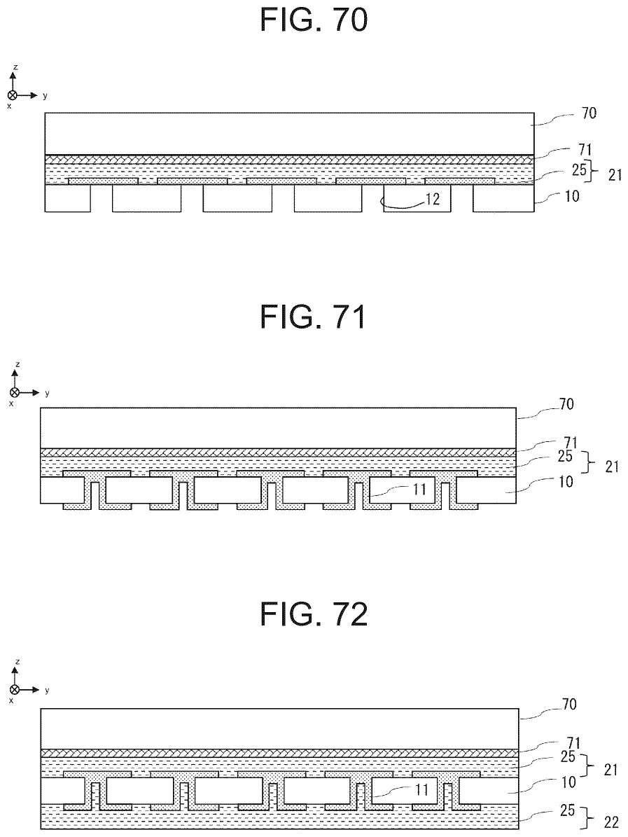

The shape of the through hole 12 in the first embodiment (Supplement 1) will be described. In the first embodiment (Supplement 1), as shown in FIG. 70 described later, the glass substrate 10 in which laser modified portions 65 are formed is etched from the second surface 102 side of the glass substrate 10. Therefore, the formed through hole 12 has a truncated cone shape whose diameter narrows from the second surface 102 toward the first surface 101. The inclination angles of the side surface of the through hole 12 vary depending on the laser processing conditions and etching conditions for the glass substrate 10.

In each Example of the present invention, the glass substrate is subjected to laser processing under the irradiation conditions of pulse width and number of shots shown in Table 1, and the through hole 12 is then formed by etching. In Example 1 of the first embodiment (Supplement 1), the pulse width is 5 ps and the number of shots is 1, in Example 2 the pulse width is 15 ps and the number of shots is 1, and in Example 3 the pulse width is 25 ps and the number of shots is 1.

In addition, the Comparative Examples are through holes created by changing the producing method and laser processing method shown in the first embodiment (Supplement 1). In other words, in Comparative Example 1 the pulse width is 30 ps and the number of shots is 1, in Comparative Example 2 the pulse width is 30 ns and the number of shots is 50, and in Comparative Example 3 the pulse width is 50 μs and the number of shots is 5.

All of the Examples and Comparative Examples each had an average opening diameter of 80 μm on the second surface 102 side of the glass substrate 10, and had a 3σ of 4.5 μm or less in this case, the 3σ being the average of the measured values plus three times the standard deviation. In addition, the formed laser modified portions 65 each had an opening diameter φ on the second surface 102, the opening diameter φ having a difference of 10 μm or less between its maximum opening diameter φ_{Max} and its minimum opening diameter φ_{Min}.

TABLE 9

| | Example | Example | Example | Comparative | Comparative | Comparative |
|---|---|---|---|---|---|---|
| | 1 | 2 | 3 | Example 1 | Example 2 | Example 3 |
| Pulse | 5 ps | 15 ps | 25 ps | 30 ps | 30 ns | 50 μs |
| width | | | | | | |
| Number | 1 | 1 | 1 | 1 | 50 | 5 |
| of shots | | | | | | |

### (Inclination Angle of Through Hole)

The following is used to describe the shapes and characteristic shapes of the through holes in each Example and Comparative Example in the first embodiment (Supplement 1).

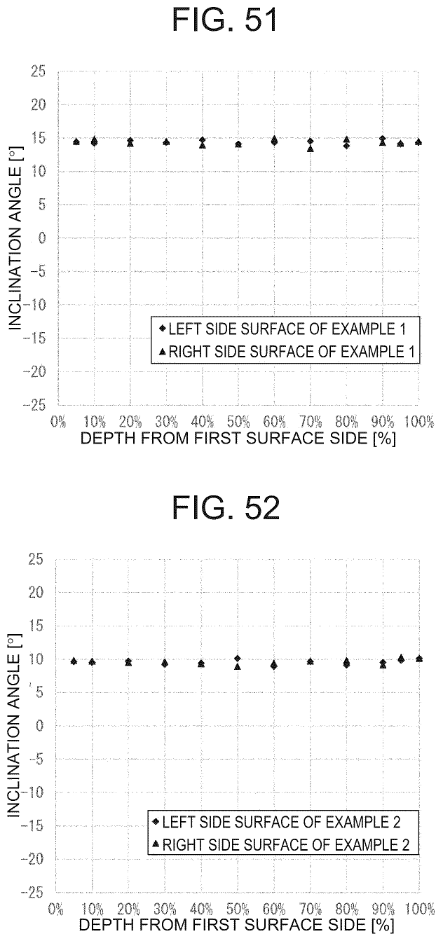

FIG. 51 is a diagram showing measurement results of inclination angles of a through hole of Example 1 in the first embodiment (Supplement 1).

FIG. 52 is a diagram showing measurement results of inclination angles of a through hole in Example 2 in the first embodiment (Supplement 1).

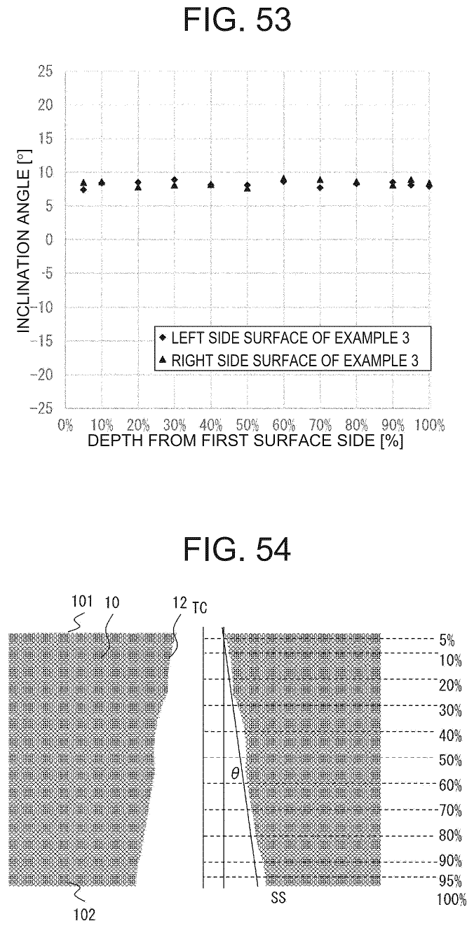

FIG. 53 is a diagram showing measurement results of inclination angles of a through hole in Example 3 in the first embodiment (Supplement 1).

FIG. 54 is a diagram showing a cross-sectional shape of a through hole of Comparative Example 1 in the first embodiment (Supplement 1).

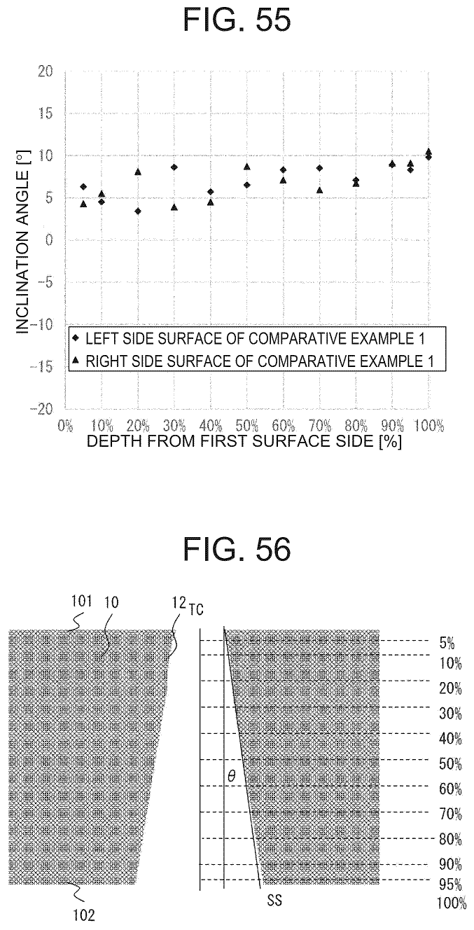

FIG. 55 is a diagram showing measurement results of inclination angles of the through hole of Comparative Example 1 in the first embodiment (Supplement 1).

FIG. 56 is a diagram showing a cross-sectional shape of a through hole of Comparative Example 2 in the first embodiment (Supplement 1).

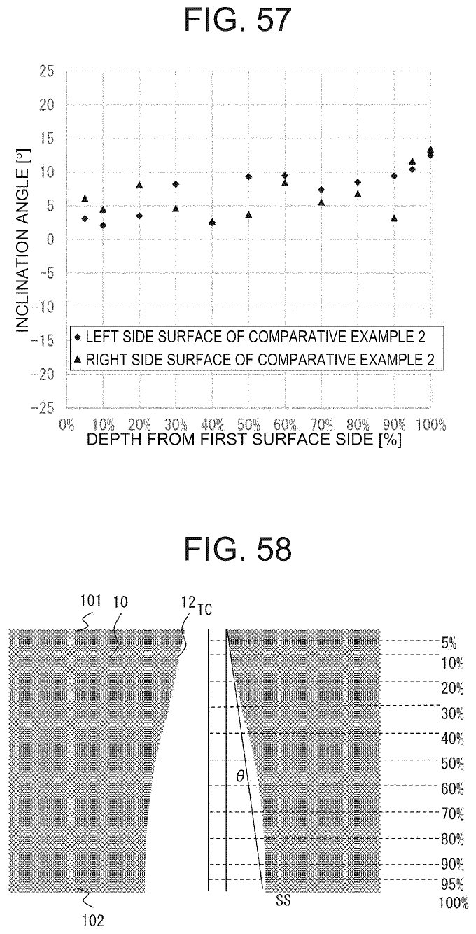

FIG. 57 is a diagram showing measurement results of inclination angles of the through hole of Comparative Example 2 in the first embodiment (Supplement 1).

FIG. 58 is a diagram showing a cross-sectional shape of a through hole of Comparative Example 3 in the first embodiment (Supplement 1).

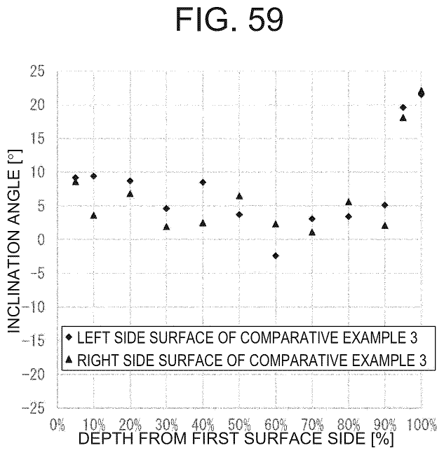

FIG. 59 is a diagram showing measurement results of inclination angles of the through hole of Comparative Example 3 in the first embodiment (Supplement 1).

Table 10 summarizes, in a tabular form, measurement results of the inclination angles of the side surfaces of the through holes 12 in each Example and each Comparative Example. In each Example of the first embodiment (Supplement 1), the side surface angles of the through hole 12 are almost constant from the position of 5% to 95%. Each Comparative Example demonstrates that the inclination angles of the side surface of the through hole 12 vary at each position of 5% to 95%. As shown in Table 2, each side surface of the through hole has an inclination angle in a range of 7° to 15° inclusive at a position in a section of 5% to 95% inclusive from the first surface. In addition, when the side surfaces of the through hole in a cross-sectional view are defined as the left side surface and the right side surface, a difference between an inclination angle of the left side surface and an inclination angle of the right side surface is 1.0° or less.

In addition, in each Example, the inclination angle from the second surface (100%) to a position at a distance of 95% differs from the inclination angle from a position at a distance of 5% to a position at a distance of 95%, by +/−1.0° or less. The inclination angle is in a range of 7° to 15° inclusive, from the second surface (100%) to a position at a distance of 95%; and the inclination angle is also in a range of 7° to 15° inclusive, from a position at a distance of 5% to a position at a distance of 95%.

Contrarily, in each Comparative Example, the inclination angle from the second surface (100%) to a position at a distance of 95% differs from the inclination angle from a position at a distance of 5% to a position at a distance of 95%, by +/−1.0° or more.

Thus, it can be seen that the tendencies of the inclination angles of the side surfaces of each through hole to vary are significantly different between Examples and Comparative Examples in the present invention.

TABLE 10

| | | | | | | | Comparative | | Comparative | | Comparative | |
|---|---|---|---|---|---|---|---|---|---|---|---|---|
| | Example 1 | | Example 2 | | Example 3 | | Example 1 | | Example 2 | | Example 3 | |
| | Left | Right | Left | Right | Left | Right | Left | Right | Left | Right | Left | Right |
| | side | side | side | side | side | side | side | side | side | side | side | side |
| | surface | surface | surface | surface | surface | surface | surface | surface | surface | surface | surface | surface |
| 100% | 14.3 | 14.5 | 10.1 | 10.1 | 7.9 | 8.4 | 9.8 | 10.5 | 12.5 | 13.4 | 21.5 | 22.1 |
| 95% | 14.1 | 14.2 | 9.8 | 10.3 | 8.1 | 8.9 | 8.3 | 9.1 | 10.4 | 11.6 | 19.6 | 18.1 |
| 90% | 14.9 | 14.3 | 9.5 | 9.1 | 8.5 | 8.1 | 8.9 | 9.1 | 9.4 | 3.2 | 5.1 | 2.1 |
| 80% | 13.8 | 14.8 | 9.1 | 9.8 | 8.3 | 8.6 | 7.1 | 6.7 | 8.5 | 6.8 | 3.4 | 5.6 |
| 70% | 14.5 | 13.4 | 9.6 | 9.7 | 7.7 | 8.9 | 8.5 | 5.9 | 7.4 | 5.5 | 3.1 | 1.1 |
| 60% | 14.3 | 14.9 | 8.9 | 9.4 | 8.6 | 9.1 | 8.3 | 7.1 | 9.5 | 8.4 | −2.4 | 2.3 |
| 50% | 14.1 | 14.1 | 10.1 | 8.9 | 8.1 | 7.6 | 6.5 | 8.7 | 9.3 | 3.7 | 3.7 | 6.5 |
| 40% | 14.7 | 13.9 | 9.4 | 9.3 | 8.1 | 8.2 | 5.7 | 4.5 | 2.5 | 2.6 | 8.5 | 2.5 |
| 30% | 14.3 | 14.5 | 9.2 | 9.6 | 8.9 | 8.1 | 8.6 | 3.9 | 8.2 | 4.6 | 4.6 | 1.9 |
| 20% | 14.6 | 14.2 | 9.7 | 9.5 | 8.5 | 7.8 | 3.4 | 8.1 | 3.5 | 8.1 | 8.7 | 6.8 |
| 10% | 14.2 | 14.8 | 9.5 | 9.7 | 8.4 | 8.6 | 4.5 | 5.5 | 2.1 | 4.5 | 9.4 | 3.6 |
| 5% | 14.4 | 14.5 | 9.6 | 9.8 | 7.4 | 8.5 | 6.3 | 4.3 | 3.1 | 6.1 | 9.2 | 8.6 |
| Mean | 14.4 | 14.3 | 9.5 | 9.6 | 8.2 | 8.4 | 6.9 | 6.6 | 6.7 | 5.9 | 6.6 | 5.4 |
| Standard | 0.3 | 0.4 | 0.3 | 0.4 | 0.4 | 0.5 | 1.8 | 2.0 | 3.2 | 2.7 | 5.6 | 4.9 |
| deviation | | | | | | | | | | | | |

These indicate that in order to obtain excellent transmission characteristics, it is desirable that: the shape of the through hole is such that an inclination angle of the side surface is in a range of 7° to 15° inclusive at a position in the section of 5% to 95% inclusive from the first surface; and when the side surface of the through hole is regarded as a left side surface and a right side surface in a cross-sectional view, a difference between an inclination angle of the left side surface and an inclination angle of the right side surface is 1.0° or less.

### (Mean Dispersion Roughness and Unevenness Width)

Next, the mean dispersion roughnesses and unevenness widths of the side surfaces of the through holes 12 will be described with reference to Table 11 for each Example and each Comparative Example in the embodiment. As shown in Table 11, each Example of the first embodiment (Supplement 1) has a dispersion roughness of 1,000 nm or less and an unevenness width of 1,500 nm or less. Each Comparative Example has a dispersion roughness of 1,500 nm or more and an unevenness width of 1,500 nm or more. These demonstrate that there is a difference in the roughnesses of the through hole side surfaces.

TABLE 11

| | | | | Comparative | Comparative | Comparative |
|---|---|---|---|---|---|---|
| | Example 1 | Example 2 | Example 3 | Example 1 | Example 2 | Example 3 |
| Dispersion | 30.5 nm | 501.3 nm | 985.1 nm | 1623.5 nm | 1829.4 nm | 1789.5 nm |
| roughness | | | | | | |
| Unevenness | 316.2 nm | 982.1 nm | 1323.5 nm | 1756.4 nm | 199.61 nm | 1985.4 nm |
| width | | | | | | |

### (Opening Diameter)

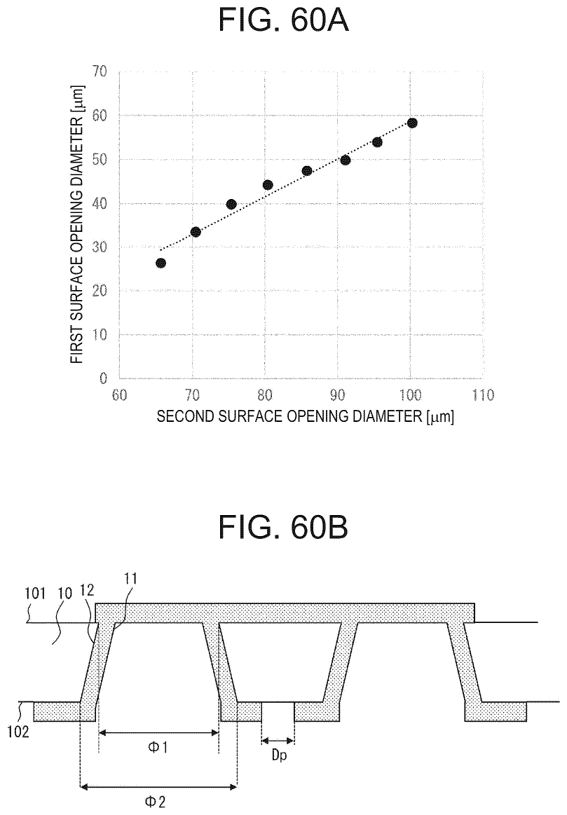

The following describes the relationship between the opening diameters of the first and second surfaces of the through holes in the first embodiment (Supplement 1), using Table 12 and FIG. 60A. Table 12 shows the diameters of each opening on the first surface 101 of the through hole 12 and the diameters of each opening on the second surface 102 thereof when the thickness of the glass substrate 10 is changed from 100 μm to 200 μm under the conditions of Example 1. FIG. 60A is a diagram showing Table 12 in a form of a graph. According to the embodiment, regardless of the opening diameter of the second surface 102, the relationship between the opening diameters of each second surface 102 and the opening diameters of each first surface 101 is “first surface side opening diameter Φ1/second surface side opening diameter Φ2≥0.4”.

TABLE 12

| Second surface | First surface opening | |
|---|---|---|
| opening diameter: Φ2 | diameter: Φ1 | Φ1/Φ2 |
| 100.3 | 58.3 | 0.58 |
| 95.5 | 53.9 | 0.56 |
| 91.1 | 49.8 | 0.55 |
| 85.8 | 47.4 | 0.55 |
| 80.4 | 44.2 | 0.55 |
| 75.4 | 39.8 | 0.53 |
| 70.5 | 33.5 | 0.48 |
| 65.7 | 26.3 | 0.40 |

Unit: μm

Table 13 shows the first surface opening diameter and the second surface opening diameter of each Example and each Comparative Example in the first embodiment (Supplement 1). Table 13 shows typical values of the opening diameters Φ1 on the first surface 101 side of the through holes 12 and the opening diameters Φ2 on the second surface 102 side, measured in each Example and each Comparative Example in the first embodiment (Supplement 1).

TABLE 13

| | Example | Example | Example | Comparative | Comparative | Comparative |
|---|---|---|---|---|---|---|
| | 1 | 2 | 3 | Example 1 | Example 2 | Example 3 |
| Second surface opening | 71.6 | 80.5 | 72.6 | 75.3 | 78.5 | 69.8 |
| diameter Φ2 | | | | | | |
| First surface opening | 33.2 | 60.7 | 46.1 | 54.6 | 45.6 | 57.1 |
| diameter Φ1 | | | | | | |

Unit: μm

The relationship between the opening diameter and the transmission characteristics will now be described with reference to FIG. 60B. FIG. 60B is a schematic diagram showing a case in which the through electrode 12 is formed. As shown by the relationship Φ1/Φ2≥0.4, the through hole 12 can have an opening diameter Φ1 smaller than Φ2. For example, in use for a communication device described later, a coil is formed using the through electrode 11, and the relationship between Φ1 and Φ2 allows the coil to secure the design freedom. In addition, a distance Dp between pads can be secured, so that a Q factor can be reduced when a circuit including a coil is formed, making it possible to reduce transmission loss. The above-described fact makes it possible to stabilize a signal of the through electrode (reduce signal loss).

### (Cross-Sectional Shape)

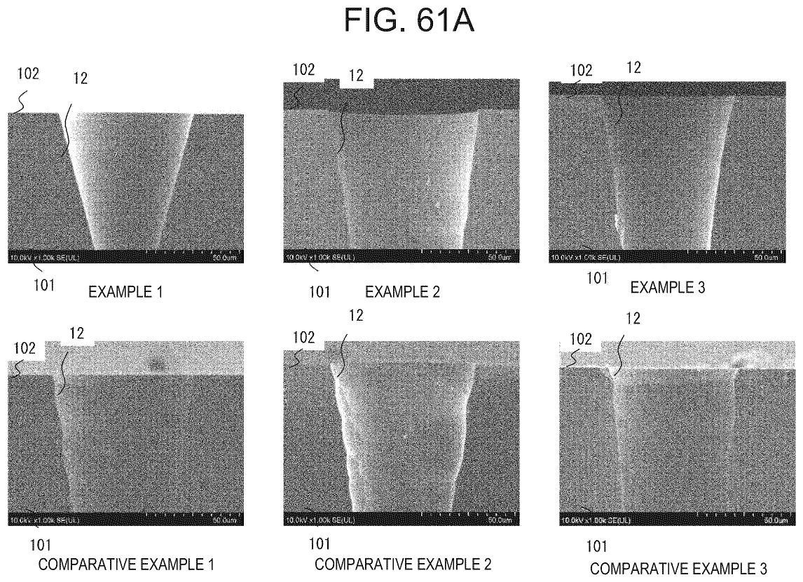

Next, the side surface shape of the through hole 12 will be described. FIGS. 61A to 61C are diagrams describing the side surfaces of the through holes in each Example and each Comparative Example of the first embodiment (Supplement 1). FIGS. 61A to 61C are diagrams showing SEM images of cross sections of the through holes in each Example and each Comparative Example of the first embodiment (Supplement 1).

The SEM images shown in FIGS. 61A to 61C are each obtained by photographing the cut surface of the through hole in the thickness direction of the glass substrate. The images are at a magnification of 1000 times (one division of the scale included in each SEM image is 5 μm).

In the SEM image, the areas that have high contrast and appear white are each a region where the angle of the inclined surface of the sample surface changes to form a ridgeline on the inclined surface. For this reason, the areas that appear as white lines each indicate either a peak or a bottom of the roughness on the sample surface, and the state of presence and degree of placement of the ridgelines formed on the side surface of these through holes makes it possible to understand the roughness of the side surface of the through hole, which affects the transmission characteristics of the through electrode.

In each Example of the first embodiment (Supplement 1) shown in FIG. 61A, white ridgelines appear that extend in a direction parallel or substantially parallel to the first surface 101 of the glass substrate 10, forming a band-like striped pattern.

Now, with reference to FIG. 61B, the ridgelines of the cross section of the through hole will be described. FIG. 61B is a diagram describing the ridgelines of the through hole in each Example of the first embodiment (Supplement 1). FIG. 61B (a) is an enlarged view of Example 3 in FIG. 61A. FIG. 61B (b) is a diagram indicating the ridgelines of the side surface and cross section by solid lines in the observed through hole in the SEM image.

In the example shown in FIG. 61B (b), the widest space between ridgelines among the substantially parallel ridgelines is between a ridgeline Rl1 and a ridgeline Rl2. In the example shown in FIG. 61B (b), the space between the ridgelines on the side surface is less than or equal to Rs in a direction perpendicular to the first surface 101. As shown in FIG. 61B (a), in Example 3, the space between the ridgelines is 15.5 μm or less.

When the state of the ridgelines is observed in the same manner, in Example 1, the space between the ridgelines in the direction perpendicular to the first surface 101 is in a range of 2 μm to 3 μm inclusive. In Example 2, the space between the ridgelines in the direction perpendicular to the first surface 101 of the glass substrate 10 is in a range of 5 μm to 6 μm inclusive.

As is clear from FIG. 61A, as the through hole changes from Example 3 toward Example 1 in the first embodiment (Supplement 1), that is, as the dispersion roughness, which is the smoothness of the side surface of the through hole, decreases, the side surface of the through hole 12 is denser with the white lines, which can be seen as ridgelines extending in a direction parallel to the first surface 101 of the glass substrate 10, and the space between ridgelines decreases. Conversely, as the dispersion roughness increases (i.e., as the through hole changes from Example 1 to Example 3, and further from Comparative Example 1 to Comparative Example 3), the space between the ridgelines increases and the number of ridgelines extending in a direction that is not parallel to the first surface 101 also increases. Furthermore, it can be seen that the occurrence frequency of the following ridgelines increases: ridgelines extending in a direction perpendicular to the first surface 101; and ridgelines extending in a direction between the direction parallel to the first surface 101 and the direction perpendicular to the first surface 101 (hereinafter also referred to as a “diagonal direction”). This indicates that the ratio of ridgelines extending in a vertical direction and ridgelines extending in a diagonal direction decreases as the dispersion roughness decreases. For example, in Example 2, when the mean dispersion roughness is 500 nm and the unevenness width is 980 nm, white lines can be seen that extend in a direction between a direction parallel to the first surface 101 and a direction perpendicular to the first surface 101.

On the other hand, when the side surface of the through hole is rougher (when the mean dispersion roughness is greater than 1,000 nm and the unevenness width is greater than 1,500 nm) as in Comparative Examples 1 to 3 in the embodiment, the ratio of white lines increases that extend in a direction perpendicular to the first surface 101 of the glass substrate 10 or in a direction between a direction perpendicular to the first surface 101 and a direction parallel to the first surface 101. In other words, a plurality of ridgelines can be seen in the diagonal direction. It can be seen that the smoothness (roughness) of the side surface of the through hole 12 appears in the SEM image, and affects the transmission characteristics of the through electrode.

FIG. 61C is a diagram showing a SEM image of a cross section when a through electrode is formed in a through hole in the first embodiment (Supplement 1). As shown here, the areas indicated by arrows and surrounded by dashed lines each have a shape with a raised end. In other words, there is no area that gradually changes between the side surface of the through hole 12 and the second surface 102 of the glass substrate 10, and the angle changes completely in a cross-sectional view. In other words, the side surface of the through hole 12 and the second surface 102 of the glass substrate 10 have a shape with raised ends, and have a shape in which the side surface and the second surface region can be clearly distinguished in a 1000 times SEM image.

### (Transmission Characteristics)

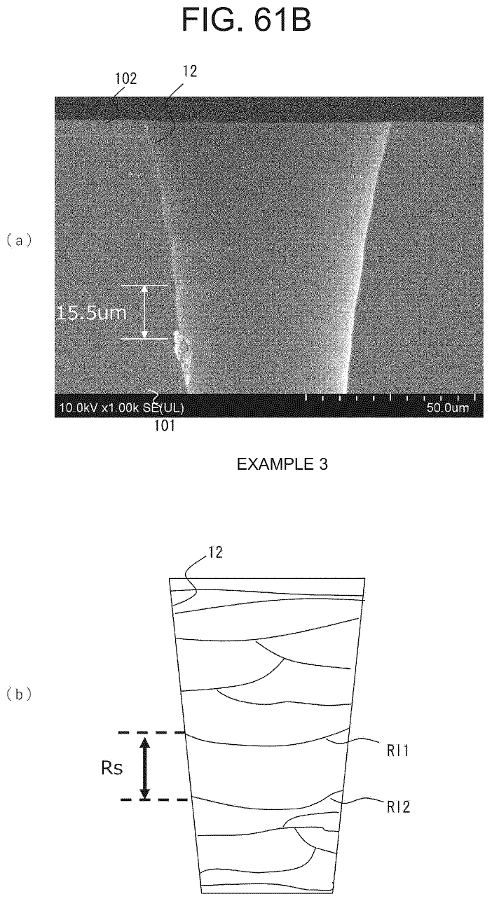

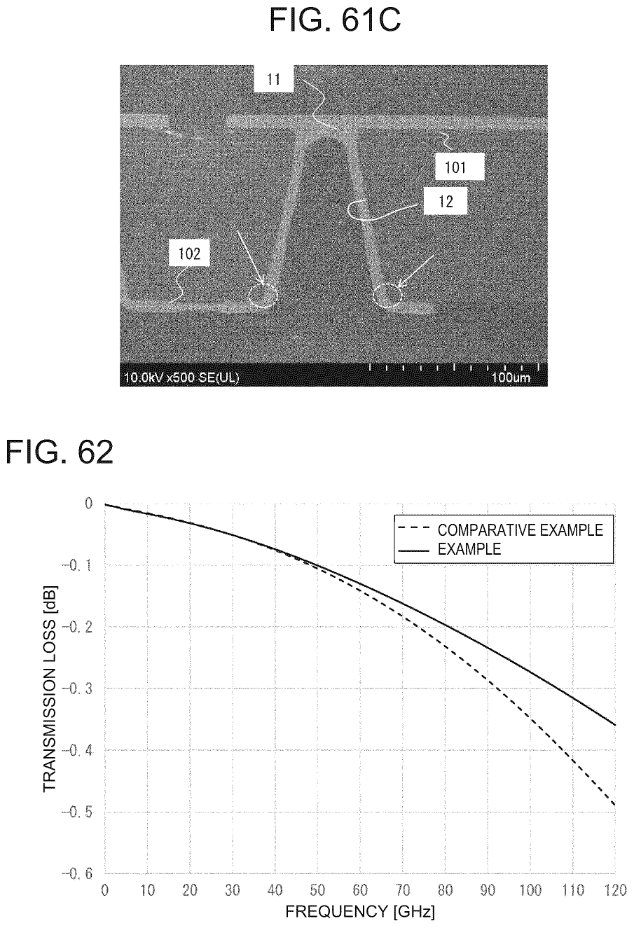

The following describes the transmission characteristics of the through electrodes of each Example and each Comparative Example in the first embodiment (Supplement 1), using FIG. 62. FIG. 62 is a diagram showing transmission characteristics of a through electrode of Example 1 and transmission characteristics of a through electrode of Comparative Example 1 in the embodiment. FIG. 62 shows the results of measuring a transmission loss S21 as the transmission characteristics in the through electrode. The transmission characteristics of Examples 1 to 3 showed the same tendency, and Example 1 is shown as a representative. The transmission characteristics of Comparative Examples 1 to 3 also showed almost the same tendency, and Comparative Example 1 is shown as a representative. The formation conditions for the formation of the seed layer, plating processing, and the like for forming electrodes were the same in both the Examples and Comparative Examples. As shown in FIG. 62, the transmission loss of the Example is smaller than that of the Comparative Example in all frequency regions. This shows that as the side surface of the through hole has smaller values of dispersion roughness and unevenness width, the loss is smaller and the transmission characteristics are more excellent, in the through electrode formed in the through hole.

(Transmission Characteristics when Thickness of Glass Substrate is Changed)

The transmission characteristics S21 were also measured when the thickness of the glass substrate 10 was changed for each Example and each Comparative Example. These results are shown in Table 14. As shown in Table 14, the thicknesses of the glass substrates 10 were set to 100 μm, 150 μm, and 200 μm, the through holes and the through electrodes were created under conditions based on each Example and each Comparative Example, and the transmission characteristics were measured. Table 14 shows that all the Examples in the first embodiment (Supplement 1) have the more excellent transmission characteristics S21 than any of Comparative Examples therein.

Note that the conditions for forming the through electrodes shown in each Comparative Example are the same as those for forming the through electrodes shown in Patent Literature 4. As described in Patent Literature 4, the through electrodes are formed using technique of electroless plating that uses an electrolytic plating solution containing Ni. The plating thicknesses are the same in all the Examples and Comparative Examples.

The transmission characteristics shown in Table 14 are the transmission characteristics of a single through electrode, and in a multilayer wiring substrate that requires a plurality of through electrodes, improving the transmission characteristics of a single through electrode leads to a significant performance improvement. Using each Example according to the first embodiment (Supplement 1) makes it possible to obtain a multilayer wiring substrate that achieves excellent transmission characteristics of the through electrode in a high frequency band compared to existing techniques.

In terms of transmission characteristics, the through electrodes shown in Examples 1 to 3 provide more excellent results than the through electrodes shown in Comparative Examples 1 to 3. Comparison of the Examples demonstrates that Example 1 is the most preferable, followed by Example 2 and Example 3 in this order.

TABLE 14

| | | | | | | | | Comparative | | Comparative | | Comparative | |
|---|---|---|---|---|---|---|---|---|---|---|---|---|---|
| | | Example 1 | | Example 2 | | Example 3 | | Example 1 | | Example 2 | | Example 3 | |
| | | | Deter- | | Deter- | | Deter- | | Deter- | | Deter- | | Deter- |
| Fre- | Glass | Measured | mina- | Measured | mina- | Measured | mina- | Measured | mina- | Measured | mina- | Measured | mina- |
| quency | thickness | value | tion | value | tion | value | tion | value | tion | value | tion | value | tion |
| 5 GHz | 100 μm | 0.0079 | Good | 0.0082 | Good | 0.0087 | Good | 0.0090 | | 0.0090 | | 0.0090 | |
| | 150 μm | −0.0083 | Good | −0.0087 | Good | −0.0094 | Good | −0.0098 | — | −0.0099 | — | −0.0099 | — |
| | 200 μm | −0.0091 | Good | −0.0101 | Good | −0.0106 | Good | −0.0111 | — | −0.0112 | — | −0.0112 | — |
| 10 GHz | 100 μm | −0.0140 | Good | −0.0148 | Good | −0.0154 | Good | −0.0157 | — | −0.0157 | — | −0.0157 | — |
| | 150 μm | −0.0145 | Good | −0.0156 | Good | −0.0165 | Good | −0.0169 | — | −0.0170 | — | −0.0170 | — |
| | 200 μm | −0.0161 | Good | −0.0189 | Good | −0.0189 | Good | −0.0193 | — | −0.0194 | — | −0.0194 | — |
| 20 GHz | 100 μm | 0.0293 | Good | 0.0302 | Good | 0.0309 | Good | 0.0314 | | 0.0314 | | 0.0314 | |
| | 150 μm | −0.0288 | Good | −0.0298 | Good | −0.0315 | Good | −0.0321 | — | −0.0321 | — | −0.0321 | — |
| | 200 μm | −0.0312 | Good | −0.0379 | Good | −0.0352 | Good | −0.0357 | — | −0.0358 | — | −0.0358 | — |
| 28 GHz | 100 μm | −0.0442 | Good | −0.0456 | Good | −0.0463 | Good | −0.0469 | — | −0.0469 | — | −0.0469 | — |
| | 150 μm | 0.0441 | Good | 0.0450 | Good | 0.0468 | Good | 0.0471 | | 0.0471 | | 0.0471 | |
| | 200 μm | −0.0486 | Good | −0.0595 | Good | −0.0537 | Good | −0.0542 | — | −0.0544 | — | −0.0544 | — |
| 56 GHz | 100 μm | 0.0851 | Good | 0.0914 | Good | 0.1040 | Good | 0.1337 | | 0.1457 | | 0.1517 | |
| | 150 μm | −0.0976 | Good | −0.1013 | Good | −0.1160 | Good | −0.1537 | — | −0.1875 | — | −0.1915 | — |
| | 200 μm | 0.1094 | Good | 0.1213 | Good | 0.1340 | Good | 0.1854 | | 0.1984 | | 0.2184 | |
| 84 GHz | 100 μm | −0.1891 | Good | −0.2014 | Good | −0.2114 | Good | −0.2527 | — | −0.2727 | — | −0.2827 | — |
| | 150 μm | 0.2004 | Good | 0.2212 | Good | 0.2114 | Good | 0.2827 | | 0.3127 | | 0.3193 | |
| | 200 μm | −0.2114 | Good | −0.2421 | Good | −0.2114 | Good | −0.3027 | — | −0.3374 | — | −0.3474 | — |

### <Configuration of Multilayer Wiring Substrate According to First Embodiment (Supplement 1)>

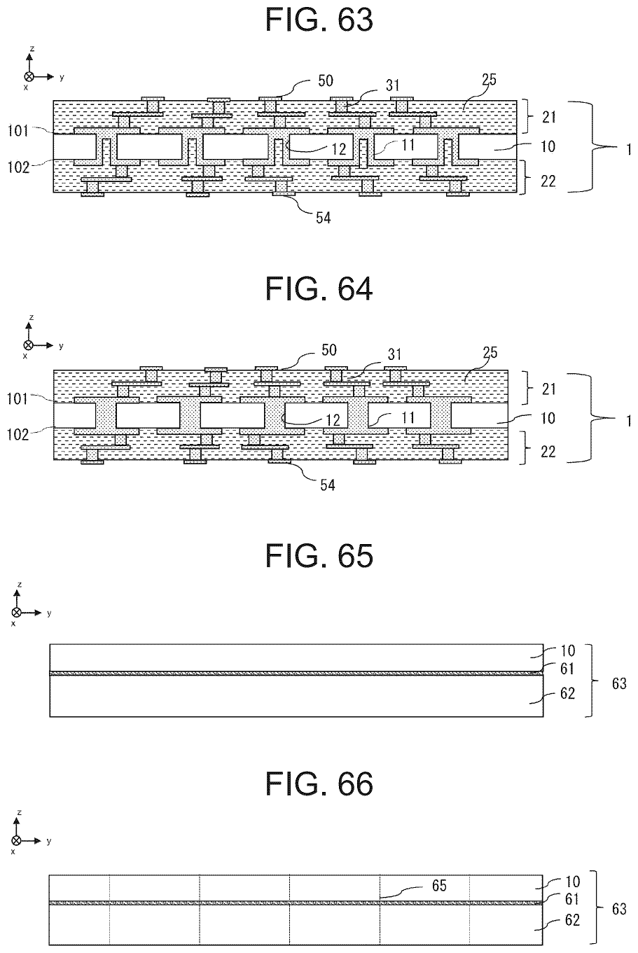

FIG. 63 is a diagram showing an example of a configuration of a multilayer wiring substrate 1 according to the first embodiment (Supplement 1). FIG. 64 is a diagram showing another example of a configuration of the multilayer wiring substrate 1 according to the first embodiment (Supplement 1). The multilayer wiring substrate 1 includes the glass substrate 10, the first wiring layer 21, and the second wiring layer 22. The first wiring layer 21 is disposed on the first surface 101 side of the glass substrate 10, and the second wiring layer 22 is disposed on the second surface 102 side of the glass substrate 10. The glass substrate 10 includes the through holes 12 penetrating from the first surface 101 side to the second surface 102 side. Each through electrode 11 is formed of a conductor formed along the side surface of the through hole 12. The through electrode 11 electrically connects part of the first wiring layer 21 and part of the second wiring layer 22. The first wiring layer 21 and the second wiring layer 22 each include the insulating resin layer 25. The first wiring layer 21 and the second wiring layer 22 may also be configured with a plurality of layers laminated, and the number of layers may be set as necessary. The through electrode 11 is an electrode for establishing an electrical connection between the first wiring layer 21 and the second wiring layer 22. A conductive electrodes 31 are each an electrode for ensuring electrical continuity in the thickness direction of the multilayer wiring substrate 1. Semiconductor power device joining pads 50 are members for connecting semiconductor circuits to be mounted on the multilayer wiring substrate 1. Substrate joining pads 54 are members for joining the multilayer wiring substrate 1 to another substrate or another semiconductor power device.

As long as the through electrode can electrically connect the first surface 101 side to the second surface 102 side of the glass substrate 10, a conductor may be disposed only on the side surface of the through hole 12 as shown in FIG. 63, or a conductor may be embedded in the through hole 12 as shown in FIG. 64.

In addition, in the first embodiment (Supplement 1), the conductive electrode 31 can be placed on the Z-axis of the through electrode 11 in the first wiring layer 21.

Note that the shapes of the through holes 12 are shown with details omitted in FIGS. 63 and 64. Similarly, the detailed shapes thereof are omitted in FIGS. 65 to 74.

The thickness of the multilayer wiring substrate 1 is, for example, in a range of 100 μm to 200 μm inclusive.

### <Method for Producing Multilayer Wiring Substrate in First Embodiment (Supplement 1)>

Next, a method for producing the multilayer wiring substrate 1 will be described with reference to FIGS. 65 to 74. First, a step of forming the through holes 12 in the glass substrate 10 will be described.

### [Bonding Step of First Support]

FIG. 65 is a diagram showing a step of bonding the glass substrate 10 to a first support 62. The thickness of the glass substrate 10 can be set appropriately depending on the application, taking into account the thickness after etching.

As shown in FIG. 65, the glass substrate 10 and the first support 62 are bonded together at a first bonding layer 61, and a laminated structure 63 is formed that includes the glass substrate 10, the first bonding layer 61, and the first support 62.

Note that the glass substrate 10 and the first support 62 are temporarily fixed by the first bonding layer 61.

To bond the first support to the glass substrate 10, for example, a laminator, a vacuum pressure press, a reduced pressure bonding machine, or the like can be used.

The first support 62 is desirably made of the same material as the glass substrate 10, for example. When the glass substrate 10 is made of alkali-free glass with a SiO₂ ratio in the range of 55 mass % to 81 mass % inclusive, it is desirable that the first support 62 be also made of alkali-free glass. The thickness of the first support 62 can be set appropriately depending on the thickness of the glass substrate 10. However, the thickness of the first support 62 is desirably such that the first support 62 can be transported during the step of producing, and the thickness of the first support 62 is, for example, in a range of 300 μm to 1,500 μm inclusive.

The glass substrate 10 can use, for example, alkali-free glass with a SiO₂ ratio in the range of 55 mass % to 81 mass % inclusive. If the SiO₂ ratio of the glass substrate 10 is greater than 81 mass %, the processing rate of etching decreases, the flatness of the angle of the side surface of the through hole 12 decreases, and poor adhesion will occur in forming the through electrode 11, which will be described later. If the SiO₂ ratio is less than 55 mass %, alkali metals are highly likely to be contained in the glass, which will affect the reliability of the multilayer wiring substrate after the electronic device is mounted. If the SiO₂ ratio of alkali-free glass is 55 mass % to 81 mass % inclusive, the set ratio may be set appropriately.

### [Laser Modification Step]

Next, FIG. 66 is a diagram showing a step of forming laser modified portions. Laser modified portions 65 are formed in the glass substrate 10 by irradiating the portions of the glass substrate 10 where through holes are to be formed with a laser. The laser modified portion 65 is processed into a shape of Φ3 μm or less on the glass substrate 10, and is formed continuously in the thickness direction of the glass substrate 10. At this time, it is desirable that there occur no fine cracks (hereinafter also referred to as “microcracks”) of 5 μm or more around the laser modified portion 65 (hereinafter also referred to as a “peripheral portion of the laser irradiation”). When microcracks of 10 μm or more occur around the laser modified portion 65, the dispersion roughness of the side surface of the through hole 12 after etching will be 1000 nm or more, and the unevenness width thereof will be 1500 nm or more. This makes it difficult to obtain the through hole 12 with a smooth side surface.

When microcracks of 5 μm or more occur, the SEM image of the side surface of the through hole 12 after etching visibly shows not only the ridgelines extending in a direction parallel to the first surface 101 of the glass substrate 10, but also ridgelines extending in a direction perpendicular to the first surface 101 and ridgelines extending in a direction between the direction parallel to the first surface 101 and the direction perpendicular to the first surface 101, as is described later.

For processing the laser modified portion 65, it is preferable to use, for example, a femtosecond laser or a picosecond laser, and to use a laser emission wavelength of any one of 1064 nm, 532 nm, and 355 nm. If the laser pulse width is 25 picoseconds or more, microcracks of 5 μm or more are likely to occur around the laser modified portion 65. For this reason, the laser pulse width is desirably 25 picoseconds or less. In addition, since microcracks are likely to occur if processing is performed by a plurality of times of pulse irradiation, the laser modified portion 65 is desirably formed by one pulse. Under the condition that does not generate microcracks of 5 μm or more around the laser modified portion 65, the laser emission wavelength and laser output may be appropriately set depending on the thickness of the glass substrate 10. In other words, in the laser modification step (first step), the glass substrate is irradiated with a laser at the portion where the through hole is to be formed, and the microcracks that occur in a peripheral portion of the laser irradiation have a maximum length of 5 μm.

### [Formation of First Wiring Layer]

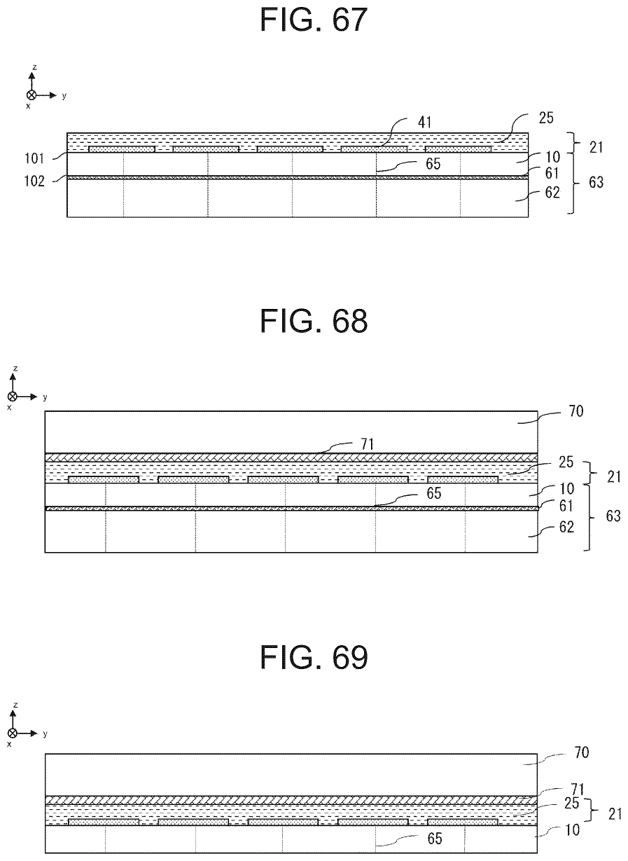

Next, FIG. 67 is a diagram showing a step of forming the first wiring layer 21. As shown in FIG. 67, the first wiring layer 21 consisting of a conductive layer and an insulating resin layer is formed on the first surface 101 on the glass substrate 10 of the laminated structure 63. Here, a seed layer including a hydrofluoric acid resistant metal layer is formed on the glass substrate 10, and then through electrode connection portions 41 (or wiring between the through electrodes) are formed on the first surface 101 through a semi-additive process (SAP). The unnecessary seed layer is removed, and then the insulating resin layer 25 is formed.

In the formation of the seed layer, the hydrofluoric acid resistant metal layer on the glass substrate 10 is an alloy layer containing chromium, nickel, or both, and can be formed in a range of 10 nm to 1,000 nm inclusive by sputtering processing. After that, a conductive metal film is formed to the desired thickness on the hydrofluoric acid resistant metal. The conductive metal film can be appropriately set from, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, and Cu₃N₄.

In the semi-additive process, a photoresist is used to form a desired pattern to form a wiring pattern by plating. Generally, a dry film resist is used, but a liquid resist can also be used. The desired pattern is formed through exposure and development, a plating film is then formed through electrolytic plating, the unnecessary resist is peeled, and the seed layer is etched, thereby making it possible to form wiring.

### [Insulating Resin Layer]

Next, in the formation of the insulating resin layer 25, the insulating resin layer 25 is made of thermosetting resin, and the material thereof is a material that contains at least one of epoxy resin, polyimide resin, and polyamide resin, and that contains silica SiO₂ filler. The material of the insulating resin layer 25 can be appropriately selected as necessary. However, when a photosensitive insulating resin material is used, filling the silica SiO₂ filler is difficult for ensuring photolithography properties. For this reason, a photosensitive insulating resin material can also be used, but it is more preferable to use thermosetting resin.

### [Bonding Step of Second Support]

Next, FIG. 68 is a diagram showing a step of bonding a second support. As shown in FIG. 68, a second bonding layer 71 is formed on the first wiring layer 21 of the laminated structure 63, and a second support 70 is placed and bonded on the second bonding layer 71.

The second support 70 can use, for example, glass, and is desirably made of the same material as the glass substrate 10. When the glass substrate 10 is alkali-free glass, the second support 70 is also desirably made of alkali-free glass. The thickness of the second support 70 can be set appropriately depending on the thickness of the glass substrate 60. However, the thickness is desirably such that the second support 70 can be transported, and the thickness is in a range of 300 μm to 1,500 μm inclusive.

### [Peeling Step]

Next, FIG. 69 shows a step of peeling the first support. As shown in FIG. 69, the first support 62 is peeled off the glass substrate 10 at the first bonding layer 61.

### [Formation of Through Holes]

Next, FIG. 70 shows a step of forming the through hole 12.

### [Etching Step]

The glass substrate 10 in which the laser modified portions 65 are formed is subjected to etching processing with a predetermined etching solution to form the through holes 12. At the same time, the second surface of the glass substrate 10 is also etched, and the thickness of the glass substrate 10 decreases.

### [Etching Solution]

The etching solution to be used contains hydrofluoric acid in a range of 0.2 mass % to 20.0 mass % inclusive, nitric acid in a range of 4.0 mass % to 25.0 mass % inclusive, and inorganic acid other than hydrofluoric acid and nitric acid in a range of 0.5 mass % to 11.0 mass % inclusive. Examples of inorganic acids other than hydrofluoric acid and nitric acid include hydrochloric acid, sulfuric acid, phosphoric acid, and sulfamic acid. At least one inorganic acid is contained depending on the type of components other than silicon contained in the glass substrate 10. Desirably, the etching solution contains hydrochloric acid and sulfuric acid. The etching rate for the glass substrate 10 is appropriately adjusted to be in a range of 0.1 μm/min to 10 μm/min inclusive. The etching rate for the glass substrate 10 is desirably in a range of 0.25 μm/min to 4 μm/min inclusive, and more desirably in a range of 0.25 μm/min to 0.5 μm/min inclusive. The etching temperature is not particularly limited and can be adjusted appropriately, and is, for example, in a range of 10° C. to 30° C. inclusive.

In the step of forming the through holes 12 by etching, the concentration of hydrofluoric acid may be lowered and etching may be performed a plurality of times. An example is such that: the etching rate for the glass substrate 10 in the first etching processing is in a range of 4 μm/min to 10 μm/min inclusive; the etching rate for the glass substrate 10 in the second etching processing is in a range of 0.5 μm/min to 4 μm/min inclusive; and then the etching rate for the glass substrate 10 in the third etching processing is in a range of 0.25 μm/min to 0.5 μm/min inclusive. The number of etching processing times may be set appropriately so that the roughness of the side surface of the through holes falls within the desired range.

### [Formation of Through Electrode]

Next, a step of forming the through electrodes 11 will be described with reference to FIG. 71. FIG. 71 is a diagram showing a step of forming the through electrodes 11.

A metal layer for electrolytic plating processing is formed on the second surface 102 of the glass substrate 10 in which the through holes 12 are formed. The metal layer just needs to be made of any metal that functions as a seed layer for electrolytic plating processing, such as metals including Cu, Ti, Cr, W, Ni, or the like. The metal layer uses at least one of the above-mentioned metals. The metal layer desirably has a Cu layer formed on its outermost surface. Ti, Cr, W, and Ni are desirably used as an adhesion layer with the glass substrate 10 under the Cu layer. The thickness of the metal layer is appropriately set to a range that can cover the side surface of each through hole 12. The formation method to be employed can be, for example, a formation method through deposition using sputtering.

Subsequently, the through electrodes 11 are formed by electrolytic plating processing that uses the above-mentioned metal layer as the seed layer. To selectively grow the through holes 12, a mask is formed with an insulator such as a resist on the second surface 102 of the glass substrate 10 except for a predetermined range of the through hole 12 and around the through hole 12, and then electrolytic plating processing is performed. As a material used for electrolytic plating processing, for example, Cu can be used, and other metals including Au, Ag, Pt, Ni, Sn, or the like can also be used. Depending on the application of the multilayer wiring substrate, electrolytic plating processing may be performed so that the through holes 12 are filled with the above-mentioned metal conductors.

### [Formation of Insulating Resin Layer]

A step of forming the insulating resin layer 25 will be described with reference to FIG. 72. FIG. 72 is a diagram showing a step of forming the insulating resin layer. After electrolytic plating processing for forming the through electrodes, the insulator such as a resist is removed, the metal films are removed that are formed on the first surface 101 and the second surface 102 of the glass substrate 10, and the plurality of through electrodes 11 formed on the glass substrate 10 are electrically isolated from each other, and then the insulating resin layer 25 is formed on the second surface side as shown in FIG. 72.

### [Peeling of Second Support]

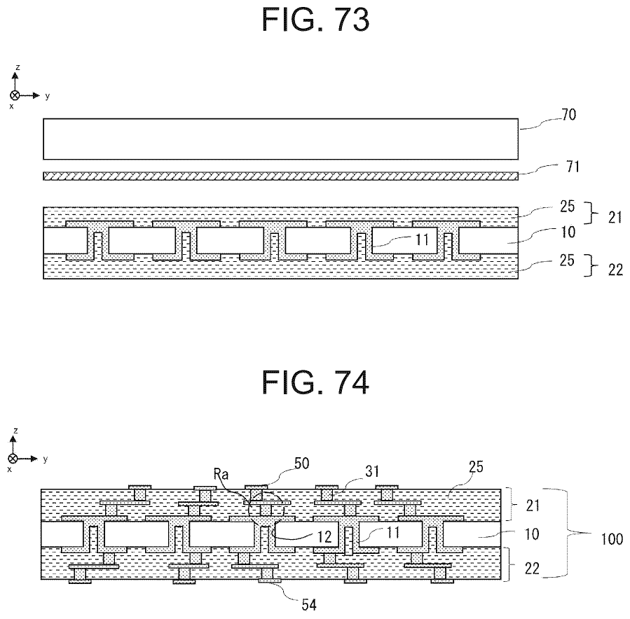

The following describes a step of peeling the second support 70 and the second bonding layer 71 with reference to FIG. 73. FIG. 73 is a diagram showing a step of peeling the second support 70 and the second bonding layer 71. As shown in FIG. 73, the second bonding layer 71 and the second support 70 formed above the first wiring layer 21 are peeled off the interface between the first wiring layer 21 and the second bonding layer 71 on the first surface 101 side. As a result, as shown in FIG. 73, the glass substrate 10 is obtained in which the first wiring layer 21 is formed on the first surface 101 side and the second wiring layer 22 is formed on the second surface 102 side.

When the second support 70 is peeled off the second wiring layer 22, a peeling method can be appropriately selected from UV light irradiation, heat treatment, physical peeling, or the like depending on the material used for the second bonding layer 71. In addition, if there is a residue of the second bonding layer 71 on the joining surface between the first wiring layer 21 and the second bonding layer 71, the following may be performed: plasma cleaning, ultrasonic cleaning, water washing, solvent cleaning using alcohol, or the like.

### [Formation of First Wiring Layer and Second Wiring Layer]

The following describes formation of the first wiring layer 21 and the second wiring layer 22 formed on the glass substrate 10 with reference to FIG. 74. FIG. 74 is a diagram showing a step of forming the first wiring layer 21 and the second wiring layer 22. For the glass substrate 10 on which the through electrodes 11 are formed, the first wiring layer 21 is formed on the first surface 101, and the second wiring layer 22 is formed on the second surface 102. In the step of forming the first wiring layer 21 and the second wiring layer 22, a mask having a pattern is first formed with a photosensitive resist, a dry film resist or the like, and wiring is then formed by electrolytic plating processing. After that, physical adhesion processing or chemical adhesion processing is performed, and then the insulating resin layer 25 is laminated. For the conductive electrodes 31, holes are formed in the insulating resin layer 25 by laser processing or the like, and then a metal film is formed by electroless plating or deposition processing by sputtering. A mask having a pattern is formed on the above-mentioned metal film using resist, and the holes formed by electrolytic plating are filled with a conductor. The mask and excess metal film are then removed. The above-mentioned step is repeated a plurality of times depending on the number of layers required, to form the first wiring layer 21 and the second wiring layer 22. Note that the first wiring layer 21 and the second wiring layer 22 desirably have the same number of layers in order to prevent warping of the multilayer wiring substrate 1. If the layer thicknesses of the first wiring layer 21 and the second wiring layer 22 are different, the number of layers may be different between the first wiring layer 21 and the second wiring layer 22. The number of layers of the first wiring layer 21 and the number of layers of the second wiring layer 22 may be set appropriately depending on the application of the multilayer wiring substrate.

### Second Embodiment (Supplement 1)

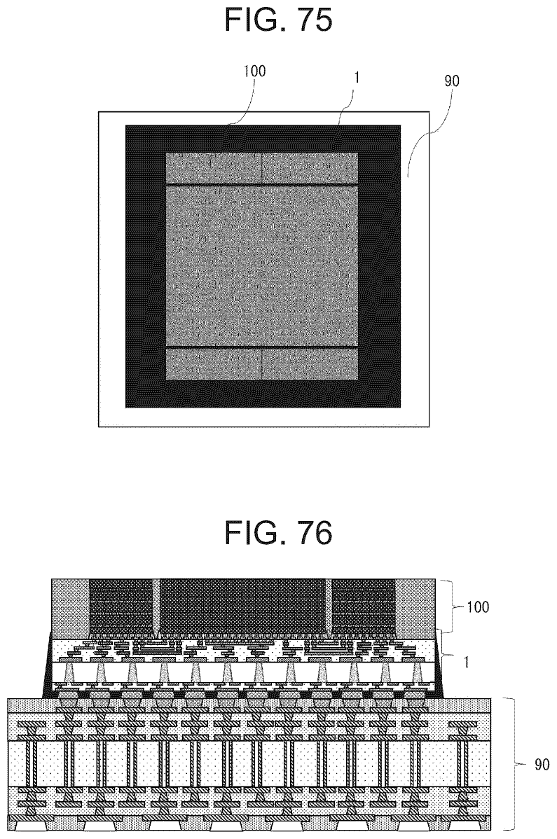

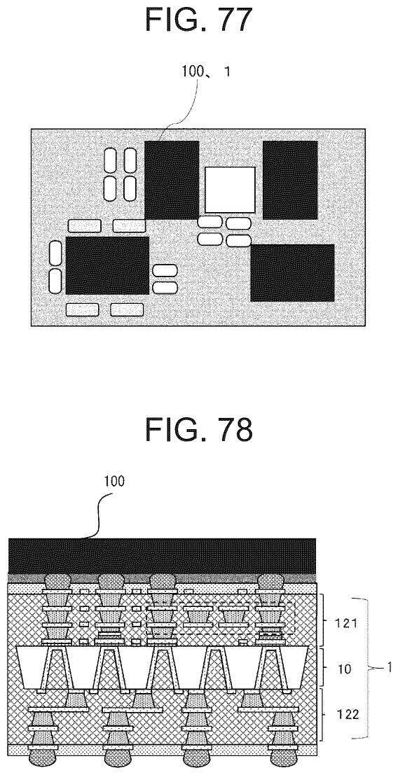

FIG. 75 is a diagram showing a case in which the multilayer wiring substrate 1 is used as an interposer substrate for a semiconductor power device 100 and a BGA (Ball Grid Array) substrate 90. FIG. 76 is a diagram showing a cross section of the case of FIG. 75. FIG. 77 is a diagram showing a case in which the multilayer wiring substrate 1 and the semiconductor power device 100 are used in an electronic device for communication. FIG. 78 is a diagram showing a cross section of the case of FIG. 77. The electronic device to be used has a layer thickness of 800 μm or less. The above-described electronic device has limited applications to which the device is adapted due to the effect of the transmission characteristics of the through electrodes, and the use of the glass substrate of the present invention allows the electronic device to be adapted to a high frequency band region.

### (Features of Through Holes and Through Electrodes of Present Disclosure)

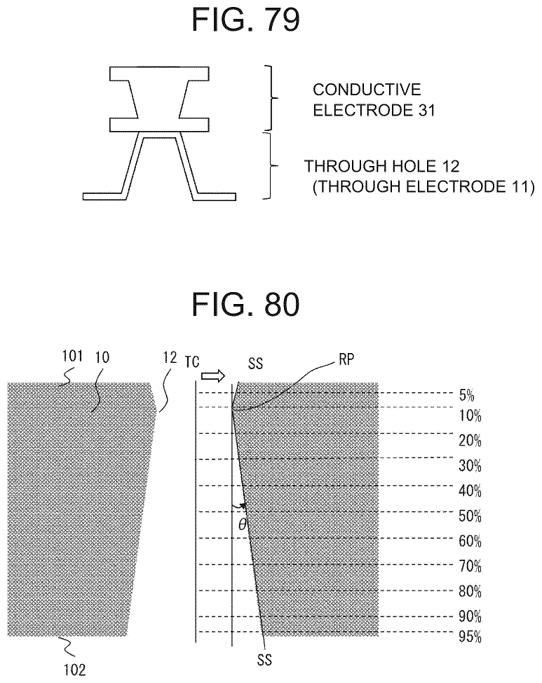

FIG. 79 is a diagram describing the features of the through hole and the through electrode formed in the present disclosure. FIG. 79 is a diagram showing an enlarged view of a region Ra in FIG. 74, for example. As shown in FIG. 79, a conductive electrode 31 can be formed directly on the through hole 12 (or the through electrode 11). This is because the through hole 12 has a so-called bottomed shape. The bottomed shape allows the conductive electrode 31 to be formed directly on the through hole 12. This shortens a transmission distance of the electrode as a whole, and allows the transmission characteristics to be improved and the through hole 12 to be finer.

Also, as described in the embodiment, the side surface of the through hole 12 in the present disclosure has no inflection point at which the side surface shape changes, and the surface is smooth. Thus, a uniform metal film or the like can be formed in plating processing on the through hole 12, so that the generation of parasitic capacitance can be prevented on the side surface of the through hole 12. The shape of the through hole 12 can be a shape with an inflection point or a so-called straight shape in which the diameters vary little from the first surface to the second surface of the glass substrate. However, from the viewpoint of transmission characteristics, the shape shown in the present disclosure, which can prevent the generation of parasitic capacitance, is desirable.

### <Actions and Effects>

The through hole formed in the present disclosure has a truncated cone shape. When the through electrode 11 is formed in the through hole 12, and a metal layer that is to be a seed layer is formed through sputtering, the metal can be selected from a plurality of metals. While Ni is selected in Patent Literature 4, in the present disclosure, the through electrode does not necessarily use Ni to be formed. This allows the through electrode to be easily formed.

As described above, according to the embodiments of the present invention, and the producing method and Examples according to the embodiments of the present invention, the side surface of the through hole can be formed smoothly, and the transmission characteristics of the through electrode can be improved compared to existing techniques. Using the present invention enables providing a multilayer wiring substrate with excellent transmission characteristics in a high frequency band.

### (Other Aspects for Implementation)

The present disclosure also includes the following aspects.

### (Aspect 1 (Supplement 1))

A glass substrate having a first surface and a second surface, the glass substrate comprising at least one through hole penetrating from the first surface to the second surface, wherein
a side surface of the through hole has an inclination angle in a range of 7° to 15° inclusive at a position in a section of 5% to 95% inclusive from the first surface, and
when the side surface of the through hole is regarded as a left side surface and a right side surface in a cross-sectional view, a difference between an inclination angle of the left side surface and an inclination angle of the right side surface is 1.0° or less.

### (Aspect 2 (Supplement 1))

The glass substrate according to Aspect 1, wherein a side surface of the through hole has an inclination angle in a range of 7° to 15° inclusive, from the second surface to a position at a distance of 95%.

### (Aspect 3 (Supplement 1))

The glass substrate according to Aspect 1 or 2, wherein a relationship between an opening diameter Φ2 on the second surface side and an opening diameter Φ1 on the first surface side is Φ1/Φ2≥0.4.

### (Aspect 4 (Supplement 1))

The glass substrate according to any one of Aspects 1 to 3, wherein a cut surface of the through hole in a thickness direction of the glass substrate has a shape of a side surface, the shape having a dispersion roughness of 1,000 nm or less and an unevenness width of 1,500 nm or less.

### (Aspect 5 (Supplement 1))

The glass substrate according to any one of Aspects 1 to 4, wherein
the dispersion roughness is an arithmetic mean roughness calculated with Expression 1 in a set section, the set section being set in a roughness curve, the roughness curve being extracted based on contour data of the side surface, and
the unevenness width is a difference between highest and lowest parts in the set section.

$$\begin{matrix}[ Expression 2 ] & \\ Ra = \frac{1}{L} {\int }_{0}^{L} {\vert f ( x ) \vert}^{2} {dx}^{\cdot \cdot } & Expression 1\end{matrix}$$

$$where : Ra is an arithmetic mean roughness .$$

$$f ( x ) is a roughness curve ; and$$

$$L is a length of a set section .$$

### (Aspect 6 (Supplement 1))

The glass substrate according to any one of Aspects 1 to 5, wherein an SiO₂ ratio of the glass substrate is in a range of 55 mass % to 81 mass % inclusive.

### (Aspect 7 (Supplement 1))

A multilayer wiring substrate comprising the glass substrate according to any one of Aspects 1 to 6, wherein
an electronic device mounted on the multilayer wiring substrate has a layer thickness of 800 μm or less, and
the multilayer wiring substrate has a thickness in a range of 100 μm to 200 μm inclusive.

### (Aspect 8 (Supplement 1))

A method for producing the glass substrate according to any one of Aspects 1 to 7, the method comprising:
a first step of irradiating a portion of the glass substrate with a laser, the portion being where the through hole is to be formed; and
a second step of etching the glass substrate irradiated with the laser to form the through hole.

### (Aspect 9 (Supplement 1))

The method for producing a glass substrate according to Aspect 8, wherein
a hydrofluoric acid resistant metal film is formed on the first surface of the glass substrate, and
in the second step, etching is performed from the second surface of the glass substrate.

### (Aspect 10 (Supplement 1))

The method for producing a glass substrate according to Aspect 8 or 9, wherein the laser radiated in the first step has any of laser emission wavelengths of 1064 nm, 532 nm, and 355 nm, and has a pulse width of 25 picoseconds or less.

### (Aspect 11 (Supplement 1))

The method for producing a glass substrate according to any one of Aspects 8 to 10, wherein, in the first step, a maximum length of a microcrack occurring in a peripheral portion of the laser irradiation is 5 μm.

### (Aspect 12 (Supplement 1))

The method for producing a glass substrate according to any one of Aspects 8 to 11, wherein, in the second step, etching is performed a plurality of times with different etching rates.

### (Aspect 13 (Supplement 1))

The method for producing a glass substrate according to any one of Aspects 8 to 12, wherein, in the second step, an etching solution is used that contains hydrofluoric acid in a range of 0.2 mass % to 20.0 mass % inclusive, nitric acid in a range of 4.0 mass % to 25.0 mass % inclusive, and an inorganic acid other than hydrofluoric acid and nitric acid in a range of 0.5 mass % to 11.0 mass % inclusive.

### (Supplement 2)

Still another aspect of the present disclosure are shown below.

The present invention relates to a glass substrate, a multilayer wiring substrate, and a method for producing a glass substrate.

### Background Art

Recently, three-dimensional mounting technique has been used in which circuit boards are laminated. In such a mounting technique, through electrodes are formed in the circuit board. The through electrodes are formed by forming through holes in a substrate made of an insulator and disposing conductors in the through holes. Higher integration of circuit boards also requires finer through holes.

For example, Patent Literature 1 discloses a technique for providing a glass substrate having a plurality of through holes by irradiating a plate-like glass with an excimer laser light. Patent Literature 2 discloses a method for manufacturing a high-density array of holes in glass, the method including a step of irradiating a front surface of a glass product with a UV laser beam. Patent Literature 3 discloses a through electrode substrate including: a substrate including a through hole; and a conductor disposed along an inner side surface of the through hole, wherein the substrate has a first surface and a second surface, and the through hole has a through hole shape that satisfies a condition in which a sum of inclination angles of the inner side surface with respect to a central axis of the through hole is 8.0° or more, where: an inclination angle expanding toward the first surface side is defined as a positive inclination angle; and the inclination angles are inclination angles at distances from the first surface, the distances being 6.25%, 18.75%, 31.25%, 43.75%, 56.25%, 68.75%, 81.25%, and 93.75% of a length of a section from the first surface to the second surface.

### CITATION LIST

### Patent Literature

<Patent Literature 1> International Publication No. 2010/087483
<Patent Literature 2> Japanese Translation of PCT International Application Publication No. 2014-501686
<Patent Literature 3> Japanese Patent Publication No. 6809511

### SUMMARY OF INVENTION

### Technical Problem

However, the contents described in Patent Literatures 1 to 3 do not discuss the effect of the side surface roughness of the through hole on the transmission characteristics of the through electrode. For this reason, the side surface of the through hole described in Patent Literatures 1 to 3 has a dispersion roughness of 1,000 nm or more and a PV (Peak to Valley) of 1,500 nm or more. This makes it difficult to maintain the sufficiently excellent transmission characteristics of the through electrode, especially in high frequency bands such as the sub-6 GHz band among the frequency bands used for 5G, due to the roughness of the side surface of the through hole.

In addition, when wiring layers are formed on a glass substrate and through electrodes are formed to connect them, the effect of thermal stress is a concern because the CTE (Coefficient of Thermal Expansion) of glass differs from the CTE of Cu or the like, which is the material of the wiring and through electrodes. For this reason, the TCT (Thermal Cycle Test), which is an accelerated test, is performed as one of the reliability tests to evaluate the reliability of the device.

However, in the conventional technique, the through hole shape has not been sufficiently considered to improve the reliability of the through electrodes against thermal stress, and it is confirmed that the wiring layers have broken each at the interface between the through electrodes and the wiring layer.

An object of the present invention is to provide a glass substrate capable of forming a through electrode with excellent transmission characteristics and high reliability, and a multilayer wiring substrate including such a glass substrate.

### Solution to Problem

To solve the above-mentioned problems, one typical glass substrate of the present invention is a glass substrate that has a first surface and a second surface and includes at least one through hole penetrating from the first surface to the second surface, in which a side surface of the through hole is such that: a side surface angle is in a range of 4° to 7° inclusive at a distance in a range from 0% or more to less than 10% from the first surface, and when the side surface of the through hole is regarded as a left side surface and a right side surface in a cross-sectional view, a difference between an inclination angle of the left side surface and an inclination angle of the right side surface is 1.0° or less; and a side surface angle is in a range of −7° to −15° inclusive at a distance in a range from 10% to 100% inclusive from the first surface, and a difference between an inclination angle of the left side surface and an inclination angle of the right side surface is 1.0° or less.

### Advantageous Effects of Invention

According to the present invention, it is possible to provide a glass substrate capable of forming a through electrode with excellent transmission characteristics and high reliability, and a multilayer wiring substrate including such a glass substrate.

Problems, configurations, and effects other than those described above will be made clear by the following explanation of embodiments of the invention.

### DESCRIPTION OF EMBODIMENTS

The scope of the present invention is not limited to the exemplary embodiments and Examples illustrated and described, and includes various modified examples. For example, the embodiments and the Examples according to the present disclosure are described in detail to describe the present invention in an easy-to-understand manner, and the scope of the present invention is not necessarily limited to those including all of the configurations described. It is also possible to replace part of the configuration of a certain embodiment and Example with the configuration of another embodiment and Example, and it is also possible to add the configuration of another embodiment and Example to the configuration of a certain embodiment and Example. In addition, part of the configuration of each embodiment and each Example can have another configuration added thereto, can be deleted, or can be replaced with another configuration.

Furthermore, all embodiments are also included that bring about an effect equivalent to the object of the present invention.

The position, size, shape, range, or the like of each component shown in the drawings may not represent the actual position, size, shape, range, and the like, in order to make the invention easier to understand. For this reason, the present invention is not necessarily limited to the position, size, shape, range, and the like disclosed in the drawings.

In the present disclosure, the term “surface” may refer not only to the surface of a plate-like member, but also to the interface of a layer contained in a plate-like member that is substantially parallel to the surface of the plate-like member. Additionally, “upper surface” or “lower surface” means the surface shown on the upper side or lower side on a drawing when a plate-like member or a layer contained in a plate-like member is illustrated. The “upper surface” and the “lower surface” are sometimes referred to as a “first surface” a “second surface”.

A term “side surface” means a thickness portion of a surface or a layer in a plate-like member or a layer contained in a plate-like member. Part of a surface and a side surface may be collectively referred to as an “end portion”.

A “side surface of a through hole” means the interface on an object that forms the through hole, in the through hole provided in the object.

An “upper side” means a vertically upward direction when a plate-like member or layer is placed horizontally. An “upper side” and a “lower side” opposite to this are sometimes referred to as a “positive Z-axis direction” and a “negative Z-axis direction”, and a horizontal direction is sometimes referred to as an “X-axis direction” and a “Y-axis direction”.

A distance in the Z-axis direction is referred to as a “height,” and a distance on an XY plane defined by the X-axis and Y-axis directions is referred to as a “width.” In referring to a layered object, the height is also referred to as a “thickness.”

A “through electrode provided in a glass substrate” means a conductive path provided for electrical continuity between the first surface and the second surface of the glass substrate when the glass substrate is used as part of a multilayer wiring substrate, and does not necessarily need to completely penetrate the glass substrate with a single conductive material. As long as the conductive path from the first surface and the conductive path from the second surface are connected, they are included in the through electrodes. The form of the through electrode may be a filled type in which a through hole is filled with a conductive material, or a conformal type in which only the side wall portion of the through hole is covered with a conductive material (the through hole includes both bottomed and completely through holes).

A “planar shape” and a “planar view” mean the shape when a surface or layer is seen from above. A “cross-sectional shape” and a “cross-sectional view” mean the shape when a plate-like member or a layer is cut in a specific direction and seen from the horizontal direction.

A “central portion” means the center portion, not a peripheral portion of the surface or the layer. A “center direction” means a direction from the peripheral portion of the surface or the layer toward the center in the planar shape of the surface or the layer.

### <Measuring Method>

To describe the shape of the through hole provided in the glass substrate according to the first embodiment (Supplement 2) of the present invention, the following first shows a method for measuring inclination angles of a through hole 12 and a method for measuring a side surface roughness.

Here shows points to note in measuring inclination angles depending on the positions of the side wall of the glass substrate through hole and describing the values thereof.

When a specific position in the through hole is specified as a position in a depth direction from one side of the glass substrate, an angle of the side surface at that position depends greatly on the scale at which the shape of the side surface at that position is observed.

In other words, results may be significantly different between the following two cases of: observing the inclination angle of the side wall at a certain position on a scale of overlooking the entire through hole of the glass substrate; and enlarging the sidewall near the measurement point, making the fine unevenness clear on the side wall at that position, precisely determining a position where that point, at which the angle is specified, corresponds to on the unevenness, and determining the inclination angle of the tangent at that position to be the desired angle.

The inclination angle of the glass substrate through hole in the present disclosure corresponds to the former case, and means an inclination angle that reflects the tendency in overlooking the entire through hole without being excessively affected by the unevenness of the side surface.

An example of a measurement method is setting the tangent at the measurement point so as to reflect the tendency of the inclination at the measurement point and in its vicinity as much as possible, in a cross-sectional photograph at a scale and resolution in which the entire through hole can be overlooked and fine unevenness on the side surface cannot be seen with the naked eye.

### (Method for Measuring Inclination Angle of Through Hole)

First, FIG. 80 illustrates the shape of the through hole 12 obtained in the first embodiment (Supplement 2) of the present invention. FIG. 80 is a diagram showing a cross section of the truncated cone-shaped through hole 12 and a method for measuring inclination angles. The cross section of the through hole 12 shown in FIG. 80 is obtained by: dividing (cutting) the through hole 12 from a first surface 101 side in the thickness direction of the glass substrate with a scriber to expose a cross section (cut surface); and analyzing the SEM image, observed with a SEM (Scanning Electron Microscope), using image analysis software. In FIG. 80, the area shown with a pattern design indicates the glass substrate 10. The through hole 12 shown in FIG. 80 has the minimum value at which the diameter of the through hole is minimum, between the first surface 101 and the second surface 102. A truncated cone shape is formed on the first surface 101 side, and a truncated cone shape is also formed on a second surface 102 side, with the point having the minimum value interposed therebetween. The scales of 5%, 10%, . . . 95% shown in FIG. 80 each indicate a percentage with respect to the length from the first surface 101 of the glass substrate 10 to the second surface 102 thereof.

A center line TC is drawn at a central portion of the through hole 12 on the first surface 101 side of the glass substrate 10 so as to be perpendicular to the first surface 101. Next, as shown by an arrow, the center line TC is translated toward either side of the through hole 12, the translated center line TC is brought into contact with the point where the diameter of the through hole 12 is at its minimum value, and the point of contact is set as a reference point RP. Then, tangent lines ss are drawn from the reference point RP to the cross-sectional positions at heights of each of the scale positions of 5% to 100%, and the inclination angles of each tangent ss are measured and defined as the inclination angles at each of the cross-sectional positions of 5% to 95%. The inclination angle is positive in a direction in which the diameter of the through hole 12 expands upward.

As described above, in the first embodiment (Supplement 2), the method for measuring the inclination angles includes the following protocols of (1) to (3): (1) creating a center line of the through hole 12; (2) moving the center line horizontally to the position where the opening is at its minimum value to create a reference point; and (3) drawing tangents from the reference point to the specific positions of the through hole, and measuring their angles. In particular, using the protocol of (2) creating a reference point enables a highly reliable measurement on a scale that overlooks the entire through hole and that is not affected by fine unevenness on the side wall.

In addition, in a specific inclination angle measurement, a scriber and a precision breaker are used to divide (cut) the through hole 12 at the central portion from the first surface 101 side to expose the cross section of the through hole 12. As a method for dividing, for example, three-point bending can be applied. Then, the exposed cross section is observed by SEM and the SEM image of the cross section is subjected to image analysis, and thereby the angle of the through hole 12 is measured.

### (Method for Measuring Side Surface Roughness)

Next, a method for measuring a side surface roughness of the through hole 12 will be described. To measure the side surface roughness of the through hole 12, the cross section of the through hole 12 is observed by SEM, as in the measurement of the side surface angle, and the observed SEM image is analyzed using image analysis software. To measure the side surface roughness of the through hole, the measurement range is normally the range from the first surface 101 to the second surface 102 of the through hole. However, if there are projections and recesses in the through hole, two or more ranges excluding the parts of the projections and recesses are set as measurement ranges, and the results of these measurement ranges are averaged to determine the side surface roughness. In calculating the side surface roughness, the same measurements are made on five through holes (sample number n=5) created under the same conditions, and the average value is defined as the side surface roughness of the through hole created under the conditions.

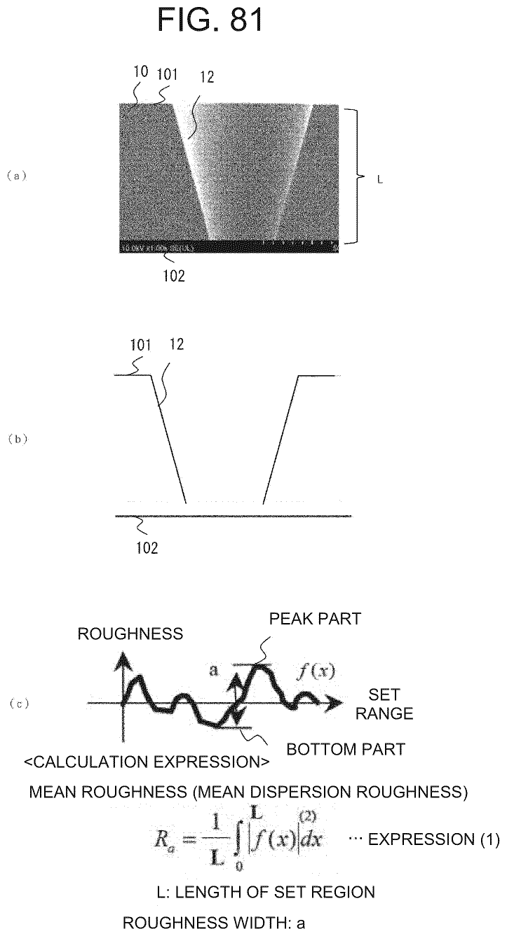

FIG. 81 is a diagram showing a method for measuring the side surface roughness of a through hole. The through hole 12 shown in FIG. 81 has a general shape for the purpose of explanation. FIG. 81(a) shows a SEM image of the cross section of the through hole 12. FIG. 81(b) shows a diagram in which the contour of the side surface of the through hole 12 is extracted from the SEM image obtained by observation of the cross section of the through hole 12. The mean dispersion roughness and the unevenness width are measured from the extracted contour data. FIG. 81(c) is a diagram schematically showing the calculation expression for mean dispersion roughness and the unevenness width. For the contour data extracted in FIG. 81(b), a roughness curve f(x) showing the roughness of the contour is measured in a set region L set based on the first surface 101. As shown in Expression (1), the mean dispersion roughness (hereinafter simply referred to as “dispersion roughness”) Ra is obtained by integrating the squared absolute value of a roughness curve f(x) over the set region L and then dividing it by a length of the set region L. The roughness width (hereinafter also referred to as the “unevenness width”) a is the difference between the peak part showing the maximum roughness value and the bottom part showing the minimum roughness value of the roughness curve f(x).

When a plurality of roughness curves f(x) are set for one through hole, the average roughness of the through hole is calculated by averaging the roughness values calculated from them.

### (Method for Measuring Transmission Characteristics)

To measure the transmission characteristics, an S parameter (S21) is used that shows the frequency dependency of the degree of propagation wave with respect to the input wave. S21 is expressed as a logarithm of the power ratio (transmitted wave power/input wave power), and a smaller absolute value indicates a smaller transmission loss.

A network analyzer was used to measure the S parameter (S21). For a measurement sample, a sample was manufactured in which the periphery of the through electrode 11 formed on the glass substrate was surrounded by a conductor and the conductor was grounded. With this sample, S21s were measured between the first surface 101 side and the second surface 102 side of the through electrode 11.

### Examples and Comparative Examples According to First Embodiment (Supplement 2)

The shape of the through hole 12 in the first embodiment (Supplement 2) will be described. In the embodiment, as shown in FIG. 104 described later, the glass substrate 10 in which laser modified portions 65 are formed is etched from the second surface 102 side of the glass substrate 10. Therefore, the formed through hole 12 has a truncated cone shape whose diameter narrows from the second surface 102 toward the first surface 101. The inclination angles of the side surface of the through hole 12 vary depending on the laser processing conditions and etching conditions for the glass substrate 10.

In each Example of the present invention, the glass substrate is subjected to laser processing under the irradiation conditions of pulse width and number of shots shown in Table 15, and the through hole 12 is then formed by etching. In Example 1 of the first embodiment (Supplement 2), the pulse width is 5 ps and the number of shots is 1, in Example 2 the pulse width is 15 ps and the number of shots is 1, and in Example 3 the pulse width is 25 ps and the number of shots is 1.

In addition, the Comparative Examples are through holes created by changing the producing method and laser processing method shown in the first embodiment (Supplement 2). In other words, in Comparative Example 1 the pulse width is 30 ps and the number of shots is 1, in Comparative Example 2 the pulse width is 30 ns and the number of shots is 50, and in Comparative Example 3 the pulse width is 50 us and the number of shots is 5.

All of the Examples and Comparative Examples each had an average opening diameter of 80 μm on the second surface 102 side of the glass substrate 10, and had a 3σ of 4.5 μm or less in this case, the 3σ being the average of the measured values plus three times the standard deviation. In addition, the formed laser modified portions 65 each had an opening diameter on the second surface 102, the opening diameter having a difference of 10 μm or less between its maximum opening diameter φ_{Max} and its minimum opening diameter φ_{Min}.

TABLE 15

| | Example | Example | Example | Comparative | Comparative | Comparative |
|---|---|---|---|---|---|---|
| | 1 | 2 | 3 | Example 1 | Example 2 | Example 3 |
| Pulse | 5 ps | 15 ps | 25 ps | 30 ps | 30 ns | 50 μs |
| width | | | | | | |
| Number | 1 | 1 | 1 | 1 | 50 | 5 |
| of shots | | | | | | |

### (Inclination Angle of Through Hole)

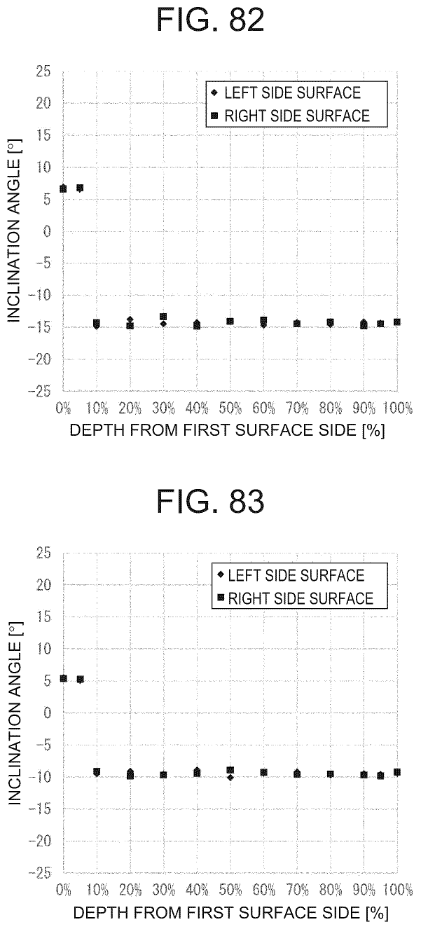

The following describes the shapes and characteristic shapes of the through holes of each Example and each Comparative Example in the first embodiment (Supplement 2) with reference to FIGS. 82 to 102.

FIG. 82 is a diagram showing measurement results of inclination angles of a through hole in Example 1 in the first embodiment (Supplement 2).

FIG. 83 is a diagram showing measurement results of inclination angles of a through hole in Example 2 in the first embodiment (Supplement 2).

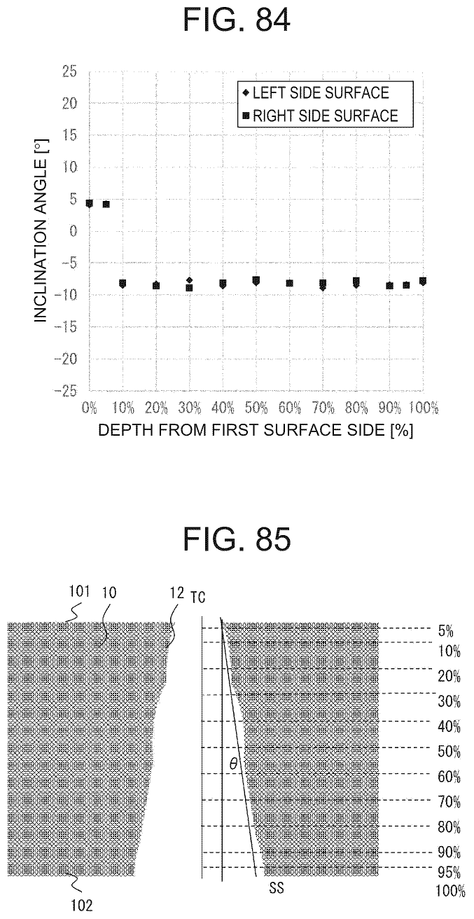

FIG. 84 is a diagram showing measurement results of inclination angles of a through hole in Example 3 in the first embodiment (Supplement 2).

FIG. 85 is a diagram showing a cross-sectional shape of a through hole of Comparative Example 1 in the first embodiment (Supplement 2).

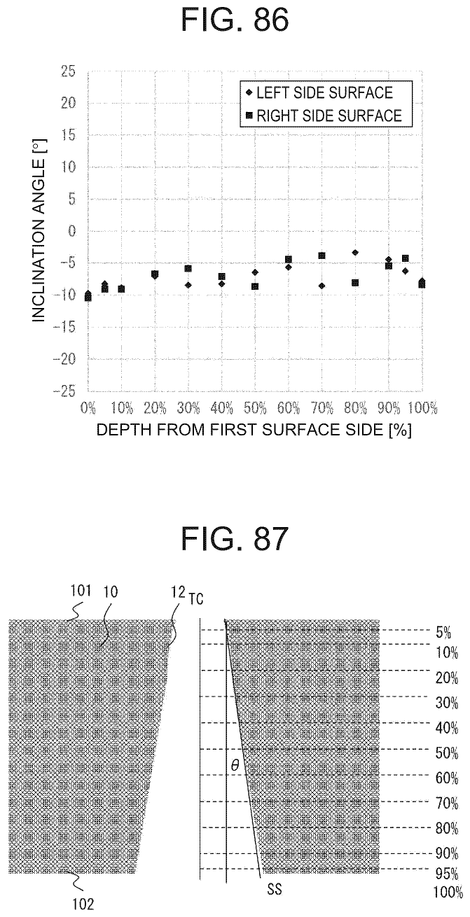

FIG. 86 is a diagram showing measurement results of inclination angles of the through hole of Comparative Example 1 in the first embodiment (Supplement 2).

FIG. 87 is a diagram showing a cross-sectional shape of a through hole of Comparative Example 2 in the first embodiment (Supplement 2).

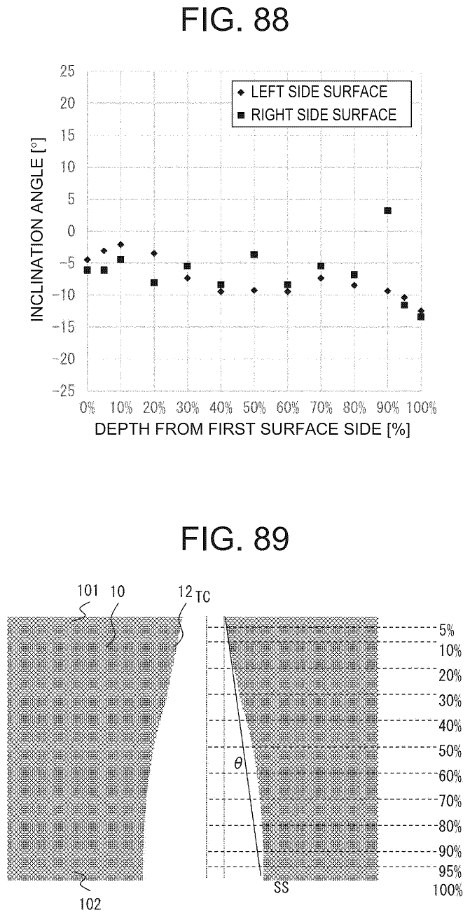

FIG. 88 is a diagram showing measurement results of inclination angles of the through hole of Comparative Example 2 in the first embodiment (Supplement 2).

FIG. 89 is a diagram showing a cross-sectional shape of a through hole of Comparative Example 3 in the first embodiment (Supplement 2).

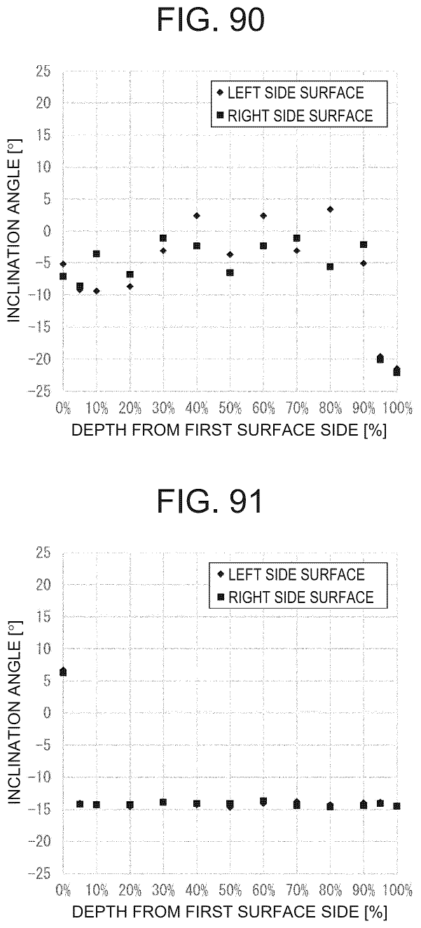

FIG. 90 is a diagram showing measurement results of inclination angles of the through hole of Comparative Example 3 in the first embodiment (Supplement 2).

### (Inclination Angle)

Table 16 summarizes, in a tabular form, measurement results of the inclination angles of the side surfaces of the through holes 12 in each Example and each Comparative Example in the embodiment. Each Example of the embodiment demonstrates that the side surface angles of the through hole 12 have the following values that are different form each other: values at a distance in a range from 0% or more to less than 10% from the first surface; and values at a distance in a range from 10% to 95% inclusive from the first surface. In other words, what is demonstrated is that: the side surface angles of the through hole 12 are almost constant (the side surface angles are in a range of 4° to 7° inclusive) at a distance in the range from 0% or more to less than 10% from the first surface; and the side surface angles thereof are almost constant (the side surface angles are in a range of −7° to −15° inclusive) at a distance in the range from 10% to 95% inclusive from the first surface. In addition, the inclination angles of the side surfaces of the through holes 12 are equal at a distance in a range from 95% to 100% inclusive from the first surface, and at a distance in a range from 10% to 95% inclusive from the first surface. The difference between the inclination angles in the two ranges is 1.0° or less.

Each Comparative Example demonstrates that the inclination angles of the side surface of the through hole 12 vary at the distances of 5% to 95% inclusive. It can be seen that the shapes of the inclination angles of the side surfaces of the through holes are significantly different between Examples of the present invention and Comparative Examples.

TABLE 16

| | | | | | | | Comparative | | Comparative | | Comparative | |
|---|---|---|---|---|---|---|---|---|---|---|---|---|
| | Example 1 | | Example 2 | | Example 3 | | Example 1 | | Example 2 | | Example 3 | |
| | Left | Right | Left | Right | Left | Right | Left | Right | Left | Right | Left | Right |
| | side | side | side | side | side | side | side | side | side | side | side | side |
| | surface | surface | surface | surface | surface | surface | surface | surface | surface | surface | surface | surface |
| 0% | 6.9 | 6.6 | 5.5 | 5.4 | 4.1 | 4.4 | −9.8 | −10.5 | −4.5 | −6.1 | −5.2 | −7.1 |
| 5% | 6.6 | 6.8 | 5.1 | 5.3 | 4.3 | 4.2 | −8.3 | −9.1 | −3.1 | −6.1 | −9.2 | −8.6 |
| 10% | −14.9 | −14.3 | −9.5 | −9.1 | −8.5 | −8.1 | −8.9 | −9.1 | −2.1 | −4.5 | −9.4 | −3.6 |
| 20% | −13.8 | −14.8 | −9.1 | −9.8 | −8.3 | −8.6 | −7.1 | −6.7 | −3.5 | −8.1 | −8.7 | −6.8 |
| 30% | −14.5 | −13.4 | −9.6 | −9.7 | −7.7 | −8.9 | −8.5 | −5.9 | −7.4 | −5.5 | −3.1 | −1.1 |
| 40% | −14.3 | −14.9 | −8.9 | −9.4 | −8.6 | −8.1 | −8.3 | −7.1 | −9.5 | −8.4 | 2.4 | −2.3 |
| 50% | −14.1 | −14.1 | −10.1 | −8.9 | −8.1 | −7.6 | −6.5 | −8.7 | −9.3 | −3.7 | −3.7 | −6.5 |
| 60% | −14.7 | −13.9 | −9.4 | −9.3 | −8.1 | −8.2 | −5.7 | −4.5 | −9.5 | −8.4 | 2.4 | −2.3 |
| 70% | −14.3 | −14.5 | −9.2 | −9.6 | −8.9 | −8.1 | −8.6 | −3.9 | −7.4 | −5.5 | −3.1 | −1.1 |
| 80% | −14.6 | −14.2 | −9.7 | −9.5 | −8.5 | −7.8 | −3.4 | −8.1 | −8.5 | −6.8 | 3.4 | −5.6 |
| 90% | −14.2 | −14.8 | −9.5 | −9.7 | −8.4 | −8.6 | −4.5 | −5.5 | −9.4 | 3.2 | −5.1 | −2.1 |
| 95% | −14.4 | −14.5 | −9.6 | −9.8 | −8.4 | −8.5 | −6.3 | −4.3 | −10.4 | −11.6 | −19.6 | −20.1 |
| 100% | −14.2 | −14.2 | −9.4 | −9.2 | −8.1 | −7.8 | −7.8 | −8.4 | −12.5 | −13.4 | −21.5 | −22.1 |

### (Mean Dispersion Roughness and Unevenness Width)

Next, the mean dispersion roughnesses and unevenness widths of the side surfaces of the through holes 12 will be described with reference to Table 17 for each Example and each Comparative Example in the first embodiment (Supplement 2). As shown in Table 17, each Example has a dispersion roughness of 1,000 nm or less and an unevenness width of 1,500 nm or less, in the side surface shape of the cut surface of the through hole 12 in the thickness direction of the glass substrate. Each Comparative Example has a dispersion roughness of 1,500 nm or more and an unevenness width of 1,500 nm or more. These demonstrate that there is a difference in the roughnesses of the through hole side surfaces.

TABLE 17

| | Example | Example | Example | Comparative | Comparative | Comparative |
|---|---|---|---|---|---|---|
| | 1 | 2 | 3 | Example 1 | Example 2 | Example 3 |
| Dispersion | 30.5 nm | 501.3 nm | 985.1 nm | 1623.5 nm | 1829.4 nm | 1789.5 nm |
| roughness | | | | | | |
| Unevenness | 316.2 nm | 982.1 nm | 1323.5 nm | 1756.4 nm | 199.61 nm | 1985.4 nm |
| width | | | | | | |

### (Inclination Angle of Application Examples)

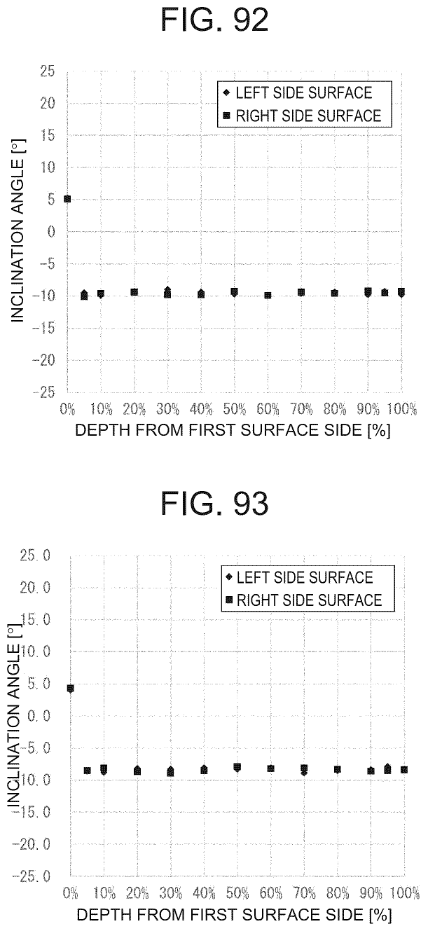

FIGS. 91 to 93 show the results of Application Examples of the first embodiment (Supplement 2) according to the present invention in each of which the through hole 12 has the side surface inclination angle with the inflection point formed at a distance in a range from 1% to 5% inclusive from the first surface. FIG. 91 is a diagram showing measurement results of inclination angles of the through hole in Application Example 1. FIG. 92 is a diagram showing measurement results of inclination angles of the through hole in Application Example 2. FIG. 93 is a diagram showing measurement results of inclination angles of the through hole in Application Example 3. Table 18 shows measurement results of the inclination angles of the side surfaces of the through hole 12 in each Application Example. As will be described later, the etching processing is performed through immersion processing using a jet. Here, each Application Example is formed in such a way that a jet direction is changed more slowly than each Comparative Example. In the number of pulses and the number of shots, the conditions in each Application Example were the same as those in each Example.

Each Application Example demonstrates that the side surface angles of the through hole 12 are almost constant at a distance in a range from 0% to 5% from the first surface, and that they are almost constant at a distance in a range from 5% to 95% from the first surface. In addition, the inclination angles of the side surfaces of the through holes 12 are equal at a distance in a range from 95% to 100% from the first surface, and at a distance in a range from 10% to 95% from the first surface. The difference between the inclination angles in the two ranges is 1.0° or less. Since there are used the same laser processing conditions and etching solution composition as in Examples 1 to 3, each roughness of the through hole side surface is the same as that in Table 17, that is, each dispersion roughness is 1000 nm or less and each unevenness width is 1500 nm or less.

TABLE 18

| | Application | | Application | | Application | |
|---|---|---|---|---|---|---|
| | Example 1 | | Example 2 | | Example 3 | |
| | Left | Right | Left | Right | Left | Right |
| | side | side | side | side | side | side |
| | surface | surface | surface | surface | surface | surface |
| 0% | 6.7 | 6.3 | 5.2 | 5.1 | 4.0 | 4.3 |
| 5% | −14.1 | −14.2 | −9.5 | −10.1 | −8.6 | −8.5 |
| 10% | −14.2 | −14.3 | −9.9 | −9.6 | −8.8 | −8.1 |
| 20% | −14.6 | −14.3 | −9.3 | −9.4 | −8.2 | −8.7 |
| 30% | −13.9 | −13.9 | −9 | −9.8 | −8.3 | −8.9 |
| 40% | −14.3 | −14.1 | −9.4 | −9.8 | −8.1 | −8.5 |
| 50% | −14.7 | −14.1 | −9.7 | −9.3 | −8.3 | −7.9 |
| 60% | −14.1 | −13.7 | −9.9 | −9.9 | −8.1 | −8.2 |
| 70% | −13.8 | −14.4 | −9.6 | −9.4 | −8.9 | −8.1 |
| 80% | −14.3 | −14.6 | −9.4 | −9.6 | −8.5 | −8.3 |
| 90% | −14.0 | −14.4 | −9.8 | −9.2 | −8.4 | −8.6 |
| 95% | −13.9 | −14.1 | −9.3 | −9.5 | −7.9 | −8.5 |

### (Opening Diameter)

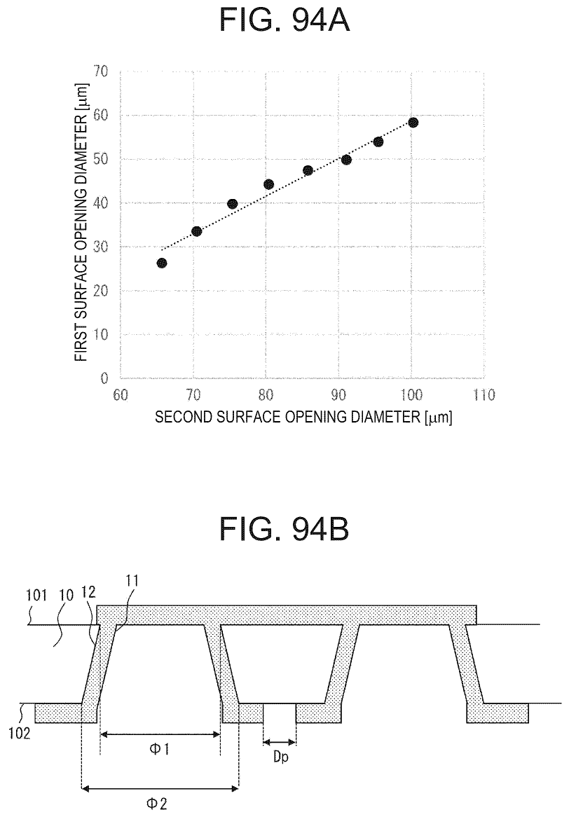

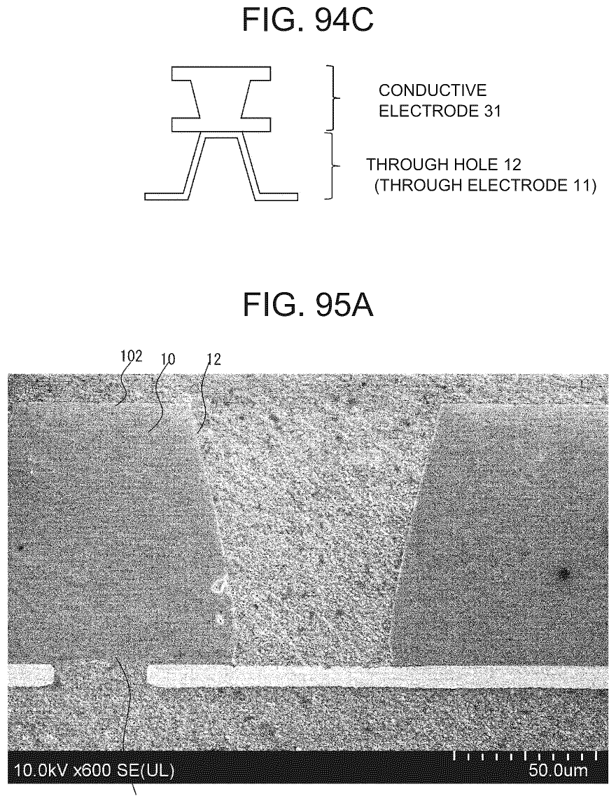

The following describes the relationship between the opening diameters of the first and second surfaces of the through holes according to the embodiment of the present invention, using Table 19 and FIG. 94A. Table 19 shows the diameters of each opening on the first surface 101 of the through hole 12 and the diameters of each opening on the second surface 102 thereof when the thickness of the glass substrate 10 is changed from 100 μm to 200 μm under the conditions of Example 1. FIG. 94A is a diagram showing Table 19 in a form of a graph. According to the first embodiment (Supplement 2), regardless of the opening diameter of the second surface 102, the relationship between the opening diameters of each second surface 102 and the opening diameters of each first surface 101 is “first surface side opening diameter Φ1/second surface side opening diameter Φ2≥0.4”.

TABLE 19

| Second surface | First surface opening | |
|---|---|---|
| opening diameter: Φ2 | diameter: Φ1 | Φ1/Φ2 |
| 100.3 | 58.3 | 0.58 |
| 95.5 | 53.9 | 0.56 |
| 91.1 | 49.8 | 0.55 |
| 85.8 | 47.4 | 0.55 |
| 80.4 | 44.2 | 0.55 |
| 75.4 | 39.8 | 0.53 |
| 70.5 | 33.5 | 0.48 |
| 65.7 | 26.3 | 0.40 |

Unit: μm

Table 20 shows the first surface opening diameters and the second surface opening diameters of each Example and each Comparative Example in the first embodiment (Supplement 2). Table 20 shows typical values of opening diameters Φ1 on the first surface 101 side of the through holes 12 and opening diameters $2 on the second surface 102 side thereof measured in each Example and each Comparative Example in the first embodiment (Supplement 2).

TABLE 20

| | Example | Example | Example | Comparative | Comparative | Comparative |
|---|---|---|---|---|---|---|
| | 1 | 2 | 3 | Example 1 | Example 2 | Example 3 |
| Second surface opening | 71.6 | 80.5 | 72.6 | 75.3 | 78.5 | 69.8 |
| diameter Φ2 | | | | | | |
| First surface opening | 33.2 | 60.7 | 46.1 | 54.6 | 45.6 | 57.1 |
| diameter Φ1 | | | | | | |

Unit: μm

The relationship between the opening diameter and the transmission characteristics will now be described with reference to FIG. 94B. FIG. 94B is a diagram schematically showing a case in which the through electrode 12 is formed. As shown by the relationship Φ1/Φ2≥0.4, the through hole 12 can have an opening diameter Φ1 smaller than Φ2. For example, in use for a communication device described later, a coil is formed using the through electrode 11, and the relationship between Φ1 and Φ2 allows the coil to secure the design freedom. In addition, a distance Dp between pads can be secured, so that a Q factor can be reduced when a circuit including a coil is formed, making it possible to reduce transmission loss. The above-described fact makes it possible to stabilize a signal of the through electrode (reduce signal loss).

### (Features of Through Holes and Through Electrodes of Present Disclosure)

FIG. 94C is a diagram for describing the features of a through hole and a through electrode formed in the present disclosure. FIG. 94C is a diagram showing, for example, an enlarged view of a region Ra in FIG. 108. As shown in FIG. 94C, a conductive electrode 31 can be formed directly on the through hole 12 (or the through electrode 11). This is because the through hole 12 has a so-called bottomed shape. The bottomed shape allows the conductive electrode 31 to be formed directly on the through hole 12. This shortens a transmission distance of the electrode as a whole, and allows the transmission characteristics to be improved and the through hole 12 to be finer.

Also, as described in the embodiment, the side surface of the through hole 12 in the present disclosure has no inflection point at which the side surface shape changes, and the surface is smooth. Thus, a uniform metal film or the like can be formed in plating processing on the through hole 12, so that the generation of parasitic capacitance can be prevented on the side surface of the through hole 12. The shape of the through hole 12 can be a shape with an inflection point or a so-called straight shape in which the diameters vary little from the first surface to the second surface of the glass substrate. However, from the viewpoint of transmission characteristics, the shape shown in the present disclosure, which can prevent the generation of parasitic capacitance, is desirable.

### (Cross-Sectional Shape)

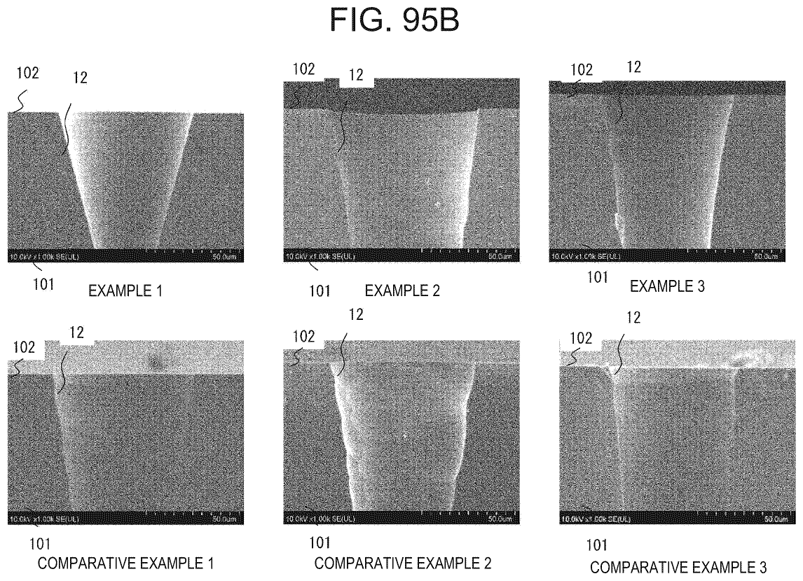

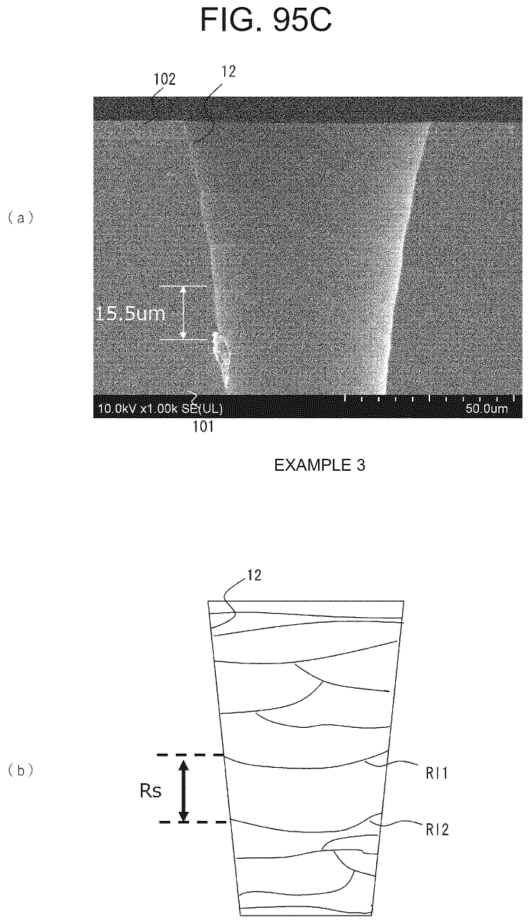

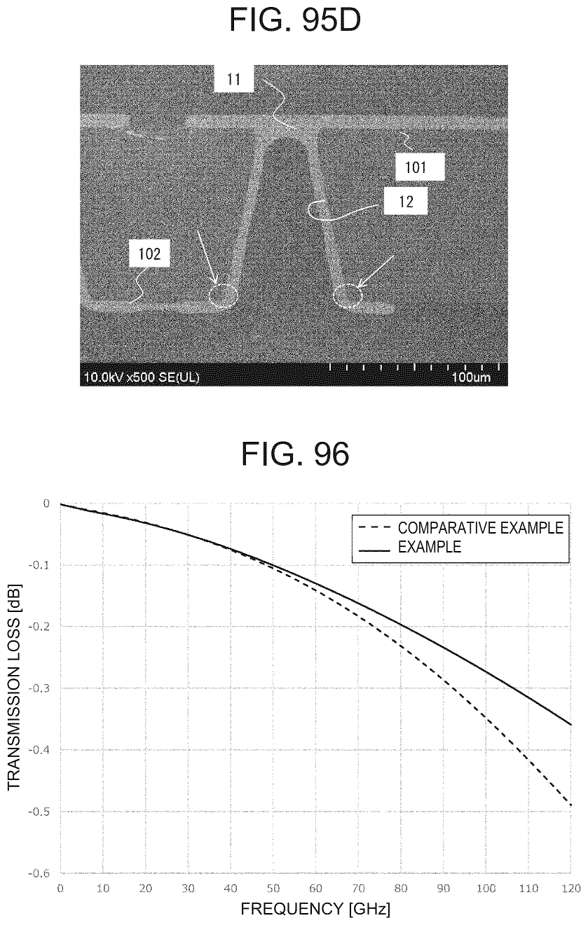

Next, the side surface shape of the through hole 12 will be described. FIGS. 95A to 95D are diagrams for describing the side surfaces of the through holes for each Example and Comparative Example. FIG. 95A is a diagram showing a SEM image of a typical cross-sectional shape of the through hole in Examples and Comparative Examples in the first embodiment (Supplement 2).

The SEM image is obtained by photographing a cut surface of the through hole in the thickness direction of the glass substrate. The SEM images shown in FIGS. 95A to 95D are at a magnification of 1000 times (one division of the scale is 5 μm).

In FIG. 95A, the through hole 12 is filled with a resin material to make it easier to observe the cross-sectional shape of the glass substrate according to the first embodiment (Supplement 2). There can be seen how the inclination angle of the side surface changes from the first surface 101 toward the second surface 102.

FIG. 95B is a diagram showing SEM images of cross-sectional shapes of the through holes in each Example and each Comparative Examples in the first embodiment (Supplement 2). In FIG. 95B, the inclination angles and the cross-sectional shapes are different from those described above, but the conditions of the pulse width and the number of shots are as described in each Example and each Comparative Example. The appearance of the SEM images and the smoothness of the cross sections of the through holes have common properties.

In the SEM image, the areas that have high contrast and appear white are each a region where the angle of the inclined surface of the sample surface changes to form a ridgeline on the inclined surface. For this reason, the areas that appear as white lines each indicate either a peak or a bottom of the roughness on the sample surface, and the state of presence and degree of placement of the ridgelines formed on the side surface of these through holes makes it possible to understand the roughness of the side surface of the through hole, which affects the transmission characteristics of the through electrode.

In each Example of the first embodiment (Supplement 2) shown in FIG. 95B, a plurality of white ridgelines appear and can be seen that extend in a direction parallel or substantially parallel to the first surface 101 of the glass substrate 10, forming a band-like striped pattern.

Now, with reference to FIG. 95C, the ridgelines of the cross section of the through hole will be described. FIG. 95C is a diagram describing the ridgelines of the through hole in each Example of the first embodiment (Supplement 2). FIG. 95C (a) is an enlarged view of Example 3 in FIG. 95B. FIG. 95C (b) is a diagram indicating the ridgelines of the side surface and cross section by solid lines in the observed through hole in the SEM image.

In the example shown in FIG. 95C (b), the widest space between ridgelines among the substantially parallel ridgelines is between a ridgeline Rl1 and a ridgeline Rl2. In the example shown in FIG. 95C (b), the space between the ridgelines on the side surface is less than or equal to Rs in a direction perpendicular to the first surface 101. As shown in FIG. 95C (a), in Example 3, the space between the ridgelines is 15.5 μm or less.

When the state of the ridgelines is checked in the same manner, in Example 1, the space between the ridgelines in the direction perpendicular to the first surface 101 is in a range of 2 μm to 3 μm inclusive. In Example 2, the space between the ridgelines in the direction perpendicular to the first surface 101 of the glass substrate 10 is in a range of 5 μm to 6 μm inclusive.

As is clear from FIG. 95B, as the first embodiment (Supplement 2) changes from Example 3 toward Example 1, that is, as the dispersion roughness, which is the smoothness of the side surface of the through hole, decreases, the side surface of the through hole 12 is denser with the white lines, which can be recognized as ridgelines extending in a direction parallel to the first surface 101 of the glass substrate 10, and the space between ridgelines decreases. Conversely, as the dispersion roughness increases (i.e., as the sample changes from Example 1 to Example 3, and further from Comparative Example 1 to Comparative Example 3), the space between the ridgelines increases and the number of ridgelines extending in a direction that is not parallel to the first surface 101 also increases. Furthermore, it can be seen that the occurrence frequency of the following ridgelines increases: ridgelines extending in a direction perpendicular to the first surface 101; and ridgelines extending in a direction between the direction parallel to the first surface 101 and the direction perpendicular to the first surface 101 (hereinafter also referred to as a “diagonal direction”). This indicates that the ratio of ridgelines extending in a vertical direction and ridgelines extending in a diagonal direction decreases as the dispersion roughness decreases. For example, in Example 2, when the mean dispersion roughness is 500 nm and the unevenness width is 980 nm, white lines can be seen that extend in a direction between a direction parallel to the first surface 101 and a direction perpendicular to the first surface 101 (i.e., the diagonal direction).

On the other hand, when the side surface of the through hole is rougher (when the mean dispersion roughness is greater than 1,000 nm and the unevenness width is greater than 1,500 nm) as in Comparative Examples 1 to 3 in the embodiment, the ratio of white lines increases that extend in a direction perpendicular to the first surface 101 of the glass substrate 10 or in the diagonal direction between a direction perpendicular to the first surface 101 and a direction parallel to the first surface 101. In other words, a plurality of ridgelines can be seen in the diagonal direction. It can be seen that the smoothness (roughness) of the side surface of the through hole 12 appears in the SEM image, and affects the transmission characteristics of the through electrode.

FIG. 95D is a diagram showing a SEM image of a cross section when the through electrode is formed in the through hole in the first embodiment (Supplement 2). In FIG. 95D, the inclination angle and cross-sectional shape are different from those described above, but the conditions of the pulse width and the number of shots are as described in each Example and each Comparative Example. The appearance of the SEM images and the smoothness of the cross sections of the through holes have common properties.

As shown here, the areas indicated by arrows and surrounded by dashed lines each have a shape with a raised end. In other words, there is no area that gradually changes between the side surface of the through hole 12 and the second surface 102 of the glass substrate 10, and the angle changes completely in a cross-sectional view. In other words, the side surface of the through hole 12 and the second surface 102 of the glass substrate 10 have a shape with raised ends, and have a shape in which the regions of the side surface and the second surface can be clearly distinguished in a 1000 times SEM image.

### (Transmission Characteristics)

The following describes transmission characteristics of the through electrodes of each Example and each Comparative Example in the first embodiment of the present invention (Supplement 2), using FIG. 96. FIG. 96 is a diagram showing transmission characteristics of the through electrode of Example 1 in the first embodiment (Supplement 2) and transmission characteristics of the through electrode of Comparative Example 1. FIG. 96 shows the results of measuring a transmission loss S21 as the transmission characteristics in the through electrode. The transmission characteristics of Examples 1 to 3 showed the same tendency, and Example 1 is shown as a representative. The transmission characteristics of Comparative Examples 1 to 3 also showed almost the same tendency, and Comparative Example 1 is shown as a representative. The formation conditions for the formation of the seed layer, plating processing, and the like for forming electrodes were the same in both the examples and Comparative Examples. As shown in FIG. 96, the transmission loss of the Example is smaller than that of the Comparative Example in all frequency regions. This shows that as the side surface of the through hole has smaller values of dispersion roughness and unevenness width, the loss is smaller and the transmission characteristics are more excellent, in the through electrode formed in the through hole.

(Transmission Characteristics when Thickness of Glass Substrate is Changed)

The transmission characteristics S21 were also measured when the thickness of the glass substrate 10 was changed in each Example and each Comparative Example. The results are shown in Table 21. As shown in Table 21, the thicknesses of the glass substrates 10 were set to 100 μm, 150 μm, and 200 μm, and through holes and through electrodes were created under conditions based on each Example and each Comparative Example, and the transmission characteristics were measured. Table 21 shows all the Examples in the first embodiment (Supplement 2) have more excellent transmission characteristics S21 than any of Comparative Examples therein.

The transmission characteristics shown in Table 21 are the transmission characteristics of a single through electrode, and in a multilayer wiring substrate that requires a plurality of through electrodes, improving the transmission characteristics of a single through electrode leads to a significant performance improvement. Using each Example according to the first embodiment (Supplement 2) makes it possible to obtain a multilayer wiring substrate that achieves excellent transmission characteristics of the through electrode in a high frequency band compared to existing techniques.

In terms of transmission characteristics, the through electrodes shown in Examples 1 to 3 provide more excellent results than the through electrodes shown in Comparative Examples 1 to 3. Comparison of the Examples demonstrates that Example 1 is the most preferable, followed by Example 2 and Example 3 in this order.

TABLE 21

| | | | | | | | | Comparative | | Comparative | | Comparative | |
|---|---|---|---|---|---|---|---|---|---|---|---|---|---|
| | | Example 1 | | Example 2 | | Example 3 | | Example 1 | | Example 2 | | Example 3 | |
| | | | Deter- | | Deter- | | Deter- | | Deter- | | Deter- | | Deter- |
| Fre- | Glass | Measured | mina- | Measured | mina- | Measured | mina- | Measured | mina- | Measured | mina- | Measured | mina- |
| quency | thickness | value | tion | value | tion | value | tion | value | tion | value | tion | value | tion |
| 5 GHz | 100 μm | −0.0079 | Good | −0.0082 | Good | −0.0087 | Good | −0.0090 | — | −0.0090 | — | −0.0090 | — |
| | 150 μm | −0.0083 | Good | −0.0087 | Good | −0.0094 | Good | −0.0098 | — | −0.0099 | — | −0.0099 | — |
| | 200 μm | 0.0091 | Good | 0.0101 | Good | 0.0106 | Good | 0.0111 | | 0.0112 | | 0.0112 | |
| 10 GHz | 100 μm | −0.0140 | Good | −0.0148 | Good | −0.0154 | Good | −0.0157 | — | −0.0157 | — | −0.0157 | — |
| | 150 μm | −0.0145 | Good | 0.0156 | Good | 0.0165 | Good | 0.0169 | | 0.0170 | | 0.0170 | |
| | 200 μm | −0.0161 | Good | −0.0189 | Good | −0.0189 | Good | −0.0193 | — | −0.0194 | — | −0.0194 | — |
| 20 GHz | 100 μm | −0.0293 | Good | −0.0302 | Good | −0.0309 | Good | −0.0314 | — | −0.0314 | — | −0.0314 | — |
| | 150 μm | −0.0288 | Good | −0.0298 | Good | −0.0315 | Good | −0.0321 | — | −0.0321 | — | −0.0321 | — |
| | 200 μm | 0.0312 | Good | 0.0379 | Good | 0.0352 | Good | 0.0357 | | 0.0358 | | 0.0358 | |
| 28 GHz | 100 μm | −0.0442 | Good | −0.0456 | Good | −0.0463 | Good | −0.0469 | — | −0.0469 | — | −0.0469 | — |
| | 150 μm | −0.0441 | Good | −0.0450 | Good | −0.0468 | Good | −0.0471 | — | −0.0471 | — | −0.0471 | — |
| | 200 μm | −0.0486 | Good | −0.0595 | Good | −0.0537 | Good | −0.0542 | — | −0.0544 | — | −0.0544 | — |
| 56 GHz | 100 μm | −0.0851 | Good | −0.0914 | Good | −0.1040 | Good | −0.1337 | — | −0.1457 | — | −0.1517 | — |
| | 150 μm | −0.0976 | Good | −0.1013 | Good | −0.1160 | Good | −0.1537 | — | −0.1875 | — | −0.1915 | — |
| | 200 μm | 0.1094 | Good | 0.1213 | Good | 0.1340 | Good | 0.1854 | | 0.1984 | | 0.2184 | |
| 84 GHz | 100 μm | 0.1891 | Good | 0.2014 | Good | 0.2114 | Good | 0.2527 | | 0.2727 | | 0.2827 | |
| | 150 μm | −0.2004 | Good | −0.2212 | Good | −0.2114 | Good | −0.2827 | — | −0.3127 | — | −0.3193 | — |
| | 200 μm | −0.2114 | Good | −0.2421 | Good | −0.2114 | Good | −0.3027 | — | −0.3374 | — | −0.3474 | — |

Tables 22 and 23 show the reliability evaluation results by the TCT test (Temperature Cycling Test). The reliability test conditions are as follows.
Setting conditions: Lower limit temperature was set to −40° C./30 minutes, and upper limit temperature was set to 150° C./30 minutes.
Test apparatus TSA-43EL (manufactured by ESPEC CORP.)
Measure the increase in a resistance of the wiring path including the through electrode in each number of cycles.
NG criteria: If the resistance value after the cycle exceeds 10 times the initial resistance value, it is determined as NG.

As shown in Tables 22 and 23, all the examples according to the embodiment of the present invention show higher reliability than any of Comparative Examples.

TABLE 22

| | | | | | | | Comparative | | Comparative | | Comparative | |
|---|---|---|---|---|---|---|---|---|---|---|---|---|
| | Example 1 | | Example 2 | | Example 3 | | Example 1 | | Example 2 | | Example 3 | |
| | | Deter- | | Deter- | | Deter- | | Deter- | | Deter- | | Deter- |
| | Measured | mina- | Measured | mina- | Measured | mina- | Measured | mina- | Measured | mina- | Measured | mina- |
| | value | tion | value | tion | value | tion | value | tion | value | tion | value | tion |
| 50 | Passed | Good | Passed | Good | Passed | Good | Passed | Good | Passed | Good | Passed | Good |
| cycle | | | | | | | | | | | | |
| 100 | Passed | Good | Passed | Good | Passed | Good | Passed | Good | Passed | Good | Passed | Good |
| cycle | | | | | | | | | | | | |
| 200 | Passed | Good | Passed | Good | Passed | Good | Passed | Good | Passed | Good | Passed | Good |
| cycle | | | | | | | | | | | | |
| 300 | Passed | Good | Passed | Good | Passed | Good | Passed | Good | Passed | Good | Passed | Good |
| cycle | | | | | | | | | | | | |
| 400 | Passed | Good | Passed | Good | Passed | Good | Passed | Good | Passed | Good | Passed | Good |
| cycle | | | | | | | | | | | | |
| 500 | Passed | Good | Passed | Good | Passed | Good | Passed | Good | Failed | NG | Passed | NG |
| cycle | | | | | | | | | | | | |
| 600 | Passed | Good | Passed | Good | Passed | Good | Failed | NG | Failed | NG | Passed | NG |
| cycle | | | | | | | | | | | | |
| 700 | Passed | Good | Passed | Good | Passed | Good | Failed | NG | Failed | NG | Passed | NG |
| cycle | | | | | | | | | | | | |
| 800 | Passed | Good | Passed | Good | Passed | Good | Failed | NG | Failed | NG | Passed | NG |
| cycle | | | | | | | | | | | | |
| 900 | Passed | Good | Passed | Good | Passed | Good | Failed | NG | Failed | NG | Failed | NG |
| cycle | | | | | | | | | | | | |
| 1000 | Passed | Good | Passed | Good | Passed | Good | Failed | NG | Failed | NG | Failed | NG |
| cycle | | | | | | | | | | | | |
| 1500 | Passed | Good | Passed | Good | Passed | Good | Failed | NG | Failed | NG | Failed | NG |
| cycle | | | | | | | | | | | | |

TABLE 23

| | | Application Example 1 | | Application Example 2 | | Application Example 3 | |
|---|---|---|---|---|---|---|---|
| | | Measured | | Measured | | Measured | |
| | | value | Determination | value | Determination | value | Determination |
| 50 | cycle | Passed | Good | Passed | Good | Passed | Good |
| 100 | cycle | Passed | Good | Passed | Good | Passed | Good |
| 200 | cycle | Passed | Good | Passed | Good | Passed | Good |
| 300 | cycle | Passed | Good | Passed | Good | Passed | Good |
| 400 | cycle | Passed | Good | Passed | Good | Passed | Good |
| 500 | cycle | Passed | Good | Passed | Good | Passed | Good |
| 600 | cycle | Passed | Good | Passed | Good | Passed | Good |
| 700 | cycle | Passed | Good | Passed | Good | Passed | Good |
| 800 | cycle | Passed | Good | Passed | Good | Passed | Good |
| 900 | cycle | Passed | Good | Passed | Good | Passed | Good |
| 1000 | cycle | Passed | Good | Passed | Good | Passed | Good |
| 1500 | cycle | Passed | Good | Passed | Good | Passed | Good |
| 2000 | cycle | Passed | Good | Passed | Good | Passed | Good |

### <Configuration of Multilayer Wiring Substrate According to First Embodiment (Supplement 2)>

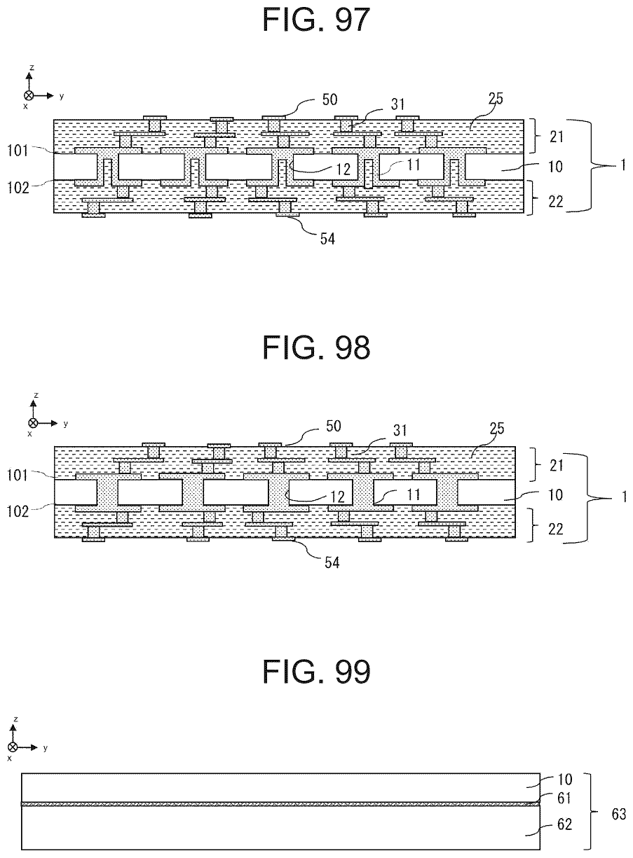

FIG. 97 is a diagram showing an example of a configuration of the multilayer wiring substrate 1 according to the first embodiment (Supplement 2). FIG. 98 is a diagram showing another example of a configuration of the multilayer wiring substrate 1 according to the first embodiment (Supplement 2). The multilayer wiring substrate 1 includes the glass substrate 10, the first wiring layer 21, and the second wiring layer 22. The first wiring layer 21 is disposed on the first surface 101 side of the glass substrate 10, and the second wiring layer 22 is disposed on the second surface 102 side of the glass substrate 10. The glass substrate 10 includes the through holes 12 penetrating from the first surface 101 side to the second surface 102 side. Each through electrode 11 is formed of a conductor formed along the side surface of the through hole 12. The through electrode 11 electrically connects part of the first wiring layer 21 and part of the second wiring layer 22. The first wiring layer 21 and the second wiring layer 22 each include an insulating resin layer 25. The first wiring layer 21 and the second wiring layer 22 may also be configured with a plurality of layers laminated, and the number of layers may be set as necessary. The through electrode 11 is an electrode for establishing an electrical connection between the first wiring layer 21 and the second wiring layer 22. A conductive electrodes 31 are each an electrode for ensuring electrical continuity in the thickness direction of the multilayer wiring substrate 1. Semiconductor power device joining pads 50 are members for connecting semiconductor circuits to be mounted on the multilayer wiring substrate 1. Substrate joining pads 54 are members for joining the multilayer wiring substrate 1 to another substrate.

As long as the through electrode can electrically connect the first surface 101 side to the second surface 102 side of the glass substrate 10, a conductor may be disposed only on the side surface of the through hole 12 as shown in FIG. 97, or a conductor may be embedded in the through hole 12 as shown in FIG. 98.

In the first embodiment (Supplement 2), the conductive electrode 31 can be placed on the Z-axis of the through electrode 11 in the first wiring layer 21.

Note that the shapes of the through holes 12 are shown with details omitted in FIGS. 97 and 98. Similarly, the detailed shapes thereof are omitted in FIGS. 99 to 108.

The thickness of the multilayer wiring substrate 1 is, for example, in a range of 100 μm to 400 μm inclusive. <Method for producing multilayer wiring substrate in first embodiment (Supplement 2)>

A method for producing the multilayer wiring substrate 1 will be described with reference to FIGS. 82 to 91. First, a step of forming the through holes 12 in the glass substrate 10 will be described.

### [Bonding Step of First Support]

FIG. 99 is a diagram showing a step of bonding the glass substrate 10 to a first support 62.

The thickness of the glass substrate 10 can be set appropriately depending on the application, taking into account the thickness after etching.

As shown in FIG. 99, the glass substrate 10 and the first support 62 are bonded together at a first bonding layer 61, and a laminated structure 63 is formed that includes the glass substrate 10, the first bonding layer 61, and the first support 62.

Note that the glass substrate 10 and the first support 62 are temporarily fixed by the first bonding layer 61.

To bond the first support to the glass substrate 10, for example, a laminator, a vacuum pressure press, a reduced pressure bonding machine, or the like can be used.

It is desirable that the first support 62 is made of the same material as the glass substrate 10, for example. When the glass substrate 10 is made of alkali-free glass with a SiO₂ ratio in the range of 55 mass % to 81 mass % inclusive, it is desirable that the first support 62 be also made of alkali-free glass. The thickness of the first support 62 can be set appropriately depending on the thickness of the glass substrate 10. However, the thickness of the first support 62 is desirably such that the first support 62 can be transported during the step of producing, and the thickness of the first support 62 is, for example, in a range of 300 μm to 1,500 μm inclusive.

The glass substrate 10 can use, for example, alkali-free glass with a SiO₂ ratio in the range of 55 mass % to 81 mass % inclusive. If the SiO₂ ratio of the glass substrate 10 is greater than 81 mass %, the processing rate of etching decreases, the side surface angle of the through hole 12 decreases, and poor adhesion will occur in forming the through electrode 11, which will be described later. If the SiO₂ ratio is less than 55 mass %, alkali metals are highly likely to be contained in the glass, which will affect the reliability of the multilayer wiring substrate after the electronic device is mounted. If the SiO₂ ratio of alkali-free glass is in the range of 55 mass % to 81 mass % inclusive, the set ratio may be set appropriately.

### [Laser Modification Step]

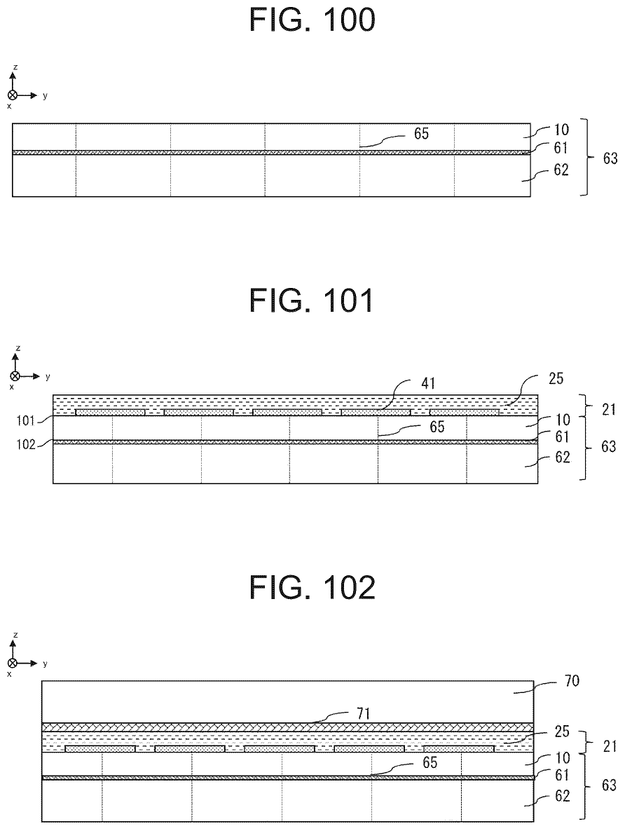

Next, FIG. 100 is a diagram showing a step of forming laser modified portions. Performing laser processing on the glass substrate 10 forms a laser modified portion 65 on the glass substrate 10. The laser modified portion 65 is processed into a shape of Φ3 μm or less on the glass substrate 10, and is formed continuously in the thickness direction of the glass substrate 10. At this time, it is desirable that no fine cracks (hereinafter also referred to as “microcracks”) of 5 μm or more occur around the laser modified portion 65. When microcracks of 5 μm or more occur around the laser modified portion 65, the dispersion roughness of the side surface of the through hole 12 after etching will be 1000 nm or more, and the unevenness width thereof will be 1500 nm or more. This makes it difficult to obtain the through hole 12 with a smooth side surface. When microcracks of 5 μm or more occur, the side surface of the through hole 12 after etching has roughness that varies at spaces in a direction perpendicular to the first surface 101 of the glass substrate 10, which will be described later.

For processing the laser modified portion 65, it is preferable to use, for example, a femtosecond laser or a picosecond laser, and to use a laser emission wavelength of any one of 1064 nm, 532 nm, and 355 nm. If the laser pulse width is 25 picoseconds or more, microcracks of 5 μm or more are likely to occur around the laser modified portion 65. For this reason, the laser pulse width is desirably 25 picoseconds or less. In addition, since microcracks are likely to occur if processing is performed by a plurality of times of pulse irradiation, the laser modified portion 65 is desirably formed by one pulse. Under the condition that does not generate microcracks of 5 μm or more around the laser modified portion 65, the laser emission wavelength and laser output may be appropriately set depending on the thickness of the glass substrate 10. In other words, in the laser modification step (first step), the glass substrate is irradiated with a laser at the portion where the through hole is to be formed, and the microcracks that occur in a peripheral portion of the laser irradiation have a maximum length of 5 μm.

### [Formation of First Wiring Layer]

Next, FIG. 101 is a diagram showing a step of forming the first wiring layer 21. As shown in FIG. 101, the first wiring layer 21 consisting of a conductive layer and an insulating resin layer is formed on the first surface 101 on the glass substrate 10 of the laminated structure 63. Here, a seed layer including a hydrofluoric acid resistant metal layer is formed on the glass substrate 10, and then through electrode connection portions 41 (or wiring between the through electrodes) are formed on the first surface 101 through a semi-additive process (SAP). The unnecessary seed layer is removed, and then the insulating resin layer 25 is formed.

In the formation of the seed layer, the hydrofluoric acid resistant metal layer on the glass substrate 10 is an alloy layer containing chromium, nickel, or both, and can be formed in a range of 10 nm to 1,000 nm inclusive by sputtering processing. After that, a conductive metal film is formed to the desired thickness on the hydrofluoric acid resistant metal. The conductive metal film can be appropriately set from, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, and Cu₃N₄.

In the semi-additive process, a photoresist is used to form a desired pattern to form a wiring pattern by plating. Generally, a dry film resist is used, but a liquid resist can also be used. The desired pattern is formed through exposure and development, a plating film is then formed through electrolytic plating, the unnecessary resist is peeled, and the seed layer is etched, thereby making it possible to form wiring.

### [Insulating Resin Layer]

Next, in the formation of the insulating resin layer 25, the insulating resin layer 25 is made of thermosetting resin, and the material thereof is a material that contains at least one of epoxy resin, polyimide resin, and polyamide resin, and that contains silica SiO₂ filler. The material of the insulating resin layer 25 can be appropriately selected as necessary. However, when a photosensitive insulating resin material is used, filling the silica SiO₂ filler is difficult for ensuring photolithography properties. For this reason, a photosensitive insulating resin material can also be used, but it is more preferable to use thermosetting resin.

### [Bonding Step of Second Support]

Next, FIG. 102 is a diagram showing a step of bonding a second support. As shown in FIG. 102, a second bonding layer 71 is formed on the first wiring layer 21 of the laminated structure 63, and the second support 70 is placed and bonded on the second bonding layer 71.

The second support 70 can use, for example, glass, and is desirably made of the same material as the glass substrate 10. When the glass substrate 10 is alkali-free glass, the second support 70 is also desirably made of alkali-free glass. The thickness of the second support 70 can be set appropriately depending on the thickness of the glass substrate 10. However, the thickness is desirably such that the second support 70 can be transported, and the thickness is in a range of 300 μm to 1,500 μm inclusive.

### [Peeling Step]

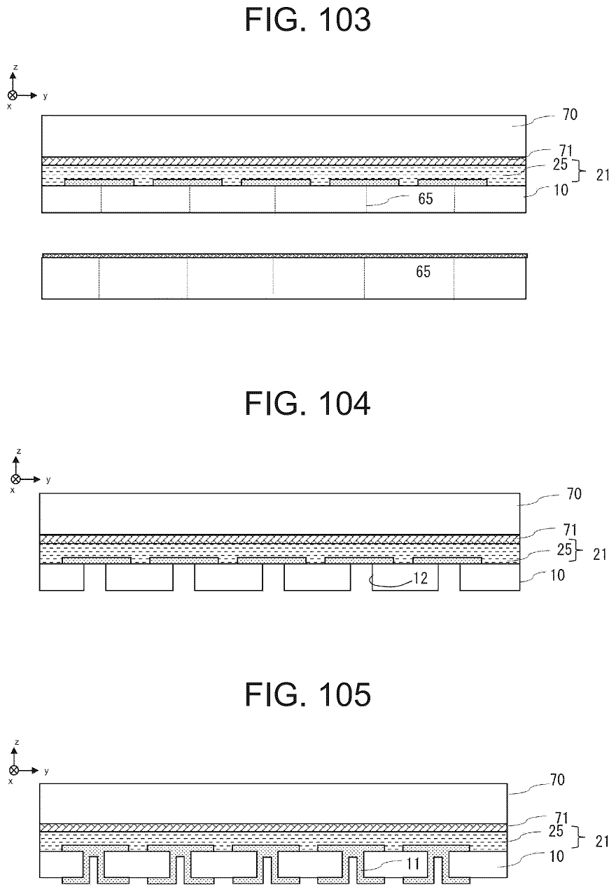

Next, FIG. 103 shows a step of peeling the first support. As shown in FIG. 103, the first support 62 is peeled off the glass substrate 10 at the first bonding layer 61.

### [Formation of Through Holes]

Next, FIG. 104 shows a step of forming the through hole 12.

### [Etching Step]

The glass substrate 10 in which the laser modified portions 65 are formed is subjected to etching processing with a predetermined etching solution to form the through holes 12. At the same time, the second surface of the glass substrate 10 is also etched, and the thickness of the glass substrate 10 decreases. The etching is performed from the second surface 102 side of the glass substrate 10.

### [Etching Solution]

The etching solution to be used contains hydrofluoric acid in a range of 0.2 mass % to 20.0 mass % inclusive, nitric acid in a range of 4.0 mass % to 25.0 mass % inclusive, and inorganic acid other than hydrofluoric acid and nitric acid in a range of 0.5 mass % to 11.0 mass % inclusive. Examples of inorganic acids other than hydrofluoric acid and nitric acid include hydrochloric acid, sulfuric acid, phosphoric acid, and sulfamic acid. At least one inorganic acid is contained depending on the type of components other than silicon contained in the glass substrate 10. Desirably, the etching solution contains hydrochloric acid and sulfuric acid. The etching rate for the glass substrate 10 is appropriately adjusted to be in a range of 0.1 μm/min to 10 μm/min inclusive. The etching rate for the glass substrate 10 is desirably in a range of 0.25 μm/min to 4 μm/min inclusive, and more desirably in a range of 0.25 μm/min to 0.5 μm/min inclusive. The etching temperature is not particularly limited and can be adjusted appropriately, and is, for example, in a range of 10° C. to 30° C. inclusive.

The etching processing is performed through immersion processing using a jet or spray processing to form the through hole 12. The immersion processing using a jet includes, for example, switching the direction of the jet in the etching solution in order to efficiently etch the bottom of the through hole 12. The timing of switching the direction of the jet is set early to apply pressure to the bottom of the through hole 12, thereby making it possible to change the inclination angle of the TGV side surface at a distance of 1 to 10% from the first surface. Similarly, in the case of etching with spray processing, a reciprocation speed of the spray having an spray nozzle for spraying the etching solution is set fast or a reciprocation speed of the substrate is set fast to apply pressure to the bottom of the through hole 12, thereby making it possible to change the inclination angle of the TGV side surface at the distance of 1 to 10% inclusive from the first surface.

In addition, in etching process with immersion processing using a jet and etching process with spray processing, since the processing conditions differ depending on the size of the apparatus used, it is desirable to check the shape of the through hole 12 and set the processing conditions. In addition, in the case of immersion processing using a jet, ultrasonic waves or the like, which is another mechanism, may be used in combination.

### [Formation of Through Electrode]

Next, a step of forming the through electrodes 11 will be described with reference to FIG. 105. FIG. 105 is a diagram showing a step of forming the through electrodes 11.

A metal layer for electrolytic plating processing is formed on the second surface 102 of the glass substrate 10 in which the through holes 12 are formed. The metal layer just needs to be made of any metal that functions as a seed layer for electrolytic plating processing, such as metals including Cu, Ti, Cr, W, Ni, or the like. The metal layer uses at least one of the above-mentioned metals. The metal layer desirably has a Cu layer formed on its outermost surface. Ti, Cr, W, and Ni are desirably used as an adhesion layer with the glass substrate 10 under the Cu layer. The thickness of the metal layer is appropriately set to a range that can cover the side surface of each through hole 12. The formation method to be employed can be, for example, a formation method through deposition using sputtering.

Subsequently, the through electrodes 11 are formed by electrolytic plating processing that uses the above-mentioned metal layer as the seed layer. To selectively grow the through holes 12, a mask is formed with an insulator such as a resist on the second surface 102 of the glass substrate 10 except for a predetermined range of the through hole 12 and around the through hole 12, and then electrolytic plating processing is performed. As a material used for electrolytic plating processing, for example, Cu can be used, and other metals including Au, Ag, Pt, Ni, Sn, or the like can also be used. Depending on the application of the multilayer wiring substrate, electrolytic plating processing may be performed so that the through holes 12 are filled with the above-mentioned metal conductors, or the like

A step of forming the insulating resin layer 25 will be described with reference to FIG. 106. FIG. 106 is a diagram showing a step of forming the insulating resin layer. After electrolytic plating processing for forming the through electrodes, the insulator such as a resist is removed, and the metal film is removed that is formed as the seed layer on the second surface 102 of the glass substrate 10. The plurality of through electrodes 11 formed in the glass substrate 10 are electrically isolated from each other, and then an insulating resin layer 25 is formed on the second surface side as shown in FIG. 106.

### [Peeling of Second Support]

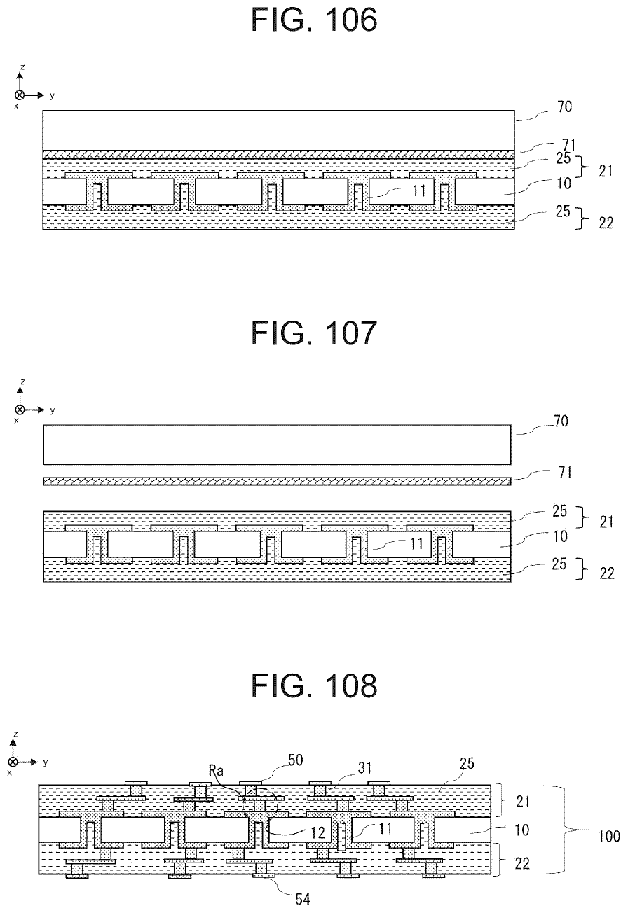

The following describes a step of peeling the second support 70 and the second bonding layer 71 with reference to FIG. 107. FIG. 107 is a diagram showing a step of peeling the second support 70 and the second bonding layer 71. As shown in FIG. 107, the second bonding layer 71 and the second support 70 formed above the first wiring layer 21 are peeled off the interface between the first wiring layer 21 and the second bonding layer 71 on the first surface 101 side. As a result, as shown in FIG. 107, a glass substrate 10 is obtained in which the first wiring layer 21 is formed on the first surface 101 side and the second wiring layer 22 is formed on the second surface 102 side.

When the second support 70 is peeled off the second wiring layer 22, a peeling method can be appropriately selected from UV light irradiation, heat treatment, physical peeling, or the like depending on the material used for the second bonding layer 71. In addition, if there is a residue of the second bonding layer 71 on the joining surface between the first wiring layer 21 and the second bonding layer 71, the following may be performed: plasma cleaning, ultrasonic cleaning, water washing, solvent cleaning using alcohol, or the like.

### [Formation of First Wiring Layer and Second Wiring Layer]

The following describes formation of the first wiring layer 21 and the second wiring layer 22 formed on the glass substrate 10 with reference to FIG. 108. FIG. 108 is a diagram showing a step of forming the first wiring layer 21 and the second wiring layer 22. For the glass substrate 10 on which the through electrodes 11 are formed, the first wiring layer 21 is formed on the first surface 101, and the second wiring layer 22 is formed on the second surface 102. In the step of forming the first wiring layer 21 and the second wiring layer 22, a mask having a pattern is first formed with a photosensitive resist or a dry film resist, and wiring is then formed by electrolytic plating processing. After that, physical adhesion processing or chemical adhesion processing is performed, and then the insulating resin layer 25 is laminated. For the conductive electrodes 31, holes are formed in the insulating resin layer 25 by laser processing or the like, and then a metal film is formed by electroless plating or deposition processing by sputtering. A mask having a pattern is formed on the above-mentioned metal film using the resist, and the holes formed by electrolytic plating are filled with a conductor. The mask and excess metal film are then removed. The above-mentioned step is repeated a plurality of times depending on the number of layers required, to form the first wiring layer 21 and the second wiring layer 22. Note that the first wiring layer 21 and the second wiring layer 22 desirably have the same number of layers in order to prevent warping of the multilayer wiring substrate 1. If the layer thicknesses of the first wiring layer 21 and the second wiring layer 22 are different, the number of layers may be different between the first wiring layer 21 and the second wiring layer 22. The number of layers of the first wiring layer 21 and the number of layers of the second wiring layer 22 may be set appropriately depending on the application of the multilayer wiring substrate.

### Second Embodiment (Supplement 2)

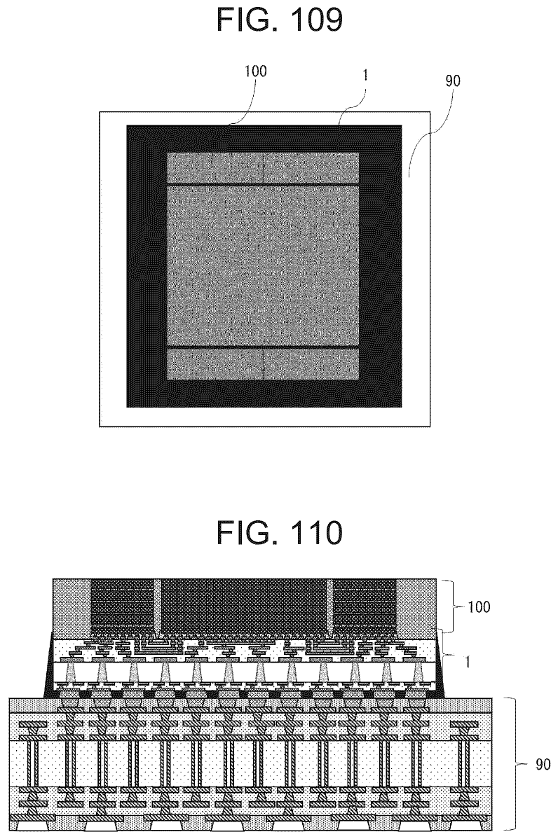

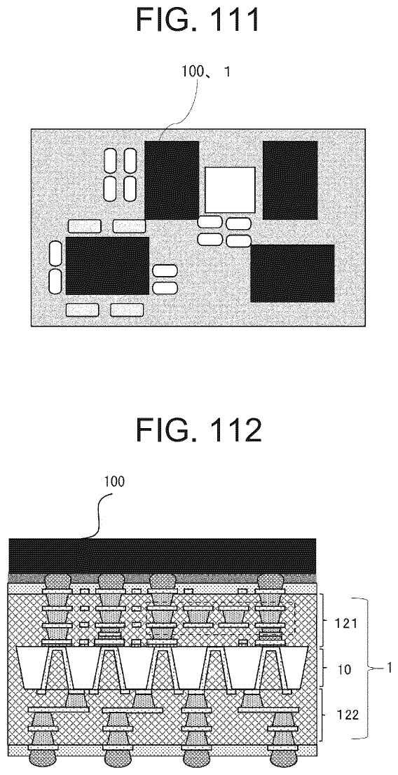

FIG. 109 is a diagram showing a case in which the multilayer wiring substrate 1 is used as an interposer substrate for a semiconductor power device 100 and a BGA (Ball Grid Array) substrate 90. FIG. 110 is a diagram showing a cross section of the case of FIG. 109. FIG. 111 is a diagram showing a case in which the multilayer wiring substrate 1 and the semiconductor power device 100 are used in an electronic device for communication. FIG. 112 is a diagram showing a cross section of the case of FIG. 111. The electronic device to be used has a layer thickness of 800 μm or less.

The above-described electronic device has limited applications to which the device is adapted due to the effect of the transmission characteristics of the through electrodes, and the use of the multilayer wiring substrate using the glass substrate of the present invention allows the electronic device to be adapted to a high frequency band region.

### <Actions and Effects>

As described above, according to the present invention, it is possible to obtain a glass substrate capable of forming a through electrode with excellent transmission characteristics and high reliability, and a multilayer wiring substrate including such a glass substrate.

### (Other Aspects for Implementation)

The present disclosure also includes the following aspects.

### (Aspect 1 (Supplement 2))

A glass substrate having a first surface and a second surface, the glass substrate comprising at least one through hole penetrating from the first surface to the second surface, wherein
a side surface of the through hole is such that:
   a side surface angle is in a range of 4° to 7° inclusive at a distance in a range from 0% or more to less than 10% from the first surface, and when the side surface of the through hole is regarded as a left side surface and a right side surface in a cross-sectional view, a difference between an inclination angle of the left side surface and an inclination angle of the right side surface is 1.0° or less; and
   a side surface angle is in a range of −7° to −15° inclusive at a distance in a range from 10% to 100% inclusive from the first surface, and a difference between an inclination angle of the left side surface and an inclination angle of the right side surface is 1.0° or less.

### (Aspect 2 (Supplement 2))

The glass substrate according to Aspect 1, wherein the side surface of the through hole has an inflection point, at which the inclination angle changes, at a distance in a range from 1% to 5% or less from the first surface.

### (Aspect 3 (Supplement 2))

The glass substrate according to Aspect 1 or 2, wherein in the through hole, a relationship between an opening diameter Φ2 on a second surface side and an opening diameter Φ1 on a first surface side is Φ1/Φ2≥0.4.

### (Aspect 4 (Supplement 2))

The glass substrate according to any one of Aspect 1 to 3, wherein a cut surface of the through hole in a thickness direction of the glass substrate has a shape of a side surface, the shape having a dispersion roughness of 1,000 nm or less and an unevenness width of 1,500 nm or less.

### (Aspect 5 (Supplement 2))

The glass substrate according to any one of Aspects 1 to 4, wherein
the dispersion roughness is an arithmetic mean roughness calculated with Expression 1 in a set section, the set section being set in a roughness curve, the roughness curve being extracted based on contour data of the side surface, and
the unevenness width is a difference between highest and lowest parts in the set section.

$$\begin{matrix}[ Expression 3 ] & \\ Ra = \frac{1}{L} {\int }_{0}^{L} {\vert f ( x ) \vert}^{2} {dx}^{\cdot \cdot } & Expression 1\end{matrix}$$

$$where : Ra is an arithmetic mean roughness ;$$

$$f ( x ) is a roughness curve ; and$$

$$L is a length of a set section .$$

### (Aspect 6 (Supplement 2))

The glass substrate according to any one of Aspects 1 to 5, wherein an SiO₂ ratio of the glass substrate is in a range of 55 mass % to 81 mass % inclusive.

### (Aspect 7 (Supplement 2))

A multilayer wiring substrate comprising the glass substrate according to any one of aspects 1 to 6, wherein
an electronic device mounted on the multilayer wiring substrate has a layer thickness of 800 μm or less, and
the multilayer wiring substrate has a thickness of 100 μm or more and 400 μm or less.

### (Aspect 8 (Supplement 2))

A method for producing the glass substrate according to any one of Aspects 1 to 7, the method comprising:
a first step of irradiating a portion of the glass substrate with a laser, the portion being where the through hole is to be formed; and
a second step of etching the glass substrate irradiated with the laser to form the through hole.

### (Aspect 9 (Supplement 2))

The method for producing a glass substrate according to Aspect 8, wherein the second step is a step of: performing etching processing in which the glass substrate irradiated with the laser is immersed in an etching solution and a direction of a jet of the etching solution is switched; and forming the through hole.

### (Aspect 10 (Supplement 2))

The method for producing a glass substrate according to Aspect 8 or 9, wherein the second step is a step of: performing etching processing in which an etching solution is sprayed onto the glass substrate irradiated with the laser and either the glass substrate or a spray nozzle of the etching solution is reciprocated; and forming the through hole.

### (Aspect 11 (Supplement 2))

The method for producing a glass substrate according to any one of Aspects 8 to 10, wherein the laser radiated in the first step has any of laser emission wavelengths of 1064 nm, 532 nm, and 355 nm, and has a pulse width of 25 picoseconds or less.

### (Aspect 12 (Supplement 2))

The method for producing a glass substrate according to any one of Aspects 8 to 11, wherein, in the first step, a maximum length of a microcrack occurring in a peripheral portion of the laser irradiation is 5 μm.

### (Aspect 13 (Supplement 2))

The method for producing a glass substrate according to any one of Aspects 8 to 12, wherein, in the second step, an etching solution is used that contains hydrofluoric acid in a range of 0.2 mass % to 20.0 mass % inclusive, nitric acid in a range of 4.0 mass % to 25.0 mass % inclusive, and an inorganic acid other than hydrofluoric acid and nitric acid in a range of 0.5 mass % to 11.0 mass % inclusive.

### REFERENCE SIGNS LIST

1: multilayer wiring substrate, 10: glass substrate, 11: through electrode, 12: through hole, 21: first wiring layer, 22: second wiring layer, 25: insulating resin layer, 31: conductive electrode, 50: semiconductor power device joining pad, 54: substrate joining pad, 61: first bonding layer, 62: first support, 63: laminated structure, 65: laser modified portion, 70: second support, 71: second bonding layer, 90: BGA substrate, 100: semiconductor power device, 101: first surface of glass substrate 10, 102: second surface of glass substrate 10, TC: center line of through hole, ss: tangent to side surface of through hole

1. A glass substrate having a first surface and a second surface, the glass substrate comprising at least one through hole penetrating from the first surface to the second surface,
wherein a cut surface of the through hole in a thickness direction of the glass substrate has a shape of a side surface, the shape having a dispersion roughness of 1,000 nm or less and an unevenness width of 1,500 nm or less.

2. The glass substrate according to claim 1, wherein
the dispersion roughness is an arithmetic mean roughness calculated with Expression 1 in a set section, the set section being set in a roughness curve, the roughness curve being extracted based on contour data of the side surface, and
the unevenness width is a difference between highest and lowest parts in the set section.
$$\begin{matrix}[ Expression 1 ] & \\ Ra = \frac{1}{L} {\int }_{0}^{L} {\vert f ( x ) \vert}^{2} {dx}^{\cdot \cdot } & Expression 1\end{matrix}$$
$$where : Ra is an arithmetic mean roughness ;$$
$$f ( x ) is a roughness curve ; and$$
$$L is a length of a set section .$$

3. A glass substrate having a first surface and a second surface, the glass substrate comprising at least one through hole penetrating from the first surface to the second surface, wherein a SEM image of a cut surface of the through hole in a thickness direction of the glass substrate allows a plurality of ridgelines to be seen, the SEM image having a magnification of 1000 times, the ridgelines extending in a side wall surface of the through hole, the ridgelines extending in a direction substantially parallel to the first surface, a space between the ridgelines being 15.5 μm or less in a direction perpendicular to the first surface.

4. The glass substrate according to claim 1, wherein an SiO₂ ratio of the glass substrate is in a range of 55 mass % to 81 mass % inclusive.

5. A multilayer wiring substrate comprising the glass substrate according to claim 1, wherein
an electronic device mounted on the multilayer wiring substrate has a layer thickness of 800 μm or less, and
the multilayer wiring substrate has a thickness in a range of 100 μm to 400 μm inclusive.

6. A method for producing the glass substrate according to claim 1, comprising:
a first step of irradiating a portion of the glass substrate with a laser, the portion being where the through hole is to be formed; and
a second step of etching the glass substrate irradiated with the laser to form the through hole.

7. The method for producing a glass substrate according to claim 6, wherein the laser radiated in the first step has any of laser emission wavelengths of 1064 nm, 532 nm, and 355 nm, and has a pulse width of 25 picoseconds or less.

8. The method for producing a glass substrate according to claim 6, wherein, in the first step, a maximum length of a microcrack occurring in a peripheral portion of the laser irradiation is 5 μm.

9. The method for producing a glass substrate according to claim 6, wherein, in the second step, etching is performed a plurality of times with different etching rates.

10. The method for producing a glass substrate according to claim 6, wherein, in the second step, an etching solution is used that contains hydrofluoric acid in a range of 0.2 mass % to 20.0 mass % inclusive, nitric acid in a range of 4.0 mass % to 25.0 mass % inclusive, and an inorganic acid other than hydrofluoric acid and nitric acid in a range of 0.5 mass % to 11.0 mass % inclusive.
